(19) United States
(12) Patent Application Publication
(10) Pub. No.: US 2022/0390658 A1
(43) Pub. Date: Dec. 8, 2022

(54) COLORING RESIN COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Masaomi MAKINO, Haibara-gun (JP); Takashi KAWASHIMA, Haibara-gun (JP)

(73) Assignee: FUJIFILM Corporation, Tokyo (JP)

(21) Appl. No.: 17/867,327

(22) Filed: Jul. 18, 2022

Related U.S. Application Data
(63) Continuation of application No. PCT/JP2021/001140, filed on Jan. 15, 2021.

(30) Foreign Application Priority Data
Jan. 20, 2020 (JP) 2020-006569

(51) Int. Cl. G02B 5/20; C09D 17/00; C09B 11/12; C09D 11/322; H01L 27/146; C09B 67/46; G02F 1/1335

(52) U.S. Cl. CPC G02B 5/208; C09D 17/003; C09B 11/12; C09D 11/322; H01L 27/14621; C09B 67/0084; G02F 1/133514; C09K 2323/031

(57) ABSTRACT

Provided are a coloring resin composition including a resin, a coloring material, and an organic solvent, in which the resin includes a resin A including a repeating unit (A) represented by Formula (a), where, in Formula (a), L^{a1} represents a trivalent group, Ar^{a1} represents an aromatic hydrocarbon group having a substituent, the substituent is a group having a structure in which a bonding portion with the aromatic hydrocarbon group is an ester bond or an amide bond, in the ester bond, an atom on a side different from an oxygen atom in the ester bond is on a side of the bonding portion with the aromatic hydrocarbon group, and in the amide bond, an atom on a side different from a nitrogen atom in the amide bond is on a side of the bonding portion with the aromatic hydrocarbon group; a film formed of the coloring resin composition; a color filter; a solid-state imaging element; and an image display device.

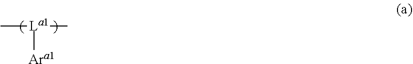

### CROSS-REFERENCE TO RELATED APPLICATIONS

This application is a Continuation of PCT International Application No. PCT/JP2021/001140 filed on Jan. 15, 2021, which claims priority under 35 U.S.C § 119(a) to Japanese Patent Application No. 2020-006569 filed on Jan. 20, 2020. Each of the above application(s) is hereby expressly incorporated by reference, in its entirety, into the present application.

### BACKGROUND OF THE INVENTION

### 1. Field of the Invention

The present invention relates to a coloring resin composition, a film, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A film including a pigment, such as a color filter, has been used for the solid-state imaging element. The film including a coloring material, such as a color filter, is manufactured by using a coloring resin composition and the like, which includes a coloring material, a resin, and a solvent.

For example, JP2003-128966A discloses an invention relating to an inkjet ink composition for a color filter, which is composed of, as a main polymer, a styrene-based polymer chain having a weight-average molecular weight of 5000 to 20000 and containing a styrene-based monomer unit in one of a main chain and a graft portion, in which the other contains a graft polymer composed of a methacrylate-based polymer chain containing a methacrylate-based monomer unit.

### SUMMARY OF THE INVENTION

In recent years, in the manufacturing process of a solid-state imaging element, it has been also studied to manufacture a film such as a color filter using a coloring resin composition including a coloring material, a resin, and a solvent, and then subject the film to a step requiring a heating treatment at a high temperature (for example, 300° C. or higher).

Therefore, an object of the present invention is to provide a novel coloring resin composition which can expand a process window of the process after manufacturing the film, a film, a color filter, a solid-state imaging element, and an image display device.

Examples of typical embodiments of the present invention are shown below.

<1> A coloring resin composition comprising:

a resin;

a coloring material; and

an organic solvent,

in which the resin includes a resin A including a repeating unit (A) represented by Formula (a),

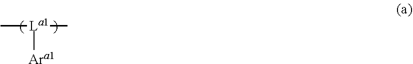

in Formula (a), L^{a1} represents a trivalent group,

Ar^{a1} represents an aromatic hydrocarbon group having a substituent,

the substituent is a group having a structure in which a bonding portion with the aromatic hydrocarbon group is an ester bond or an amide bond,

in the ester bond, an atom on a side different from an oxygen atom in the ester bond is on a side of the bonding portion with the aromatic hydrocarbon group, and

in the amide bond, an atom on a side different from a nitrogen atom in the amide bond is on a side of the bonding portion with the aromatic hydrocarbon group.

<2> The coloring resin composition according to <1>,

in which L^{a1} is an aliphatic hydrocarbon group.

<3> The coloring resin composition according to <1> or <2>,

in which the repeating unit (A) is a repeating unit represented by Formula (1),

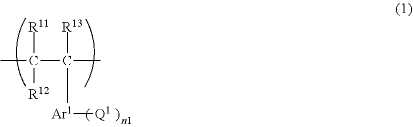

in Formula (1), R¹¹ to R¹³ each independently represent a hydrogen atom, an alkyl group, or an aryl group, Ar¹ represents an aromatic hydrocarbon group, and Q¹ represents a group represented by any one of Formula (Q-1) to Formula (Q-5),

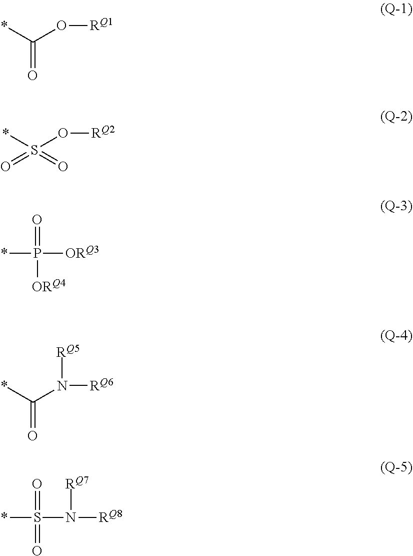

in the formulae, R^{Q1}, R^{Q2}, R^{Q3}, R^{Q6}, and R^{Q8} each independently represent a substituent,
R^{Q4}, R^{Q5}, and R^{Q7} each independently represent a hydrogen atom or a substituent, and
* represents a bonding site,

n1 represents an integer of 1 to a maximum number of substitutions of Ar¹.

<4> The coloring resin composition according to <1> or <2>,

in which the repeating unit (A) is a repeating unit represented by Formula (2),

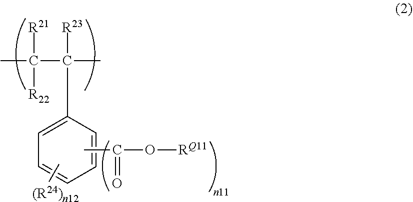

in Formula (2), R²¹ to R²³ each independently represent a hydrogen atom, an alkyl group, or an aryl group, R²⁴ represents a substituent, R^{Q11} represents a substituent, n11 represents an integer of 1 to 5, n12 represents an integer of 0 to 4, and n11+n12 is 1 to 5.

<5> The coloring resin composition according to any one of <1> to <4>,

in which the resin A has a carboxy group.

<6> The coloring resin composition according to any one of <1> to <5>,

in which an acid value of the resin A is 20 to 200 mgKOH/g.

<7> The coloring resin composition according to any one of <1> to <6>,

in which a weight-average molecular weight of the resin A is 10000 to 100000.

<8> The coloring resin composition according to any one of <1> to <7>,

in which the resin A has a crosslinkable group.

<9> The coloring resin composition according to any one of <1> to <8>,

in which the resin A is a graft polymer or a star polymer.

<10> The coloring resin composition according to any one of <1> to <9>,

in which the resin A is a graft polymer which has a graft chain including the repeating unit (A).

<11> The coloring resin composition according to any one of <1> to <10>,

in which the coloring material includes at least one selected from the group consisting of a chromatic coloring material and a near-infrared absorbing coloring material.

<12> The coloring resin composition according to any one of <1> to <11>,

in which the coloring material includes a chromatic coloring material and a near-infrared absorbing coloring material.

<13> The coloring resin composition according to any one of <1> to <12>,

in which the coloring material includes a black coloring material.

<14> The coloring resin composition according to any one of <1> to <13>,

in which the coloring material includes at least one chromatic coloring material selected from the group consisting of a red coloring material, a yellow coloring material, a blue coloring material, and a violet coloring material.

<15> The coloring resin composition according to any one of <1> to <14>, further comprising:

a photopolymerization initiator.

<16> The coloring resin composition according to <15>,

in which the photopolymerization initiator is an oxime compound.

<17> The coloring resin composition according to any one of <1> to <16>,

in which the coloring resin composition is used for forming a pattern in a photolithography method.

<18> The coloring resin composition according to any one of <1> to <17>,

in which the coloring resin composition is used for a solid-state imaging element.

<19> A film formed of the coloring resin composition according to any one of <1> to <18>.

<20> A color filter comprising:

the film according to <19>.

<21> A solid-state imaging element comprising:

the film according to <19>.

<22> An image display device comprising:

the film according to <19>.

According to the present invention, a novel coloring resin composition which can expand a process window of the process after manufacturing the film, a film, a color filter, a solid-state imaging element, and an image display device are provided.

### DESCRIPTION OF THE PREFERRED EMBODIMENTS

Hereinafter, main embodiments of the present invention will be described. However, the present invention is not limited to the specified embodiments.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, a (meth)allyl group represents either or both of allyl and methallyl, “(meth)acrylate” represents either or both of acrylate and methacrylate, “(meth)acryl” represents either or both of acryl and methacryl, and “(meth)acryloyl” represents either or both of acryloyl and methacryloyl.

In the present specification, a weight-average molecular weight and a number-average molecular weight are values in terms of polystyrene through measurement by a gel permeation chromatography (GPC) method.

In the present specification, near-infrared rays denote light having a wavelength in a range of 700 to 2500 nm.

In the present specification, a total solid content denotes the total mass of all the components of the composition excluding a solvent.

In the present specification, the term “step” refers to not only an individual step but also a step which is not clearly distinguishable from another step as long as an effect expected from the step can be achieved.

In addition, in the present specification, a combination of preferred aspects is a more preferred aspect.

<Coloring Resin Composition>

A coloring resin composition according to an embodiment of the present invention includes a resin, a coloring material, and an organic solvent, in which the resin includes a resin A including a repeating unit (A) represented by Formula (a) described later.

In the coloring resin composition according to the embodiment of the present invention, since the above-described resin A (hereinafter, also referred to as a specific resin) is included, it is possible to form a film having excellent heat resistance, which is not easily decomposed even at a high temperature and is less likely to contract even after a heating treatment at a high temperature. Therefore, even in a case where a film is formed of the coloring resin composition according to the embodiment of the present invention and then heat-treated at a high temperature (for example, 300° C. or higher), the film contraction is suppressed, and even in a case where another film such as an inorganic film is formed on the film, it is possible to suppress occurrence of cracks in the another film. Therefore, with the coloring resin composition according to the embodiment of the present invention, a process window of the process after manufacturing the film can be expanded. Although the detailed reason why such an effect is obtained is not clear, it is presumed that, since the aromatic hydrocarbon group is bonded to the trivalent group L^{a1} forming the molecular chain, the above-described specific resin has an improved depolymerization temperature of the resin. Since the above-described aromatic hydrocarbon group has a specific substituent, even in a case where a radical is generated during the depolymerization of the resin, it is presumed that the generated radical can be destabilized and the depolymerization of the resin by the radical can be suppressed. The above-described specific substituent is a group having a structure in which a bonding portion with the above-described aromatic hydrocarbon group is an ester bond or an amide bond, where in the ester bond, an atom on a side different from an oxygen atom in the ester bond is on a side of the bonding portion with the aromatic hydrocarbon group, and in the amide bond, an atom on a side different from a nitrogen atom in the amide bond is on a side of the bonding portion with the aromatic hydrocarbon group.

Therefore, with the coloring resin composition according to the embodiment of the present invention including the above-described specific resin, it is presumed that it is possible to form a film having excellent heat resistance, which is not easily decomposed even at a high temperature and is less likely to contract even after a heating treatment at a high temperature. Further, since the resin A has the above-described specific substituent, dispersibility of the coloring material in the coloring resin composition can be improved, and storage stability of the coloring resin composition can be improved.

In a case where a film having a thickness of 0.60 μm is formed by heating the coloring resin composition according to the embodiment of the present invention at 200° C. for 30 minutes, a thickness of the film after performing a heating treatment of the film at 300° C. for 5 hours in a nitrogen atmosphere is preferably 70% or more of a thickness of the film before the heating treatment, more preferably 80% or more thereof, and still more preferably 90% or more.

In addition, a thickness of the film after performing a heating treatment of the film at 350° C. for 5 hours in a nitrogen atmosphere is preferably 70% or more of a thickness of the film before the heating treatment, more preferably 80% or more thereof, and still more preferably 90% or more.

In addition, a thickness of the film after performing a heating treatment of the film at 400° C. for 5 hours in a nitrogen atmosphere is preferably 70% or more of a thickness of the film before the heating treatment, more preferably 80% or more thereof, and still more preferably 90% or more.

The above-described physical properties can be achieved by a method such as adjusting the type and content of the specific resin to be used.

In addition, in a case where a film having a thickness of 0.60 μm is formed by heating the coloring resin composition according to the embodiment of the present invention at 200° C. for 30 minutes, a rate of change ΔA in absorbance of the film after the heating treatment at 300° C. for 5 hours in a nitrogen atmosphere, which is represented by Expression (1), is preferably 50% or less, more preferably 45% or less, still more preferably 40% or less, and particularly preferably 35% or less.

ΔA (%)=|100−(A2/A1)×100| (1)

ΔA is the rate of change in the absorbance of the film after the heating treatment;

A1 is a maximum value of an absorbance of the film before the heating treatment in a wavelength range of 400 to 1100 nm; and

A2 is the absorbance of the film after the heating treatment, and is the absorbance at a wavelength showing the maximum value of the absorbance of the film before the heating treatment in a wavelength range of 400 to 1100 nm.

The above-described physical properties can be achieved by a method such as adjusting the type and content of the specific resin to be used.

In addition, in a case where a film having a thickness of 0.60 μm is formed by heating the coloring resin composition according to the embodiment of the present invention at 200° C. for 30 minutes, an absolute value of a difference between a wavelength λ1 showing the maximum value of the absorbance of the film in a wavelength range of 400 to 1100 nm and a wavelength λ2 showing the maximum value of the absorbance of the film after the heating treatment at 300° C. for 5 hours in a nitrogen atmosphere is preferably 50 nm or less, more preferably 45 nm or less, and still more preferably 40 nm or less.

The above-described physical properties can be achieved by a method such as adjusting the type and content of the specific resin to be used.

In addition, in a case where a film having a thickness of 0.60 μm is formed by heating the coloring resin composition according to the embodiment of the present invention at 200° C. for 30 minutes, a maximum value of the rate of change ΔA_{λ} in absorbance of the film after the heating treatment at 300° C. for 5 hours in a nitrogen atmosphere in a wavelength range of 400 to 1100 nm is preferably 30% or less, more preferably 27% or less, and still more preferably 25% or less. The rate of change in the absorbance is a value calculated from Expression (2).

ΔA_{λ}=|100−(A2_{λ}/A1_{λ})×100| (2)

ΔA_{λ} is the rate of change in the absorbance of the film after the heating treatment at a wavelength λ;

A1_{λ} is the absorbance of the film before the heating treatment at the wavelength λ;

and

A2_{λ} is the absorbance of the film after the heating treatment at the wavelength λ.

The above-described physical properties can be achieved by a method such as adjusting the type and content of the specific resin to be used.

In addition, in a case where the coloring resin composition according to the embodiment of the present invention is applied to a glass substrate and heated at 100° C. for 120 seconds to form a film having a film thickness of 0.6 μm, it is preferable that the film has a transmittance of 80% or more at a wavelength of 400 nm. In addition, it is preferable that the above-described film has a transmittance of 90% or more at a wavelength of 450 nm. A more preferred aspect of the above-described film is an aspect in which the transmittance at a wavelength of 400 nm is 90% or more and the transmittance at a wavelength of 450 nm is 95% or more.

The coloring resin composition according to the embodiment of the present invention can be used for a color filter, a near-infrared transmitting filter, a near-infrared cut filter, a black matrix, a light shielding film, and the like.

Examples of the color filter include a filter having a colored pixel which transmits light having a specific wavelength, and a filter having at least one colored pixel selected from a red pixel, a blue pixel, a green pixel, a yellow pixel, a cyan pixel, and a magenta pixel is preferable. The color filter can be formed using a coloring resin composition including a chromatic coloring material.

Examples of the near-infrared cut filter include a filter having a maximal absorption wavelength in a wavelength range of 700 to 1800 nm. As the near-infrared cut filter, a filter having a maximal absorption wavelength in a wavelength range of 700 to 1300 nm is preferable, and a filter having a maximal absorption wavelength in a wavelength range of 700 to 1100 nm is more preferable. In addition, in the near-infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1800 nm is preferably 20% or less. In addition, in the near-infrared cut filter, absorbance Aₘₐₓ/absorbance A₅₅₀, which is a ratio of an absorbance Aₘₐₓ at a maximal absorption wavelength to an absorbance A₅₅₀ at a wavelength of 550 nm, is preferably 20 to 500, more preferably 50 to 500, still more preferably 70 to 450, and particularly preferably 100 to 400. The near-infrared cut filter can be formed using a coloring resin composition including a near-infrared absorbing coloring material.

The near-infrared transmitting filter is a filter which transmits at least a part of near-infrared rays. The near-infrared transmitting filter may be a filter (transparent film) which transmits both visible light and near-infrared ray, or may be a filter which shields at least a part of visible light and transmits at least a part of near-infrared rays. Preferred examples of the near-infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near-infrared transmitting filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

The coloring resin composition according to the embodiment of the present invention can be preferably used as a coloring resin composition for a color filter. Specifically, the coloring resin composition according to the embodiment of the present invention can be preferably used as a coloring resin composition for forming a pixel of a color filter, and can be more preferably used as a coloring resin composition for forming a red or blue pixel of a color filter. In addition, the coloring resin composition according to the embodiment of the present invention can be preferably used as a coloring resin composition for forming a pixel of a color filter used in a solid-state imaging element.

In a case where the coloring resin composition according to the embodiment of the present invention is applied to a glass substrate and heated at 100° C. for 120 seconds to form a film having a film thickness of 0.6 μm, it is preferable that a maximum value of a transmittance of the film at a wavelength of 400 to 1100 nm is 70% or more (preferably 75% or more, more preferably 80% or more, and still more preferably 85% or more), and a minimum value thereof is 30% or less (preferably 25% or less, more preferably 20% or less, and still more preferably 15% or less). A coloring resin composition capable of forming a film satisfying the above-described spectral characteristics can be particularly preferably used as a coloring resin composition for forming a color filter, a near-infrared transmitting filter, or a near-infrared cut filter.

In addition, the coloring resin composition according to the embodiment of the present invention is also preferably a coloring resin composition used for forming a pattern in a photolithography method. According to this aspect, finely sized pixels can be easily formed. Therefore, the coloring resin composition according to the embodiment of the present invention can be particularly preferably used as a coloring resin composition for forming a pixel of a color filter used in a solid-state imaging element. For example, a coloring resin composition containing a component having a polymerizable group (for example, a resin or polymerizable compound having a polymerizable group) and a photopolymerization initiator can be preferably used as a coloring resin composition used for forming a pattern in a photolithography method. The coloring resin composition for forming a pattern in the photolithography method preferably further contains an alkali-soluble resin.

Hereinafter, the respective components used in the coloring resin composition according to the embodiment of the present invention will be described.

<Coloring Material>

The coloring resin composition according to the embodiment of the present invention contains a coloring material. Examples of the coloring material include a white coloring material, a black coloring material, a chromatic coloring material, and a near-infrared absorbing coloring material. In the present invention, the white coloring material includes not only a pure white coloring material but also a bright gray (for example, grayish-white, light gray, and the like) coloring material close to white.

It is preferable that the coloring material includes at least one selected from the group consisting of a chromatic coloring material, a black coloring material, and a near-infrared absorbing coloring material, it is more preferable to include at least one selected from the group consisting of a chromatic coloring material and a near-infrared absorbing coloring material, it is still more preferable to include a chromatic coloring material, and it is even more preferable to include at least one chromatic coloring material selected from the group consisting of a red coloring material, a yellow coloring material, a blue coloring material, and a violet coloring material.

In addition, the coloring material also preferably includes a chromatic coloring material and a near-infrared absorbing coloring material, and also preferably includes two or more kinds of chromatic coloring materials and a near-infrared absorbing coloring material. In addition, a combination of two or more kinds of chromatic coloring materials may form black. In addition, the coloring material also preferably includes a black coloring material and a near-infrared absorbing coloring material. According to these aspects, the coloring resin composition according to the embodiment of the present invention can be preferably used as a coloring resin composition for forming a near-infrared transmitting filter. For a combination of coloring materials which form black with the combination of two or more kinds of chromatic coloring materials, JP2013-077009A, JP2014-130338A, WO2015/166779A, and the like can be referred to.

Examples of the coloring material include a dye and a pigment, and from the viewpoint of heat resistance, a pigment is preferable. In addition, the pigment may be an inorganic pigment or an organic pigment, but from the viewpoint of many color variations, ease of dispersion, safety, and the like, an organic pigment is preferable. In addition, it is preferable that the pigment includes at least one selected from a chromatic pigment or a near-infrared absorbing pigment, and it is more preferable to include a chromatic pigment.

In addition, it is preferable that the pigment includes at least one selected from a phthalocyanine pigment, a dioxazine pigment, a quinacridone pigment, an anthraquinone pigment, a perylene pigment, an azo pigment, a diketopyrrolopyrrole pigment, a pyrrolopyrrole pigment, an isoindoline pigment, or a quinophthalone pigment, it is more preferable to include at least one selected from a phthalocyanine pigment, a diketopyrrolopyrrole pigment, or a pyrrolopyrrole pigment, and it is still more preferable to include a phthalocyanine pigment or a diketopyrrolopyrrole pigment. In addition, from the reason that it is easy to form a film in which spectral characteristics do not easily fluctuate even after heating to a high temperature (for example, 300° C. or higher), the phthalocyanine pigment is preferably a phthalocyanine pigment having no central metal or a phthalocyanine pigment having copper or zinc as a central metal.

In addition, from the reason that it is easy to form a film in which spectral characteristics do not easily fluctuate even after heating to a high temperature (for example, 300° C. or higher), it is preferable that the coloring material included in the coloring resin composition includes at least one selected from a red pigment, a yellow pigment, a blue pigment, or a near-infrared absorbing pigment, it is more preferable to include at least one selected from a red pigment or a blue pigment, and it is still more preferable to include a blue pigment.

The coloring material included in the coloring resin composition preferably includes a pigment A satisfying the following requirement 1. By using a coloring material having such characteristics, it is possible to form a film in which spectral characteristics do not easily fluctuate even after heating to a high temperature (for example, 300° C. or higher). A proportion of the pigment A in the total amount of the pigment included in the coloring resin composition is preferably 20 to 100 mass %, more preferably 30 to 100 mass %, and still more preferably 40 to 100 mass %.

Requirement 1)

In a case where a film having a thickness of 0.60 μm is formed by heating, at 200° C. for 30 minutes, a composition which includes 6 mass % of the pigment A, 10 mass % of a resin 1, and 84 mass % of propylene glycol monomethyl ether acetate, in a case where the film is subjected to a heating treatment at 300° C. for 5 hours in a nitrogen atmosphere, the rate of change ΔA10 in absorbance of the film after the heating treatment, which is represented by Expression (10), is 50% or less;

ΔA10=|100−(A12/A11)×100| (10)

ΔA10 is the rate of change in the absorbance of the film after the heating treatment;

A11 is the maximum value of the absorbance of the film before the heating treatment in a wavelength range of 400 to 1100 nm;

A12 is the absorbance of the film after the heating treatment, and is the absorbance at the wavelength showing the maximum value of the film before the heating treatment in a wavelength range of 400 to 1100 nm; and

The resin 1 is a resin having the following structure, in which a numerical value added to a main chain represents a molar ratio, the weight-average molecular weight is 11000, and the acid value is 32 mgKOH/g.

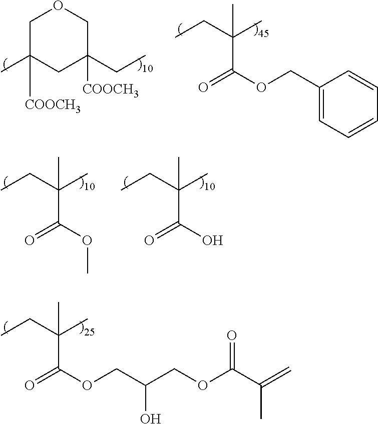

Examples of the pigment A satisfying the above-described requirement 1 include C. I. Pigment Red 254, C. I. Pigment Red 264, Pigment Red 272, Pigment Red 122, Pigment Red 177, C. I. Pigment Blue 15:3, C. I. Pigment Blue 15:4, C. I. Pigment Blue 15:6, and C. I. Pigment Blue 16.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the coloring resin composition is good. In the present invention, the primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

[Chromatic Coloring Material]

Examples of the chromatic coloring material include a coloring material having a maximal absorption wavelength in a wavelength range of 400 to 700 nm. Examples thereof include a yellow coloring material, an orange coloring material, a red coloring material, a green coloring material, a violet coloring material, and a blue coloring material. From the viewpoint of heat resistance, the chromatic coloring material is preferably a pigment (chromatic pigment), more preferably a red pigment, a yellow pigment, or a blue pigment, and still more preferably a red pigment or a blue pigment. Specific examples of the chromatic pigment include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

Among these chromatic pigments, as the red pigment, from the reason that it is easy to form a film in which spectral characteristics do not easily fluctuate even after heating to a high temperature (for example, 300° C. or higher), C. I. Pigment Red 254, C. I. Pigment Red 264, Pigment Red 272, Pigment Red 122, or Pigment Red 177 is preferable. In addition, as the blue pigment, C. I. Pigment Blue 15:3, C. I. Pigment Blue 15:4, C. I. Pigment Blue 15:6, or C. I. Pigment Blue 16 is preferable.

In addition, as the green coloring material, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue coloring material, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow coloring material, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in JP6607427B, methine dyes described in JP2019-073695A, methine dyes described in JP2019-073696A, methine dyes described in JP2019-073697A, methine dyes described in JP2019-073698A, a compound represented by Formula (QP1), and a compound represented by Formula (QP2) can also be used. In addition, from the viewpoint of improving color value, a multimerized compound of these compounds is also preferably used. In addition, as the yellow coloring material, from the viewpoint of improving resistance, it is also preferable to use C. I. Pigment Yellow 129 or C. I. Pigment Yellow 215.

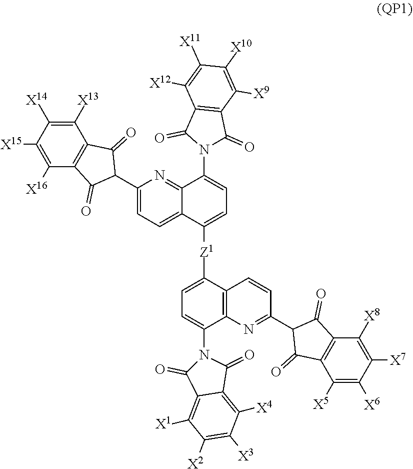

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

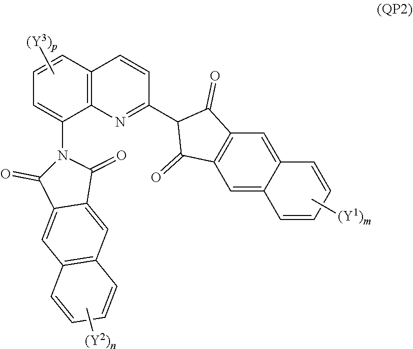

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red coloring material, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, compounds described in JP6516119B, compounds described in JP6525101B, and the like can also be used. In addition, as the red coloring material, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

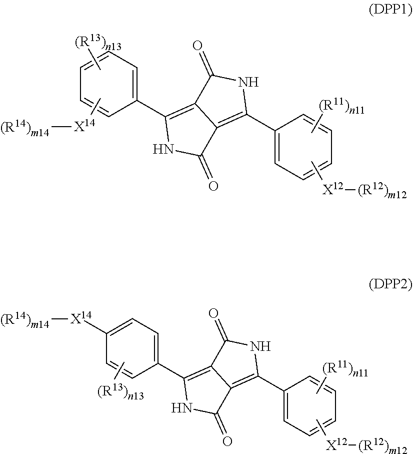

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Preferred specific examples of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

The chromatic coloring material may be used in combination of two or more kinds thereof. In addition, in a case where the chromatic coloring material is used in combination of two or more kinds thereof, the combination of two or more kinds of chromatic coloring materials may form black. Examples of such a combination include the following aspects (1) to (7). In a case where two or more kinds of chromatic coloring materials are included in the coloring resin composition and the combination of two or more kinds of chromatic coloring materials forms black, the coloring resin composition according to the embodiment of the present invention can be preferably used as a near-infrared transmitting filter.

(1) aspect in which a red coloring material and a blue coloring material are contained.

(2) aspect in which a red coloring material, a blue coloring material, and a yellow coloring material are contained.

(3) aspect in which a red coloring material, a blue coloring material, a yellow coloring material, and a violet coloring material are contained.

(4) aspect in which a red coloring material, a blue coloring material, a yellow coloring material, a violet coloring material, and a green coloring material are contained.

(5) aspect in which a red coloring material, a blue coloring material, a yellow coloring material, and a green coloring material are contained.

(6) aspect in which a red coloring material, a blue coloring material, and a green coloring material are contained.

(7) aspect in which a yellow coloring material and a violet coloring material are contained.

[White Coloring Material]

Examples of the white coloring material include inorganic pigments (white pigments) such as titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-mentioned refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published on Jun. 25, 1991, published by Gihodo Shuppan Co., Ltd.” can also be used.

The white pigment is not limited to a compound formed of a single inorganic substance, and may be particles combined with other materials. For example, it is preferable to use a particle having a pore or other materials therein, a particle having a large number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

[Black Coloring Material]

The black coloring material is not particularly limited, and a known black coloring material can be used. Examples thereof include inorganic pigments (black pigments) such as carbon black, titanium black, and graphite, and carbon black or titanium black is preferable and titanium black is more preferable. The titanium black is a black particle containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which a content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

In addition, as the black coloring material, organic black coloring materials such as a bisbenzofuranone compound, an azomethine compound, a perylene compound, and an azo compound can also be used. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF. Examples of the perylene compound include compounds described in paragraph Nos. 0016 to 0020 of JP2017-226821A, and C. I. Pigment Black 31 and 32. Examples of the azomethine compound include the compounds described in JP1989-170601A (JP-1401-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

The coloring material used in the coloring resin composition according to the embodiment of the present invention may be only the above-described black coloring material, or may further include the chromatic coloring material. According to this aspect, it is easy to obtain a composition with which a film having high light shielding properties in the visible region can be formed. In a case where the black coloring material and the chromatic coloring material are used in combination as the coloring material, the mass ratio of the two is preferably black coloring material:chromatic coloring material=100:10 to 300, and more preferably 100:20 to 200. In addition, it is preferable to use the black pigment as the black coloring material, and it is preferable to use the chromatic pigment as the chromatic coloring material.

Examples of preferred combinations of the black coloring material and the chromatic coloring material include the following.

(A-1) aspect in which the organic black coloring material and the blue coloring material are contained

(A-2) aspect in which the organic black coloring material, the blue coloring material, and the yellow coloring material are contained

(A-3) aspect in which the organic black coloring material, the blue coloring material, the yellow coloring material, and the red coloring material are contained

(A-4) aspect in which the organic black coloring material, the blue coloring material, the yellow coloring material, and the violet coloring material are contained

In the above-described aspect (A-1), the mass ratio of the organic black coloring material and the blue coloring material is preferably organic black coloring material:blue coloring material=100:1 to 70, more preferably 100:5 to 60, and still more preferably 100:10 to 50.

In the above-described aspect (A-2), the mass ratio of the organic black coloring material, the blue coloring material, and the yellow coloring material is preferably organic black coloring material:blue coloring material:yellow coloring material=100:10 to 90:10 to 90, more preferably 100:15 to 85:15 to 80, and still more preferably 100:20 to 80:20 to 70.

In the above-described aspect (A-3), the mass ratio of the organic black coloring material, the blue coloring material, the yellow coloring material, and the red coloring material is preferably organic black coloring material:blue coloring material:yellow coloring material:red coloring material=100:20 to 150:1 to 60:10 to 100, more preferably 100:30 to 130:5 to 50:20 to 90, and still more preferably 100:40 to 120:10 to 40:30 to 80.

In the above-described aspect (A-4), the mass ratio of the organic black coloring material, the blue coloring material, the yellow coloring material, and the violet coloring material is preferably organic black coloring material:blue coloring material:yellow coloring material:violet coloring material=100:20 to 150:1 to 60:10 to 100, more preferably 100:30 to 130:5 to 50:20 to 90, and still more preferably 100:40 to 120:10 to 40:30 to 80.

[Near-Infrared Absorbing Coloring Material]

The near-infrared absorbing coloring material is preferably a pigment, and more preferably an organic pigment. In addition, the near-infrared absorbing coloring material preferably has a maximal absorption wavelength in a wavelength range of more than 700 nm and 1400 nm or less. In addition, the maximal absorption wavelength of the near-infrared absorbing coloring material is preferably 1200 nm or less, more preferably 1000 nm or less, and still more preferably 950 nm or less. In addition, in the near-infrared absorbing coloring material, A₅₅₀/Aₘₐₓ, which is a ratio of an absorbance A550 at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing coloring material excellent in visible light transparency and near-infrared shielding properties can be obtained. In the present invention, the maximal absorption wavelength of the near-infrared absorbing coloring material and values of absorbance at each wavelength are values obtained from an absorption spectrum of a film formed by using a coloring resin composition including the near-infrared absorbing coloring material.

The near-infrared absorbing coloring material is not particularly limited, and examples thereof include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, and a dithiolene metal complex. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B.

In addition, as the near-infrared absorbing coloring material, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the α-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, coloring materials described in JP2013-077009A, JP2014-130338A, and WO2015/166779A, combinations of coloring materials described in these references, and the like can also be used.

A content of the coloring material in the total solid content of the coloring resin composition is preferably 30 mass % or more, more preferably 40 mass % or more, still more preferably 50 mass % or more, and even more preferably 60 mass % or more. The content of the coloring material in the total solid content of the coloring resin composition is preferably 90 mass % or less and more preferably 80 mass % or less.

In addition, a content of the pigment in the total solid content of the coloring resin composition is preferably 30 mass % or more, more preferably 40 mass % or more, still more preferably 50 mass % or more, and even more preferably 60 mass % or more. The content of the pigment in the total solid content of the coloring resin composition is preferably 90 mass % or less and more preferably 80 mass % or less.

In addition, the content of the dye in the coloring material is preferably 50 mass % or less, more preferably 40 mass % or less, and still more preferably 30 mass % or less.

In addition, from the reason that it is easy to more effectively suppress the change in film thickness in a case where the obtained film is heated to a high temperature, it is also preferable that the coloring resin composition according to the embodiment of the present invention does not substantially include the dye. The case where the coloring resin composition according to the embodiment of the present invention does not substantially include the dye means that the content of the dye in the total solid content of the coloring resin composition according to the embodiment of the present invention is preferably 0.1 mass % or less, more preferably 0.05 mass % or less, and particularly preferably 0 mass %.

<Specific Resin>

The coloring resin composition according to the embodiment of the present invention includes a resin. The resin included in the coloring resin composition includes a resin A (hereinafter, also referred to as a specific resin) including a repeating unit (A) represented by Formula (a).

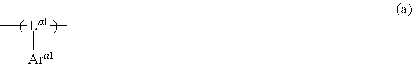

In Formula (a), L^{a1} represents a trivalent group,

Ar^{a1} represents an aromatic hydrocarbon group having a substituent,

the substituent is a group having a structure in which a bonding portion with the aromatic hydrocarbon group is an ester bond or an amide bond,

in the ester bond, an atom on a side different from an oxygen atom in the ester bond is on a side of the bonding portion with the aromatic hydrocarbon group, and

in the amide bond, an atom on a side different from a nitrogen atom in the amide bond is on a side of the bonding portion with the aromatic hydrocarbon group.

Examples of the above-described trivalent group represented by L^{a1} in Formula (a) include an aliphatic hydrocarbon group, an aromatic hydrocarbon group, a heterocyclic group, a group represented by at least two bonds selected from the group consisting of an aliphatic hydrocarbon group, an aromatic hydrocarbon group, and a heterocyclic group, and a group represented by a bond of at least one selected from the group consisting of an aliphatic hydrocarbon group, an aromatic hydrocarbon group, and a heterocyclic group, and at least one selected from the group consisting of —O—, —CO—, —COO—, —OCO—, —NH—, and —N<.

The number of carbon atoms in the above-described aliphatic hydrocarbon group is preferably 1 to 20, more preferably 1 to 15, still more preferably 1 to 10, and even more preferably 1 to 5. The aliphatic hydrocarbon group is more preferably an aliphatic saturated hydrocarbon group.

The number of carbon atoms in the above-described aromatic hydrocarbon group is preferably 6 to 30, more preferably 6 to 20, and still more preferably 6 to 12.

The number of heteroatoms constituting a ring of the above-described heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 20, more preferably 3 to 15, and more preferably 3 to 12. The heterocyclic group represented by L^{a1} is preferably a 5-membered or 6-membered heterocycle.

The above-described aliphatic hydrocarbon group, aromatic hydrocarbon group, and heterocyclic group may have a substituent. Examples of the substituent include a halogen atom, an alkyl group, an aryl group, an alkoxy group, an aryloxy group, an acyl group, and an acyloxy group. The substituent is preferably an alkyl group or an aryl group.

As the trivalent group represented by L^{a1}, from the viewpoint that the effects of the present invention can be significantly obtained, an aliphatic hydrocarbon group is preferable, and an aliphatic saturated hydrocarbon group is more preferable.

Ar^{a1} in Formula (a) represents an aromatic hydrocarbon group (hereinafter, also referred to as an aromatic hydrocarbon group A) having the specific substituent.

The number of carbon atoms constituting an aromatic hydrocarbon ring in the above-described aromatic hydrocarbon group A is preferably 6 to 30 and more preferably 6 to 20. Specific examples of the aromatic hydrocarbon ring include a benzene ring and a naphthalene ring, and a benzene ring is preferable.

The above-described specific substituent included in the above-described aromatic hydrocarbon group A is a group having a structure in which a bonding portion with the aromatic hydrocarbon group is an ester bond or an amide bond. In the ester bond in the specific substituent, an atom on a side different from an oxygen atom in the ester bond is on a side of the bonding portion with the aromatic hydrocarbon group, and in the above-described amide bond in the specific substituent, an atom on a side different from a nitrogen atom in the amide bond is on a side of the bonding portion with the aromatic hydrocarbon group. Since the above-described aromatic hydrocarbon group A has the above-described specific substituent (group having a structure in which the bonding portion with the aromatic hydrocarbon group is an ester group or an amide group), heat resistance of the obtained film can be further improved. Further, dispersibility of the coloring material in the coloring resin composition can be improved, and storage stability of the coloring resin composition can be improved.

The number of specific substituents included in one aromatic hydrocarbon group A is preferably 1 to 3, more preferably 1 or 2, and still more preferably 1. Among these, one aromatic hydrocarbon group A preferably has one to three specific substituents, more preferably one or two specific substituents, and still more preferably one specific substituent. In addition, the aromatic hydrocarbon group A may have the specific substituent at any of the para-position, the ortho-position, or the meta-position of the bonding portion with L^{a1}, but from the reason that it is easier to improve heat resistance, it is preferable to have the specific substituent at the para-position of the bonding portion with L.

In the present specification, the ester bond means a bond formed by an oxo acid and an alcohol. Examples of the oxo acid include carboxylic acid, sulfonic acid, and phosphoric acid. Specific examples of the ester bond include a carboxylic acid ester bond, a sulfonic acid ester bond, and a phosphoric acid ester bond, and a carboxylic acid ester bond is preferable. In addition, examples of the amide bond include a carboxylic acid amide bond and a sulfonic acid amide bond, and a carboxylic acid amide bond is preferable.

Specific examples of the above-described specific substituent include groups represented by Formulae (Q-1) to (Q-5), and from the reason that dispersibility of the coloring material in the coloring resin composition is good and it is easy to improve the heat resistance of the obtained film, a group represented by Formula (Q-1) is preferable.

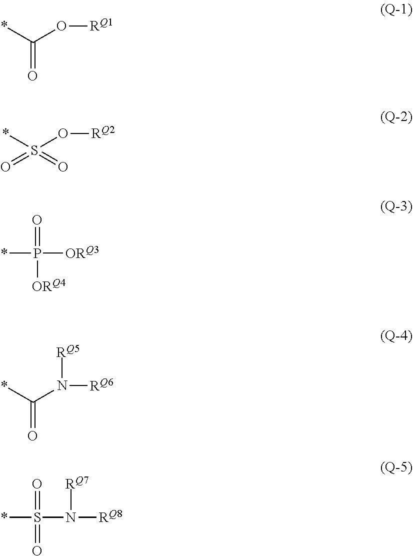

R^{Q1}, R^{Q2}, R^{Q3}, R^{Q6}, and R^{Q8} each independently represent a substituent,

R^{Q4}, R^{Q5}, and R^{Q7} each independently represent a hydrogen atom or a substituent,

* represents a bonding site, and

n1 represents an integer of 1 to the maximum number of substitutions of Ar¹.

As the substituent represented by R^{Q1} to R^{Q8}, an aliphatic hydrocarbon group, an aromatic hydrocarbon group, or at least two bonds selected from the group consisting of an aliphatic hydrocarbon group, an aromatic hydrocarbon group, a heterocyclic group, —O—, —C(═O)—, —S—, —S(═O)₂—, —C(═O)O—, —C(═O)NR^{N}—, —OC(═O)NR^{N}—, —NR^{N}C(═O)NR^{N}—, —CH₂CH(OH)CH₂—, a crosslinkable group, and a polymer chain is preferable.

As the above-described aliphatic hydrocarbon group, an aliphatic hydrocarbon group having 1 to 20 carbon atoms is preferable and an aliphatic saturated hydrocarbon group having 1 to 20 carbon atoms is more preferable.

As the above-described aromatic hydrocarbon group, an aromatic hydrocarbon group having 6 to 30 carbon atoms is preferable and an aromatic hydrocarbon group having 6 to 20 carbon atoms is more preferable. As the aromatic hydrocarbon group, a phenyl group or a naphthyl group is preferable, and a phenyl group is more preferable.

The aliphatic hydrocarbon group and aromatic hydrocarbon group may further have a substituent. Examples of the substituent include acid groups such as a phenolic hydroxy group, a carboxy group, a sulfo group, and a phosphoric acid group, and crosslinkable groups.

The number of heteroatoms constituting a ring of the above-described heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 20, more preferably 3 to 18, and more preferably 3 to 12.

Examples of the above-described crosslinkable group include an ethylenically unsaturated bond-containing group and a cyclic ether group. Examples of the ethylenically unsaturated bond-containing group include a (meth)acryloyl group, a (meth)acryloyloxy group, a (meth)acrylamide group, a vinylphenyl group, and an allyl group, and from the viewpoint of reactivity, a (meth)acryloyloxy group is preferable. Examples of the cyclic ether group include an epoxy group and an oxetanyl group.

Examples of the above-described polymer chain include polymer chains including at least one structural repeating unit selected from a polyester repeating unit, a polyether repeating unit, a poly(meth)acrylic repeating unit, and a (poly)styrene repeating unit. Specific examples of the above-described polymer chain include a polymer chain including a repeating unit represented by any one of Formula (P1-1), . . . , or Formula (P1-6). A weight-average molecular weight of the polymer chain is preferably 500 to 10000.

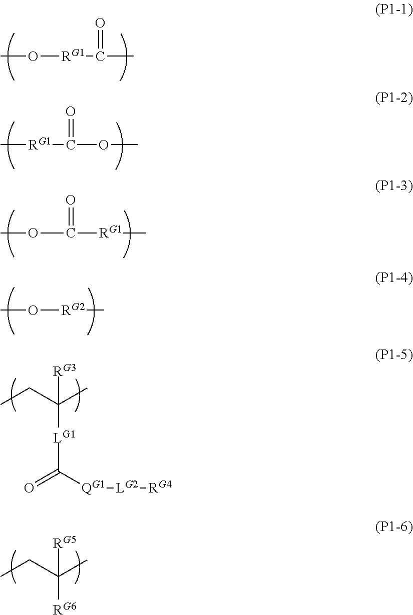

In the formulae, R^{G1} and R^{G2} each represent an alkylene group. As the alkylene group represented by R^{G1} and R^{G2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{G3} represents a hydrogen atom, a methyl group, a fluorine atom, a chlorine atom, or a hydroxymethyl group, and a hydrogen atom or a methyl group is preferable.

In the formulae, Q^{G1} represents —O— or —NR^{q}—, where R^{q} represents a hydrogen atom, an alkyl group, an aryl group, or a heterocyclic group. It is preferable that Q^{G1} represents —O—.

In the formulae, L^{G1} represents a single bond or an arylene group, and a single bond is preferable.

In the formulae, L^{G2} represents a single bond or a divalent linking group, and a single bond is preferable. Examples of the divalent linking group include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group including a combination of two or more thereof, and an alkylene group or an arylene group is preferable.

In the formulae, R^{G4} represents a hydrogen atom or a substituent. Examples of the substituent include a halogen atom, a hydroxy group, a carboxy group, a sulfo group, an alkyl group, an aryl group, a heterocyclic group, an alkoxy group, an aryloxy group, an acyl group, an acyloxy group, an alkylthioether group, an arylthioether group, and a crosslinkable group.

In the formulae, R^{G5} represents a hydrogen atom or a methyl group and R^{G6} represents an aryl group. The number of carbon atoms in the aryl group represented by R^{G6} is preferably 6 to 30, more preferably 6 to 20, and still more preferably 6 to 12. The aryl group represented by R^{G6} may have a substituent. Examples of the substituent include a halogen atom, a hydroxy group, a carboxy group, a sulfo group, an alkyl group, an aryl group, a heterocyclic group, an alkoxy group, an aryloxy group, an acyl group, an acyloxy group, an alkylthioether group, an arylthioether group, a crosslinkable group, and the above-described specific substituent.

In Formula (a), L^{a1} and Ar^{a1} may be bonded to each other to form a ring. The ring to be formed is preferably an aliphatic hydrocarbon ring, and more preferably a 5-membered or 6-membered aliphatic hydrocarbon ring. Examples of a repeating unit in the case where L^{a1} and Ar^{a1} are bonded to each other to form a ring include the following repeating units (AB-3), (AB-4), and the like.

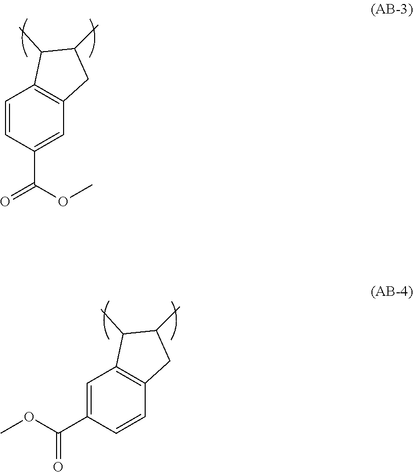

The repeating unit (A) is preferably a repeating unit represented by Formula (1). According to this aspect, dispersibility of the coloring material in the coloring resin composition is good, and heat resistance of the obtained film can be further improved.

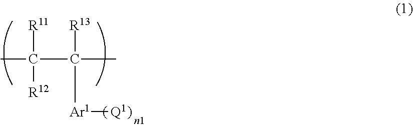

In Formula (1), R¹¹ to R¹³ each independently represent a hydrogen atom, an alkyl group, or an aryl group, Ar¹ represents an aromatic hydrocarbon group, Q¹ represents the above-described group represented by any one of Formula (Q-1), . . . , or Formula (Q-5), and n1 represents an integer of 1 to the maximum number of substitutions of Ar¹.

R¹¹ and R¹³ in Formula (1) each independently represent a hydrogen atom, an alkyl group, or an aryl group, and are preferably a hydrogen atom or an alkyl group and more preferably a hydrogen atom.

As the above-described alkyl group, an alkyl group having 1 to 10 carbon atoms is preferable, an alkyl group having 1 to 4 carbon atoms is more preferable, and a methyl group is still more preferable. The alkyl group may be a linear, branched, or cyclic alkyl group, but is preferably a linear alkyl group.

As the aryl group, an aryl group having 6 to 30 carbon atoms is preferable, an aryl group having 6 to 20 carbon atoms is more preferable, a phenyl group or a naphthyl group is still more preferable, and a phenyl group is particularly preferable.

Ar¹ in Formula (1) represents an aromatic hydrocarbon group, and an aromatic hydrocarbon group having 6 to 30 carbon atoms is preferable and an aromatic hydrocarbon group having 6 to 20 carbon atoms is more preferable. As the aromatic hydrocarbon group, a phenyl group or a naphthyl group is preferable, and a phenyl group is more preferable. The aromatic hydrocarbon group represented by Ar¹ may have a substituent. Examples of the substituent include a halogen atom, a hydroxy group, a carboxy group, a sulfo group, an alkyl group, an aryl group, a heterocyclic group, an alkoxy group, an aryloxy group, an acyl group, an acyloxy group, an alkylthioether group, an arylthioether group, and a crosslinkable group.

Q¹ in Formula (1) represents a group represented by any one of Formula (Q-1), . . . , or Formula (Q-5), and is preferably a group represented by Formula (Q-1).

n1 represents an integer of 1 to the maximum number of substitutions of Ar¹, and is preferably an integer of 1 to 3, more preferably 1 or 2, and still more preferably 1. The maximum number of substitutions of Ar¹ refers to the maximum number of substituents which can be included in the aromatic hydrocarbon group represented by Ar¹, and in a case where Ar¹ is a phenyl group, the maximum number of substitutions is 5. Hereinafter, the above-described contents are the same in the description of the maximum number of substitutions.

The repeating unit (A) is preferably a repeating unit represented by Formula (2). According to this aspect, dispersibility of the coloring material in the coloring resin composition is good, and heat resistance of the obtained film can be further improved.

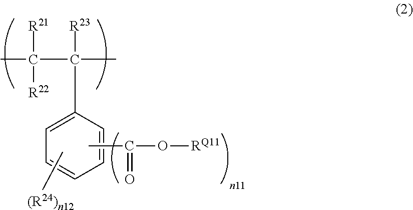

In Formula (2), R²¹ to R²³ each independently represent a hydrogen atom, an alkyl group, or an aryl group, R²⁴ represents a substituent, R^{Q11} represents a substituent, n11 represents an integer of 1 to 5, n12 represents an integer of 0 to 4, and n11+n12 is 1 to 5.

R²¹ and R²³ in Formula (2) each independently represent a hydrogen atom, an alkyl group, or an aryl group, and are preferably a hydrogen atom or an alkyl group and more preferably a hydrogen atom. The alkyl group and aryl group represented by R²¹ to R²³ have the same meaning as the alkyl group and aryl group represented R¹¹ to R¹³ in Formula (1), and the preferred ranges are also the same.

The substituent represented by R^{Q11} in Formula (2) has the same meaning as the substituent represented by R^{Q1} in Formula (Q-1) described above, and the preferred range is also the same.

Examples of the substituent represented by R²⁴ in Formula (2) include a halogen atom, a hydroxy group, a carboxy group, a sulfo group, an alkyl group, an aryl group, a heterocyclic group, an alkoxy group, an aryloxy group, an acyl group, an acyloxy group, an alkylthioether group, an arylthioether group, and a crosslinkable group.

n11 represents an integer of 1 to 5, and is preferably an integer of 1 to 3, more preferably 1 or 2, and still more preferably 1. n12 represents an integer of 0 to 4, and is preferably an integer of 0 to 3, more preferably 0 or 1, and still more preferably 0.

The repeating unit represented by Formula (2) is preferably a repeating unit represented by Formula (2a).

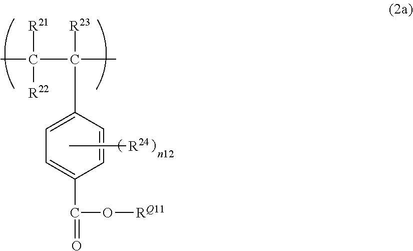

In Formula (2a), R²¹ to R²³ each independently represent a hydrogen atom, an alkyl group, or an aryl group, R²⁴ represents a substituent, R^{Q11} represents a substituent, and n12 represents an integer of 0 to 4.

From the viewpoint of expanding the process window, the content of the above-described repeating unit (A) in the specific resin is preferably 10 mol % or more, more preferably 20 mol % or more, and still more preferably 30 mol % or more with respect to the total molar amount of repeating units included in the specific resin. The upper limit is not particularly limited, and may be 100 mol % or less.

From the viewpoint of expanding the process window, the content of the above-described repeating unit (A) in the specific resin is preferably 5 mass % or more, more preferably 10 mass % or more, and still more preferably 15 mass % or more with respect to the mass of the specific resin. The upper limit is not particularly limited, and may be 100 mass % or less.

It is also preferable that the specific resin includes a repeating unit having an acid group, in addition to the above-described repeating unit (A). According to this aspect, dispersibility of the coloring material can be improved, and alkali developability can be improved. Examples of the acid group include a phenolic hydroxy group, a carboxy group, a sulfo group, and a phosphoric acid group, and a carboxy group is preferable. Examples of a structure of the repeating unit having an acid group include at least one structural repeating unit selected from a polyester repeating unit, a polyether repeating unit, a poly(meth)acrylic repeating unit, or a (poly)styrene repeating unit, and from the viewpoint of heat resistance of the obtained film, a (poly)styrene repeating unit or a poly(meth)acrylic repeating unit is preferable.

The content of the repeating unit having an acid group in the specific resin is preferably 30 to 95 mol %, more preferably 40 to 90 mol %, and still more preferably 50 to 85 mol % with respect to the total molar amount of repeating units included in the specific resin. In addition, the content of the repeating unit having an acid group in the specific resin is preferably 5 to 50 mass %, more preferably 10 to 40 mass %, and still more preferably 15 to 30 mass % with respect to the mass of the specific resin.

It is also preferable that the specific resin includes a repeating unit having a crosslinkable group, in addition to the above-described repeating unit (A). According to this aspect, it is easy to obtain a film having more excellent heat resistance. Examples of the crosslinkable group include an ethylenically unsaturated bond-containing group and a cyclic ether group. Examples of the ethylenically unsaturated bond-containing group include a (meth)acryloyl group, a (meth)acryloyloxy group, a (meth)acrylamide group, a vinylphenyl group, and an allyl group, and from the viewpoint of reactivity, a (meth)acryloyloxy group is preferable. Examples of the cyclic ether group include an epoxy group and an oxetanyl group. Examples of a structure of the repeating unit having a crosslinkable group include at least one structural repeating unit selected from a polyester repeating unit, a polyether repeating unit, a poly(meth)acrylic repeating unit, or a (poly)styrene repeating unit, and from the viewpoint of heat resistance of the obtained film, a (poly)styrene repeating unit or a poly(meth)acrylic repeating unit is preferable.

The content of the repeating unit having a crosslinkable group in the specific resin is preferably 20 to 90 mol %, more preferably 30 to 85 mol %, and still more preferably 40 to 80 mol % with respect to the total molar amount of repeating units included in the specific resin. In addition, the content of the repeating unit having a crosslinkable group in the specific resin is preferably 20 to 90 mass %, more preferably 30 to 85 mass %, and still more preferably 40 to 80 mass % with respect to the mass of the specific resin.

[Graft Polymer and Star Polymer]

The specific resin may be any of a linear polymer, a star polymer, or a graft polymer compound, but from the reason that it is easy to obtain a coloring resin composition with excellent storage stability, a graft polymer or a star polymer is preferable.

—Graft Polymer—In a case where the specific resin is a graft polymer, the above-described repeating unit (A) may be included in a main chain of the graft polymer or in a graft chain. In addition, each of the main chain and the graft chain may have the repeating unit (A). The graft chain is preferably a polymer chain having a molecular weight of 1000 to 10000 and having no acid group or basic group.

Examples of one preferred aspect of the graft polymer include a resin which has a repeating unit of a structure having a graft chain in which a main chain of a polyester repeating unit, a polyether repeating unit, a poly(meth)acrylic repeating unit, or a (poly)styrene repeating unit includes the above-described repeating unit (A) as a side chain.

The graft polymer may further have a repeating unit having an acid group or a repeating unit having a crosslinkable group.

—Star Polymer—

In a case where the specific resin is a star polymer, the specific resin is preferably a resin represented by Formula (S-1).

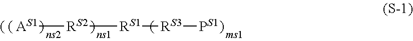

In Formula (S-1), R^{S1} represents an (ms1+ns1)-valent organic linking group, R^{S2}'s each independently represent a single bond or an (ns2+1)-valent linking group, A^{S1}'s each independently represent at least one group selected from the group consisting of a hydroxy group, a carboxy group, a sulfo group, a phosphoric acid group, and an amino group, R^{S3}'s each independently represent a single bond or a divalent linking group, P^{S1}'s each independently represent a polymer chain, ms1 represents an integer of 1 to 8, ns1 represents an integer of 2 to 9, ms1+ns1 is 3 to 10, and ns2 is an integer of 1 or more. In a case where ms is 1, P^{S1} is a polymer chain including the above-described repeating unit (A), and in a case where ms is 2, at least one P^{S1} of ms pieces P^{S1}'s is a polymer chain including the above-described repeating unit (A).

Examples of the (ms1+ns1)-valent organic linking group represented by R^{S1} in Formula (S-1) include a group composed of 1 to 100 carbon atoms, 0 to 10 nitrogen atoms, 0 to 50 oxygen atoms, 1 to 200 hydrogen atoms, and 0 to 20 sulfur atoms, and a group composed of 1 to 60 carbon atoms, 0 to 10 nitrogen atoms, 0 to 40 oxygen atoms, 1 to 120 hydrogen atoms, and 0 to 10 sulfur atoms is more preferable, a group composed of 1 to 50 carbon atoms, 0 to 10 nitrogen atoms, 0 to 30 oxygen atoms, 1 to 100 hydrogen atoms, and 0 to 7 sulfur atoms is still more preferable, and a group composed of 1 to 40 carbon atoms, 0 to 8 nitrogen atoms, 0 to 20 oxygen atoms, 1 to 80 hydrogen atoms, and 0 to 5 sulfur atoms is particularly preferable. Examples of the (ms1+ns1)-valent organic linking group represented by R^{S1} include a group (which may form a ring structure) composed of the following structural unit or a combination of two or more the following structural units.

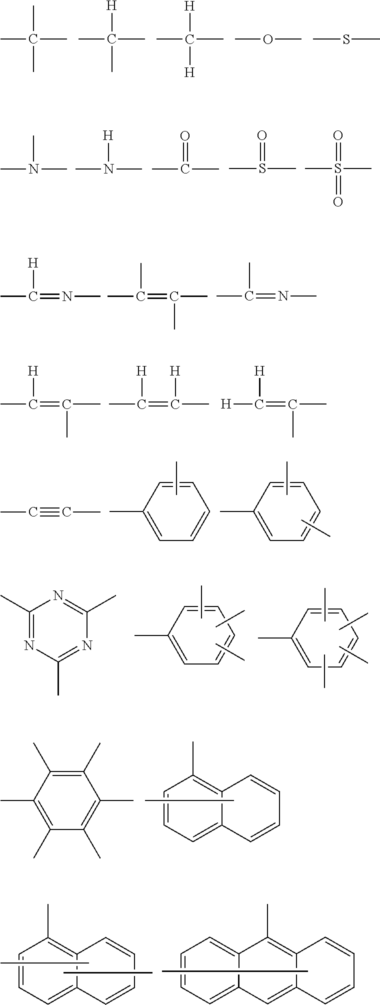

In Formula (S-1), examples of the (ns2+1)-valent linking group represented R^{S2} and the divalent linking group represented by R^{S3} include a group composed of 1 to 50 carbon atoms, 0 to 8 nitrogen atoms, 0 to 25 oxygen atoms, 1 to 100 hydrogen atoms, and 0 to 10 sulfur atoms, and a group composed of 1 to 30 carbon atoms, 0 to 6 nitrogen atoms, 0 to 15 oxygen atoms, 1 to 50 hydrogen atoms, and 0 to 7 sulfur atoms is preferable, and a group composed of 1 to 10 carbon atoms, 0 to 5 nitrogen atoms, 0 to 10 oxygen atoms, 1 to 30 hydrogen atoms, and 0 to 5 sulfur atoms is more preferable. Specific examples of the linking group represented by R^{S2} and R^{S3} include a group composed of one of the following structural units or a combination of two or more of the structural units.

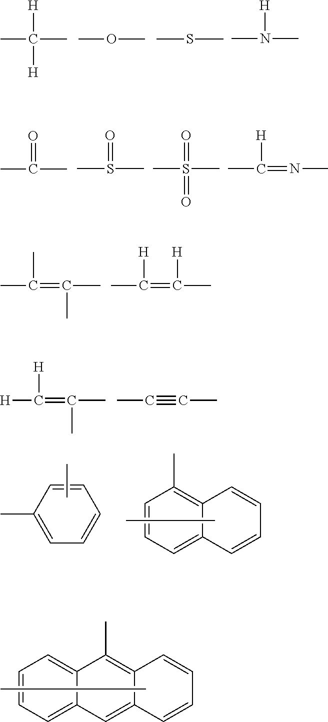

R^{S2} is preferably a single bond or a group composed of 1 to 30 carbon atoms, 0 to 6 nitrogen atoms, 0 to 15 oxygen atoms, 1 to 50 hydrogen atoms, and 0 to 7 sulfur atoms, and more preferably a single bond or a divalent group composed of 1 to 10 carbon atoms, 0 to 5 nitrogen atoms, 0 to 10 oxygen atoms, 1 to 30 hydrogen atoms, and 0 to 5 sulfur atoms.

R^{S3} is preferably a single bond or —S—, and more preferably —S—.

Examples of the polymer chain represented by P^{S1} include polymer chains including at least one structural repeating unit selected from a polyester repeating unit, a polyether repeating unit, a poly(meth)acrylic repeating unit, and a (poly)styrene repeating unit. Specific examples thereof include a polymer chain including at least one repeating unit selected from the above-described repeating unit (A), the above-described repeating unit represented by Formula (P1-1), the above-described repeating unit represented by Formula (P1-2), the above-described repeating unit represented by Formula (P1-3), the above-described repeating unit represented by Formula (P1-4), the above-described repeating unit represented by Formula (P1-5), or the above-described repeating unit represented by Formula (P1-6), and a polymer chain including the above-described repeating unit (A) is preferable. A weight-average molecular weight of the polymer chain is preferably 500 to 10000. In addition, the polymer chain represented by P^{S1} is also preferably a polymer chain having no acid group and basic group.

ms1 in Formula (S-1) represents an integer of 1 to 8, preferably 1 to 5, more preferably 1 to 4, and particularly preferably 2 to 4. ns1 in Formula (S-1) represents an integer of 2 to 9, preferably 2 to 8, more preferably 2 to 7, and particularly preferably 2 to 6. ns2 In Formula (S-1) represents an integer of 1 or more, preferably 1 or 10, more preferably 1 to 4, and still more preferably 1 or 2.

The star polymer represented by Formula (S-1) is preferably a star polymer represented by Formula (S-2).

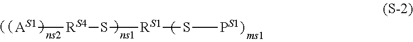

R^{S1}, A^{S1}, P^{S1} ns1, ns2, and ms1 in Formula (S-2) have the same meaning as R^{S1}, A^{S1}, P^{S1} ns1, ns2, and ms1 in Formula (S-1), respectively, and the preferred aspects thereof are also the same.

R^{S4} in Formula (S-2) represents a single bond or an (ns2+1)-valent linking group. Examples of the (ns2+1)-valent linking group represented by R^{S4} include a group composed of 1 to 50 carbon atoms, 0 to 8 nitrogen atoms, 0 to 25 oxygen atoms, 1 to 100 hydrogen atoms, and 0 to 10 sulfur atoms, and a group composed of 1 to 30 carbon atoms, 0 to 6 nitrogen atoms, 0 to 15 oxygen atoms, 1 to 50 hydrogen atoms, and 0 to 7 sulfur atoms is preferable, and a group composed of 1 to 10 carbon atoms, 0 to 5 nitrogen atoms, 0 to 10 oxygen atoms, 1 to 30 hydrogen atoms, and 0 to 5 sulfur atoms is more preferable. Specific examples of the linking group represented by R^{S4} include a group composed of one of the following structural units or a combination of two or more of the structural units.

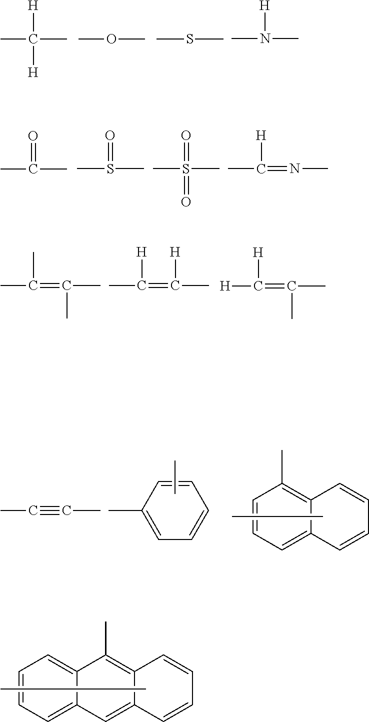

R^{S4} is preferably a single bond or a group composed of 1 to 30 carbon atoms, 0 to 6 nitrogen atoms, 0 to 15 oxygen atoms, 1 to 50 hydrogen atoms, and 0 to 7 sulfur atoms, and more preferably a single bond or a divalent group composed of 1 to 10 carbon atoms, 0 to 5 nitrogen atoms, 0 to 10 oxygen atoms, 1 to 30 hydrogen atoms, and 0 to 5 sulfur atoms.

[Molecular Weight]

A weight-average molecular weight (Mw) of the specific resin is preferably 5000 to 100000, more preferably 10000 to 100000, and still more preferably 10000 to 50000.

[Molar Absorption Coefficient]

The maximum value of a molar absorption coefficient of the specific resin at a wavelength of 400 to 1100 nm is preferably 0 to 1000 L·mol⁻¹·cm⁻¹ and more preferably 0 to 100 L·mol⁻¹·cm⁻¹.

[Acid Group]

From the viewpoint of improving alkali developability, the specific resin preferably has an acid group. Examples of the acid group include a phenolic hydroxy group, a carboxy group, a sulfo group, and a phosphoric acid group, and a carboxy group is preferable. The acid group may be included in the above-described repeating unit (A), or may be included in a repeating unit different from the above-described repeating unit (A). From the viewpoint of improving film-forming properties and alkali developability, an acid value of the specific resin is preferably 20 to 200 mgKOH/g. The lower limit of the above-described acid value is preferably 30 mgKOH/g or more and more preferably 50 mgKOH/g or more. The upper limit of the above-described acid value is preferably 150 mgKOH/g or less.

[Crosslinkable Group]

The specific resin preferably has a crosslinkable group. According to this aspect, it is easy to obtain a film having more excellent heat resistance. Examples of the crosslinkable group include an ethylenically unsaturated bond-containing group and a cyclic ether group. Examples of the ethylenically unsaturated bond-containing group include a (meth)acryloyl group, a (meth)acryloyloxy group, a (meth)acrylamide group, a vinylphenyl group, and an allyl group, and from the viewpoint of reactivity, a (meth)acryloyloxy group is preferable. Examples of the cyclic ether group include an epoxy group and an oxetanyl group. The crosslinkable group may be included in the above-described repeating unit (A), or may be included in a repeating unit different from the above-described repeating unit (A).

In a case where the specific resin includes an ethylenically unsaturated bond-containing group, from the viewpoint of storage stability and curing properties, an ethylenically unsaturated bond-containing group value (hereinafter, also referred to as a C═C value) of the specific resin is preferably 0.01 to 5 mmol/g. The lower limit of the C═C value is preferably 0.02 mmol/g or more, more preferably 0.03 mmol/g or more, still more preferably 0.05 mmol/g or more, and particularly preferably 0.10 mmol/g or more. The upper limit of the above-described C═C value is preferably 3 mmol/g or less, more preferably 2 mmol/g or less, still more preferably 1.5 mmol/g or less, and particularly preferably 1 mmol/g or less.

[Heat Resistance]

The specific resin preferably has a 5 mass % reduction temperature of 280° C. or higher, more preferably 300° C. or higher, and still more preferably 320° C. or higher by a thermogravimetry/differential thermal analysis (TG/DTA) under a nitrogen atmosphere. The upper limit of the above-described 5 mass % reduction temperature is not particularly limited, and for example, it is sufficient to be 1,000° C. or lower. The 5 mass % reduction temperature is determined by a known TG/DTA measuring method as a temperature at which a mass reduction rate is 5% in a case of being allowed to stand at a specific temperature for 5 hours under a nitrogen atmosphere.

In addition, the specific resin preferably has a mass reduction rate of 10% or less, more preferably 5% or less, and still more preferably 2% or less in a case of being allowed to stand at 300° C. for 5 hours under a nitrogen atmosphere. The lower limit of the above-described mass reduction rate is not particularly limited, and may be 0% or more.

The mass reduction rate is a value calculated as a proportion of mass reduction in the specific resin before and after being allowed to stand at 300° C. for 5 hours under a nitrogen atmosphere.

[Synthesis Method]

A method for synthesizing the specific resin is not particularly limited, and the specific resin can be synthesized by a known method.

### Specific Example

Specific examples of the specific resin are shown below, but the present invention is not limited thereto. In the following chemical formulae, the description of “S-Polym” in Formulae (AA-1) to (AA-15) indicates that the polymer chain of the structure in which the repeating unit of the structure indicated by “Polym” is bonded by the number of subscripts is bonded to the sulfur atom (S). In addition, two of *'s in R of Formulae (AA-16) to (AA-18) are bonded to the structure shown in square brackets on the left side, and four thereof are bonded to the structure shown in square brackets on the right side.

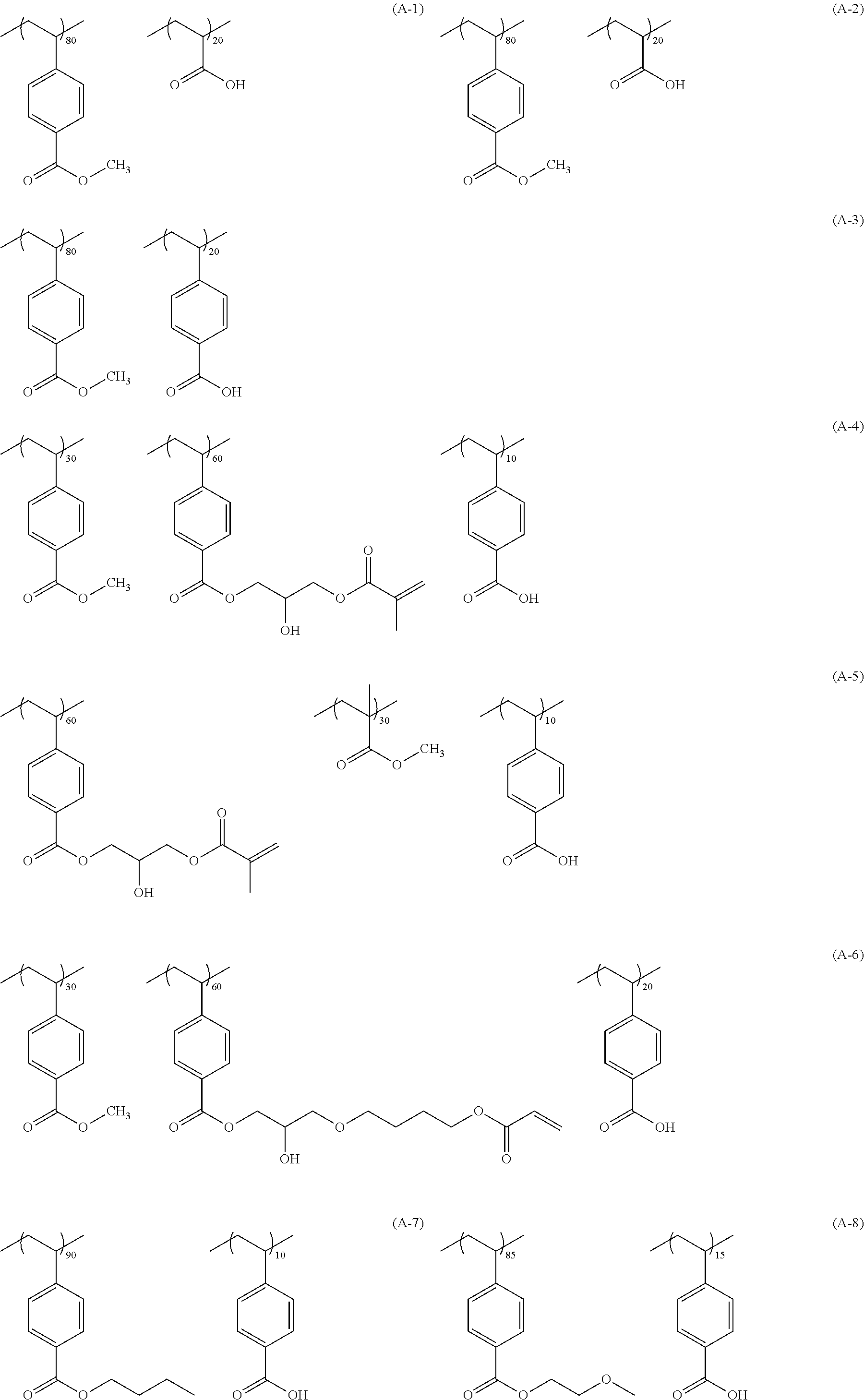

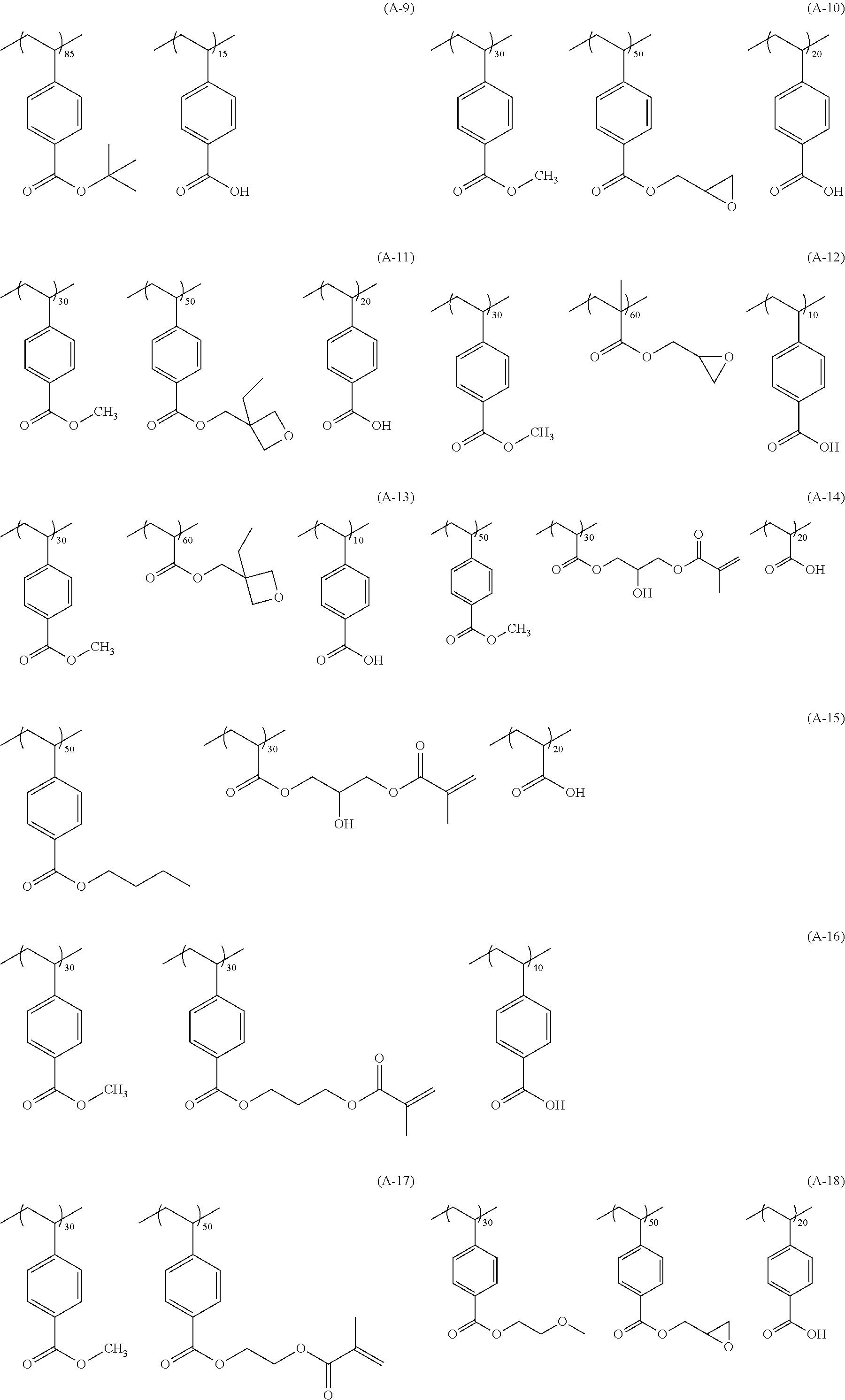

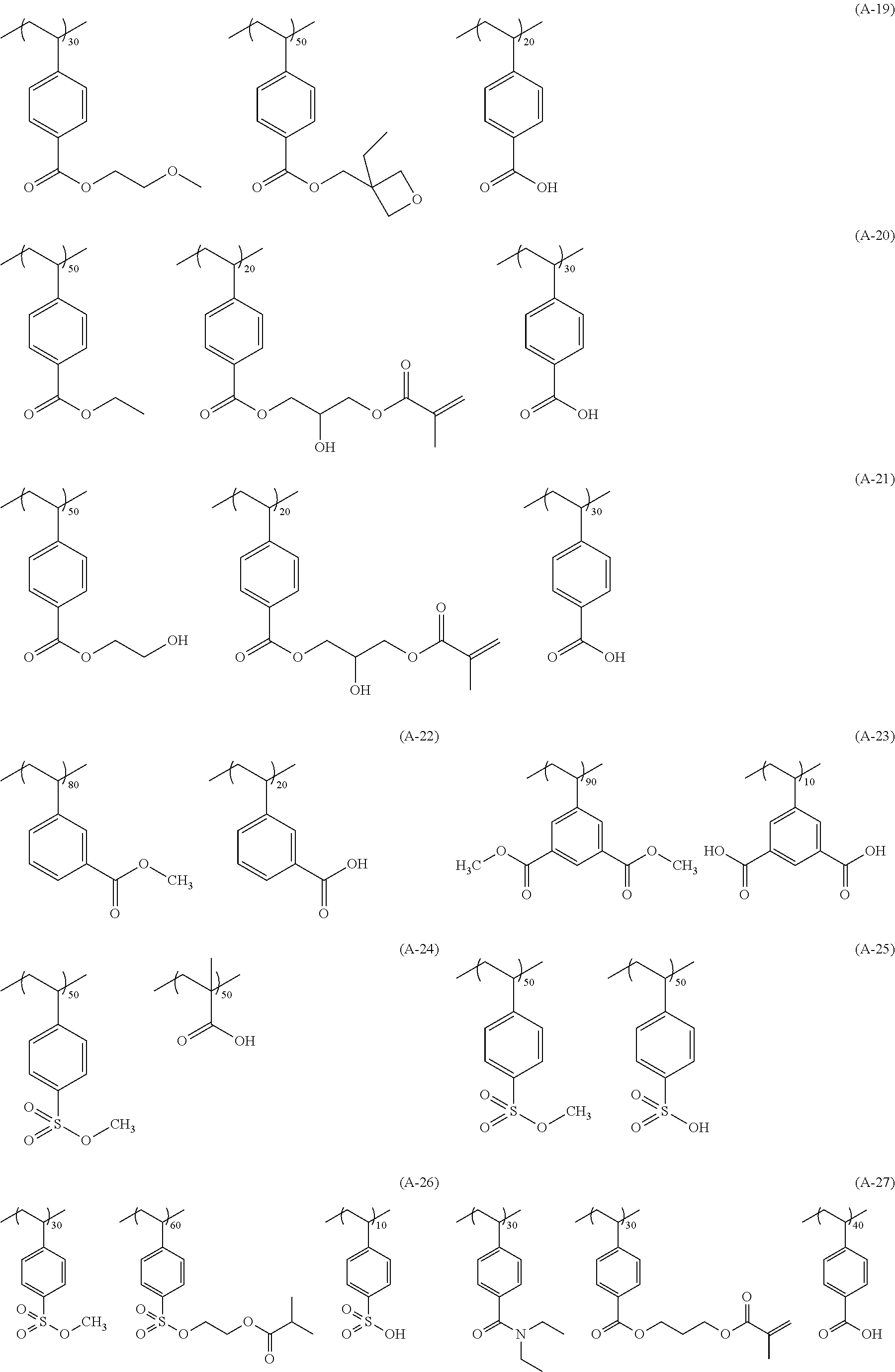

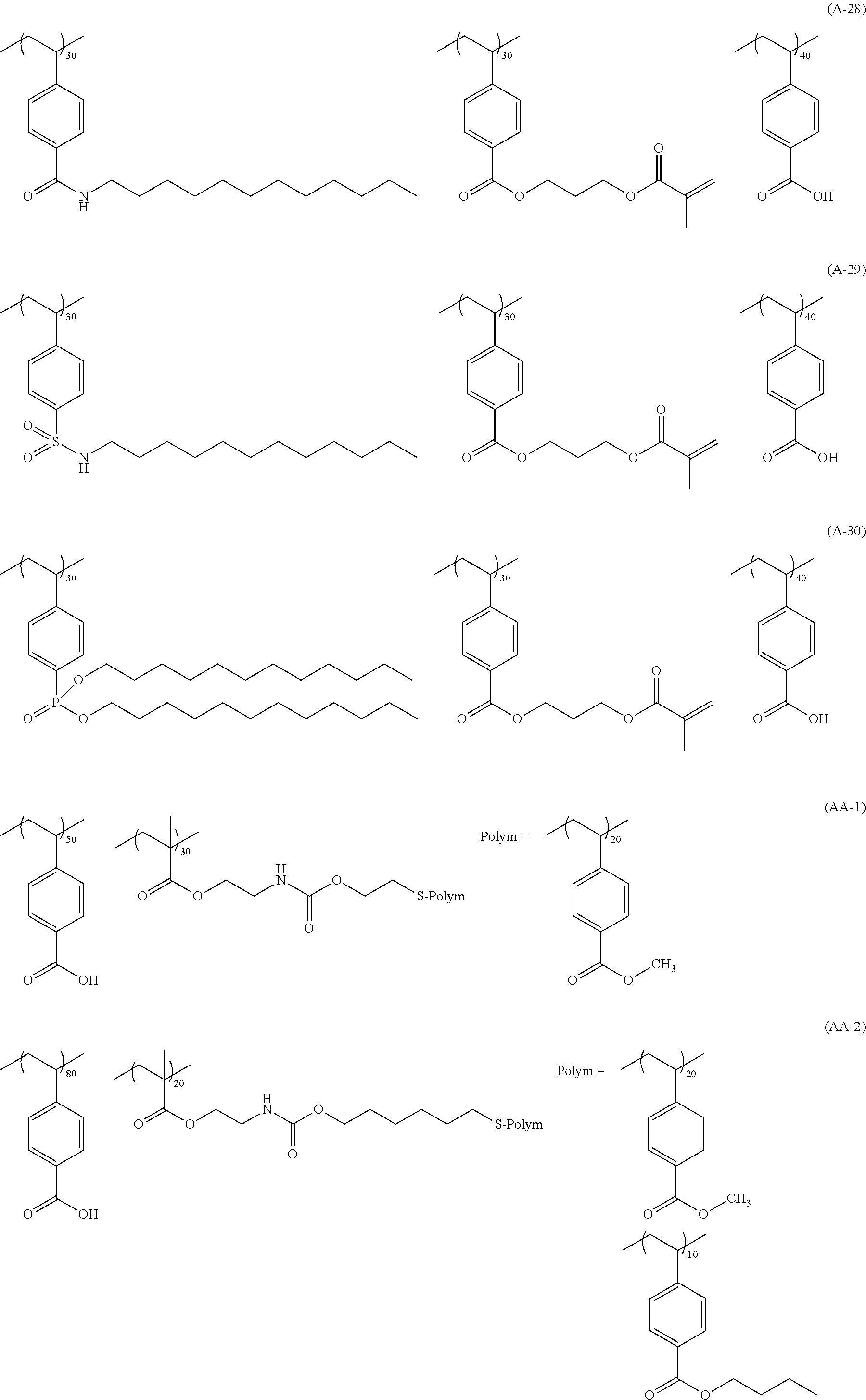

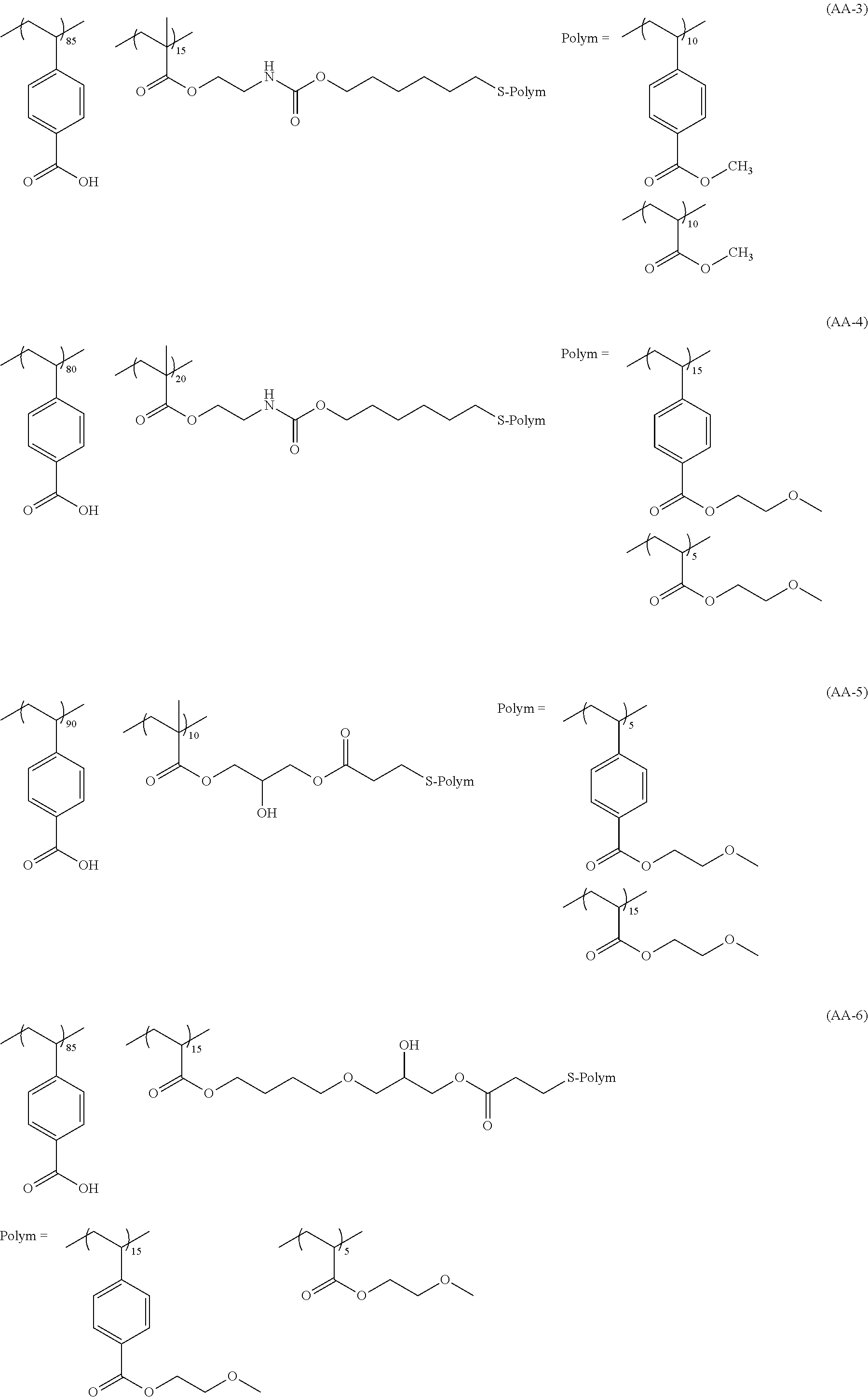

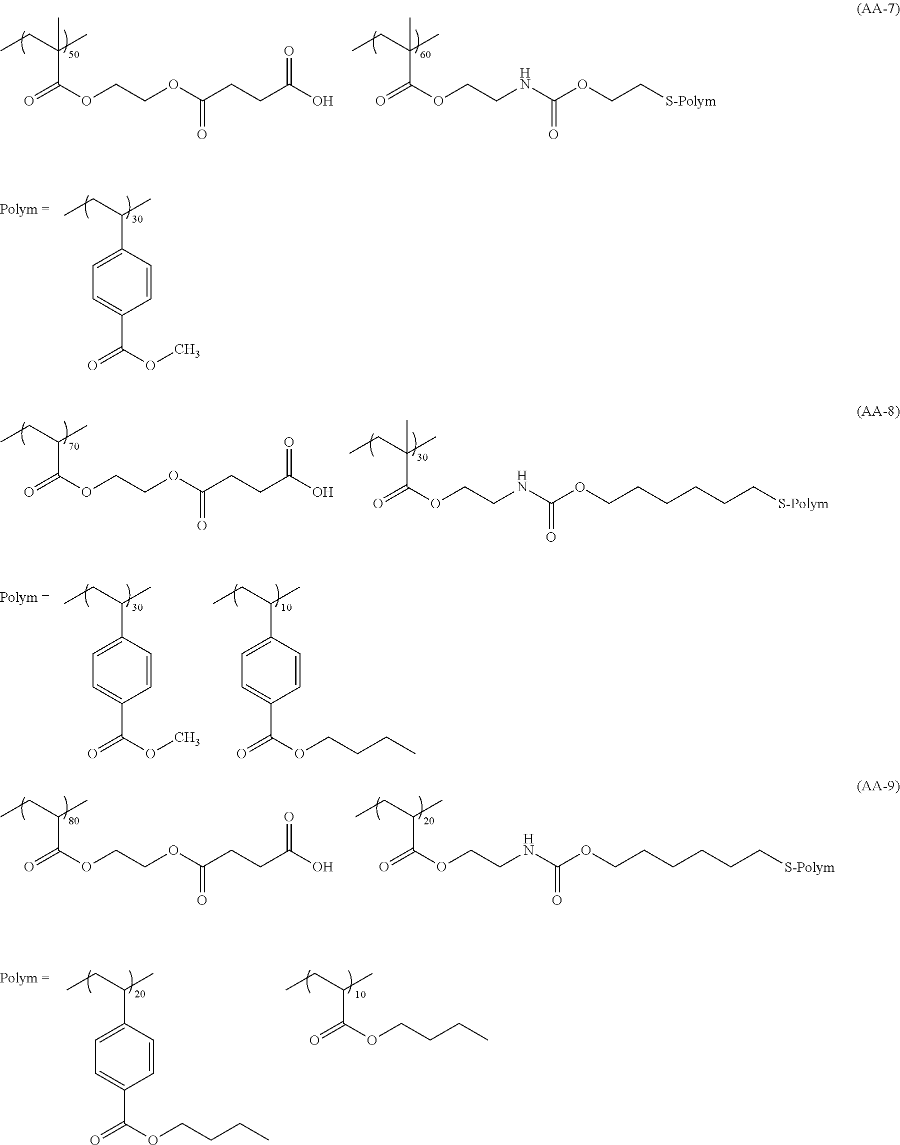

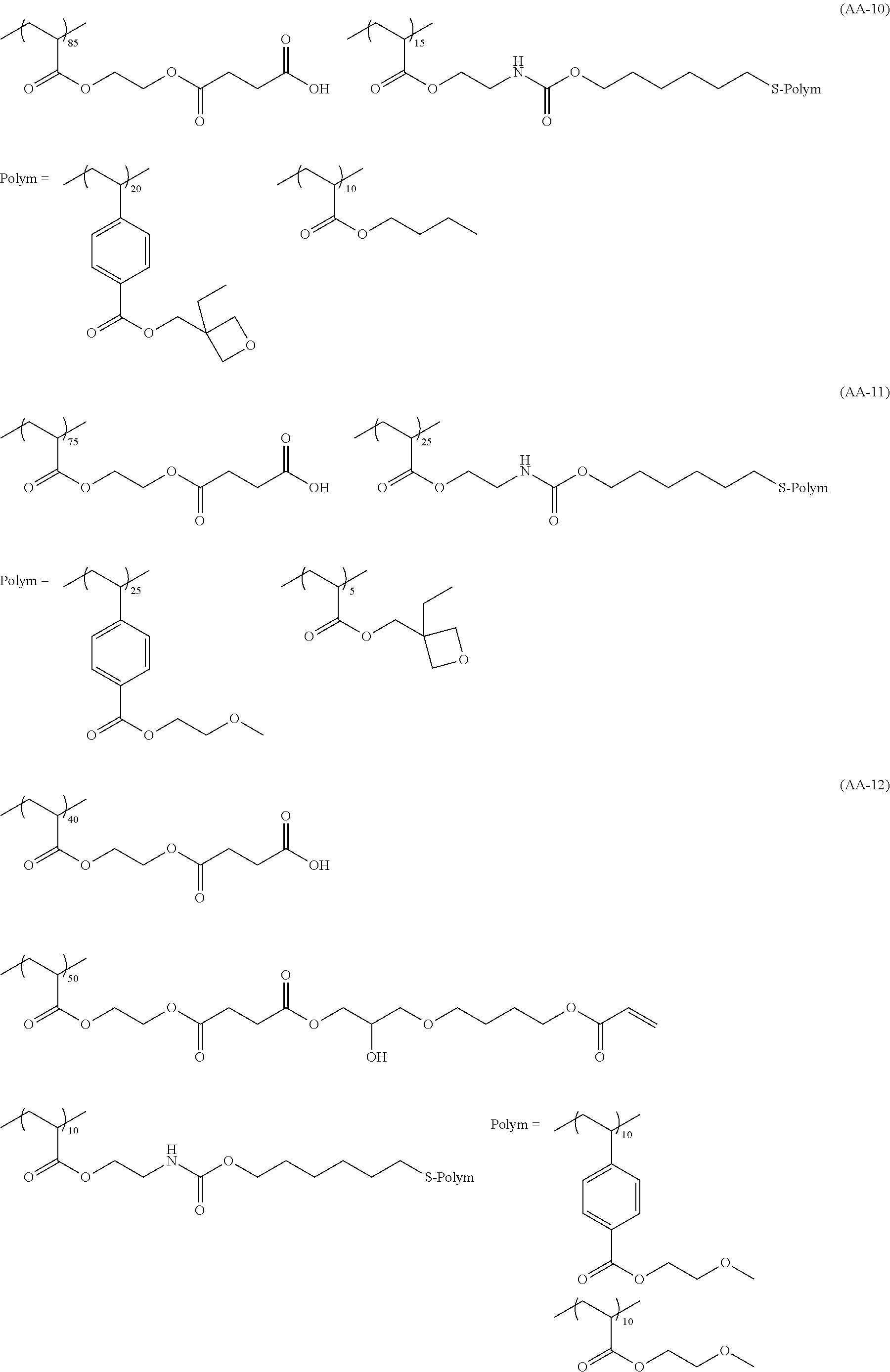

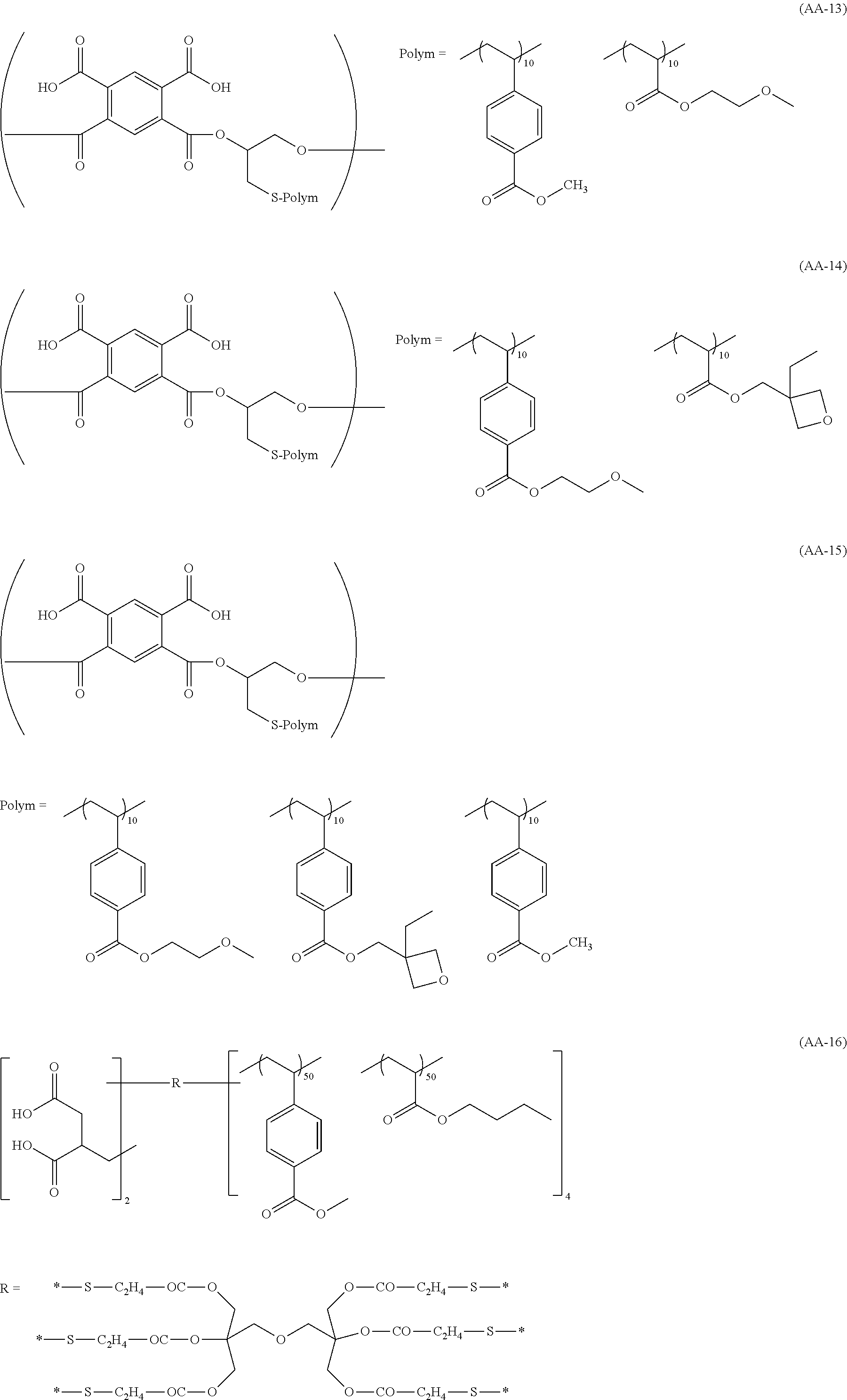

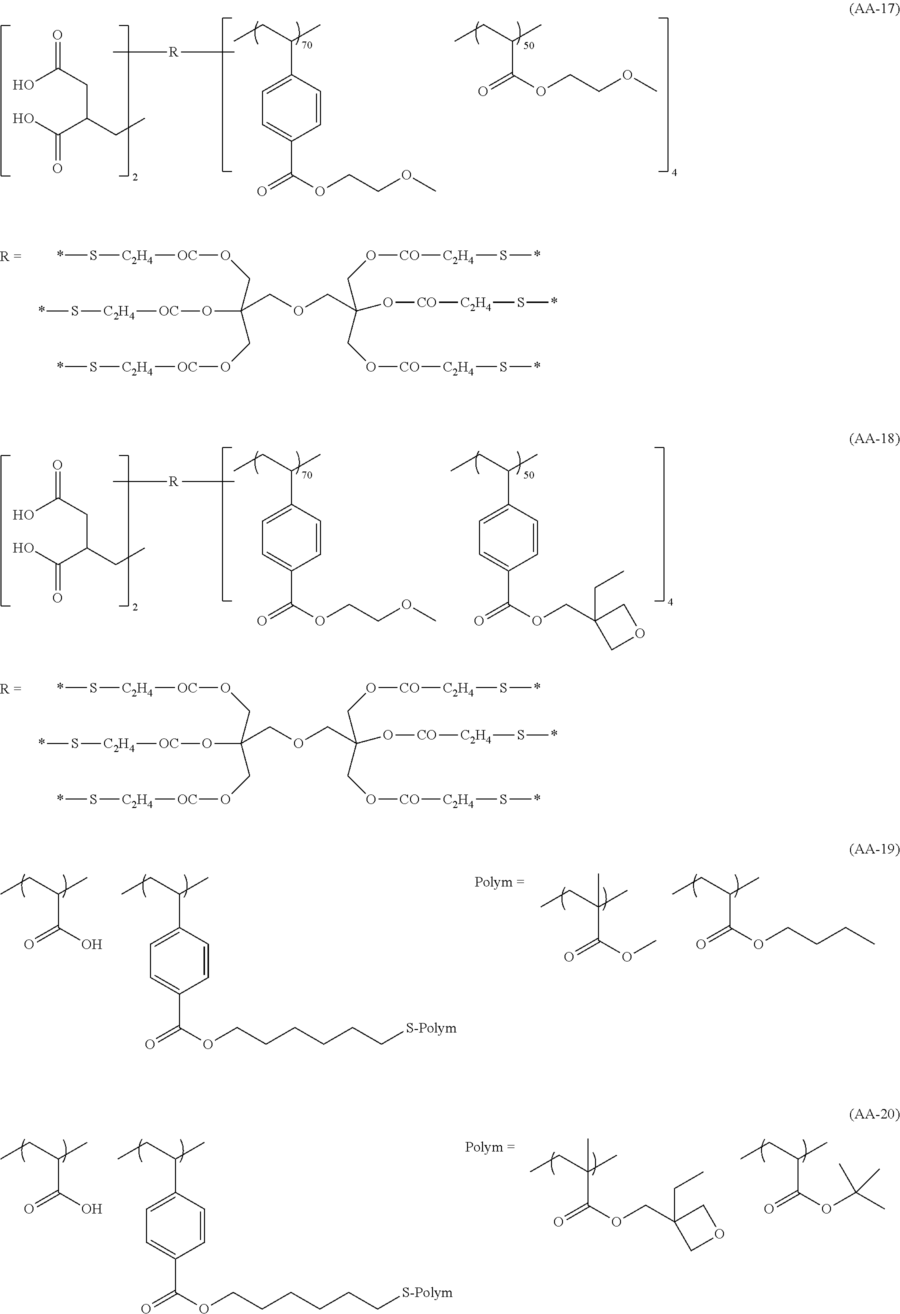

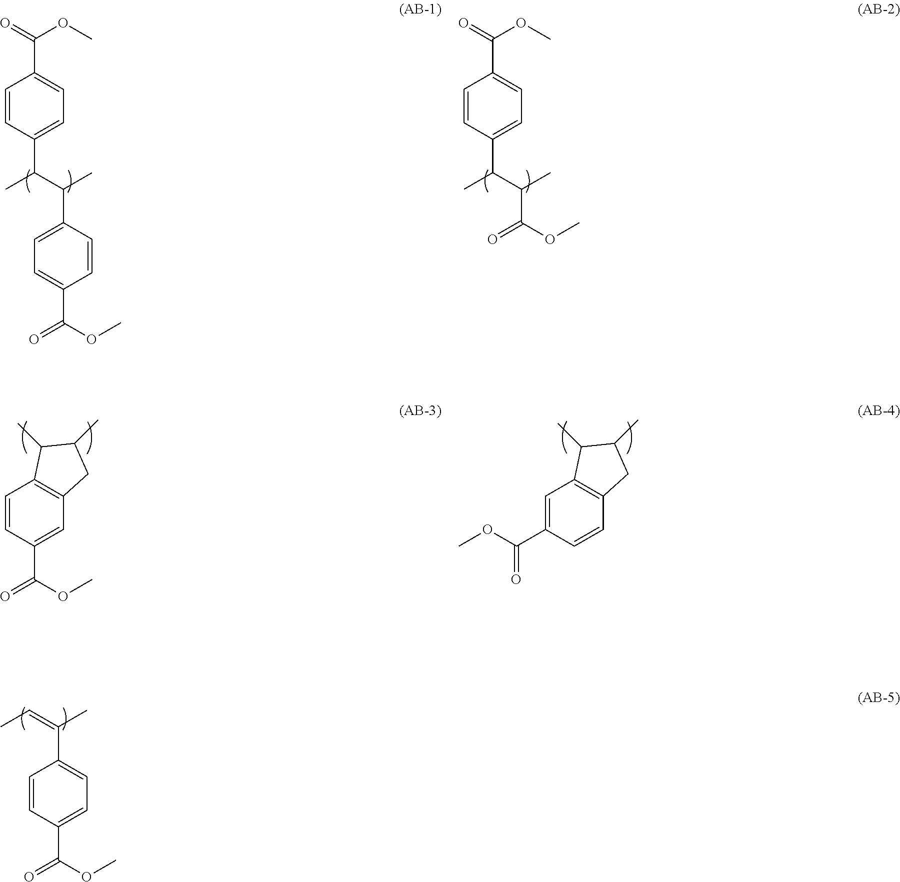

[Content]

A content of the specific resin in the coloring resin composition according to the embodiment of the present invention is preferably 10 to 95 mass % with respect to the total solid content of the coloring resin composition. The lower limit is more preferably 20 mass % or more and still more preferably 30 mass % or more. The upper limit is more preferably 90 mass % or less and still more preferably 85 mass % or less.

The coloring resin composition according to the embodiment of the present invention may contain the specific resin alone or in combination of two or more kinds thereof. In a case where two or more kinds of specific resins are used in combination, the total amount thereof is preferably within the above-described range.

In addition, in the present invention, in the components in which the coloring material is excepted from the total solid content of the coloring resin composition, the specific resin is included preferably in an amount of 20 mass % or more, more preferably in an amount of 30 mass % or more, and still more preferably in an amount of 40 mass % or more. The upper limit may be 100 mass %, 90 mass % or less, or 85 mass % or less. In a case where the content of the specific resin is within the above-described range, it is easy to form a film having excellent heat resistance, and it is easy to suppress film contraction after heating. Further, in a case where an inorganic film is formed on a surface of the film obtained using the coloring resin composition according to the embodiment of the present invention, it is also possible to suppress the occurrence of cracks in the inorganic film even in a case where this laminate is exposed to a high temperature.

In addition, the total content of the coloring material and the above-described specific resin in the total solid content of the coloring resin composition is preferably 25 to 100 mass %. The lower limit is more preferably 30 mass % or more and still more preferably 40 mass % or more. The upper limit is more preferably 90 mass % or less and still more preferably 80 mass % or less.

<Other Resins>

The coloring resin composition according to the embodiment of the present invention may include a resin other than the above-described specific resin as the resin. Examples of other resins include a resin having alkali developability and a resin as a dispersant.

[Resin Having Alkali Developability]

A weight-average molecular weight (Mw) of the resin having alkali developability is preferably 3000 to 2000000. The upper limit is more preferably 1000000 or less and still more preferably 500000 or less. The lower limit is more preferably 4000 or more and still more preferably 5000 or more.

Examples of the resin having alkali developability include a (meth)acrylic resin, a polyimine resin, a polyether resin, a polyolefin resin, a cyclic olefin resin, a polyester resin, and a styrene resin, and a (meth)acrylic resin or a polyimine resin is preferable and a (meth)acrylic resin is more preferable. In addition, as the other resin, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, and resins described in JP2017-066240A can also be used.

In addition, as the resin having alkali developability, it is preferable to use a resin having an acid group. According to this aspect, developability of the coloring resin composition can be further improved. Examples of the acid group include a phenolic hydroxy group, a carboxy group, a sulfo group, a phosphoric acid group, a phosphonic acid group, an active imide group, and a sulfonamide group, and a carboxy group is preferable. The resin having an acid group can be used, for example, as an alkali-soluble resin.

The resin having alkali developability preferably includes a repeating unit having an acid group in the side chain, and more preferably includes 1 to 70 mol % of repeating units having an acid group in the side chain with respect to the total repeating units of the resin. The upper limit of the content of the repeating unit having an acid group in the side chain is preferably 50 mol % or less and more preferably 40 mol % or less. The lower limit of the content of the repeating unit having an acid group in the side chain is preferably 2 mol % or more and more preferably 5 mol % or more.

An acid value of the resin having alkali developability is preferably 200 mgKOH/g or less, more preferably 150 mgKOH/g or less, still more preferably 120 mgKOH/g or less, and particularly preferably 100 mgKOH/g or less. In addition, an acid value of the resin having an acid group is preferably 5 mgKOH/g or more, more preferably 10 mgKOH/g or more, and still more preferably 20 mgKOH/g or more.

The resin having alkali developability also preferably has an ethylenically unsaturated bond-containing group. Examples of the ethylenically unsaturated bond-containing group include a vinyl group, an allyl group, and a (meth)acryloyl group, and an allyl group or a (meth)acryloyl group is preferable and a (meth)acryloyl group is more preferable.

The resin having an ethylenically unsaturated bond-containing group preferably includes a repeating unit having an ethylenically unsaturated bond-containing group in the side chain, and more preferably includes 5 to 80 mol % of the repeating unit having an ethylenically unsaturated bond-containing group in the side chain with respect to the total repeating units of the resin. The upper limit of the content of the repeating unit having an ethylenically unsaturated bond-containing group in the side chain is preferably 60 mol % or less and more preferably 40 mol % or less. The lower limit of the content of the repeating unit having an ethylenically unsaturated bond-containing group in the side chain is preferably 10 mol % or more and more preferably 15 mol % or more.

It is also preferable that the resin having alkali developability includes a repeating unit derived from a monomer component including a compound represented by Formula (ED1) and/or a compound represented by Formula (ED2) (hereinafter, these compounds may be referred to as an “ether dimer”).

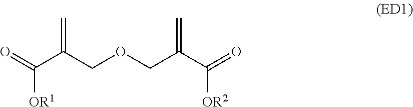

In Formula (ED1), R¹ and R² each independently represent a hydrogen atom or a hydrocarbon group having 1 to 25 carbon atoms, which may have a substituent.

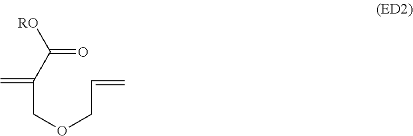

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

It is also preferable that the resin having alkali developability includes a repeating unit derived from a compound represented by Formula (X).

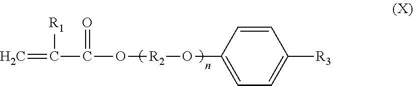

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

Examples of the resin having alkali developability include resins having the following structures. In the following structural formulae, Me represents a methyl group.

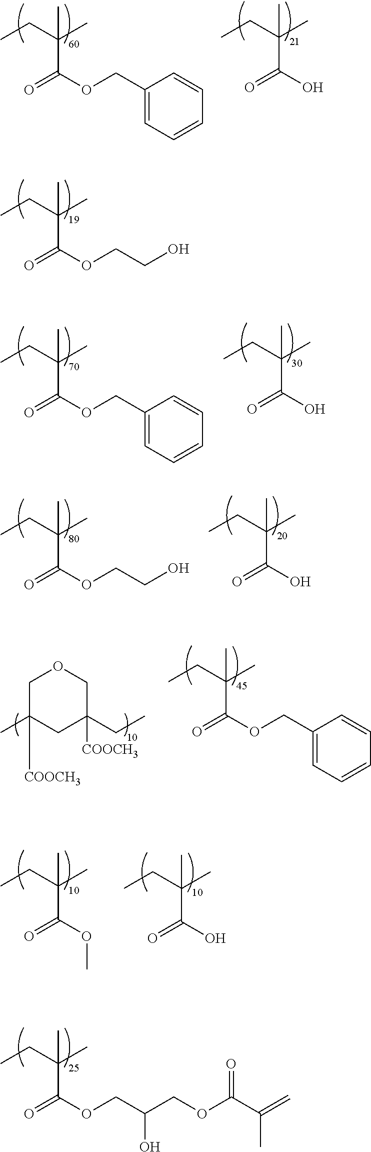

[Dispersant]

The coloring resin composition according to the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxy group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a repeating unit having an acid group.

It is also preferable that the resin used as a dispersant is a graft resin. Examples of the graft resin include resins described in paragraph Nos. 0025 to 0094 of JP2012-255128A, the contents of which are incorporated herein by reference.

It is also preferable that the resin used as a dispersant is a polyimine-based dispersant (polyimine resin) including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. Examples of the polyimine-based dispersant include resins described in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

A commercially available product is also available as the dispersant, and specific examples thereof include DISPERBYK series (for example, DISPERBYK-111, 161, and the like) manufactured by BYK Chemie, and Solsperse series (for example, Solsperse 36000) manufactured by Lubrizol Corporation. The dispersing agents described in paragraph Nos. 0041 to 0130 of JP2014-130338A can also be used, the contents of which are incorporated herein by reference. In addition, as the dispersant, compounds described in JP2018-150498A, JP2017-100116A, JP2017-100115A, JP2016-108520A, JP2016-108519A, and JP2015-232105A may be used.

The resin described as a dispersant can be used for an application other than the dispersant. For example, the resin can also be used as a binder.

The content of the total resin component in the total solid content of the coloring resin composition is preferably 10 to 95 mass %. The lower limit is more preferably 20 mass % or more and still more preferably 30 mass % or more. The upper limit is more preferably 90 mass % or less and still more preferably 85 mass % or less.

In addition, in the coloring resin composition, the content of the other resins described above is preferably 230 parts by mass or less, more preferably 200 parts by mass or less, and still more preferably 150 parts by mass or less with respect to 100 parts by mass of the above-described specific resin. The lower limit may be 0 part by mass, 5 parts by mass or more, or 10 parts by mass or more. In addition, it is also preferable that the coloring resin composition does not substantially include the above-described other resins. According to this aspect, it is easy to form a film having more excellent heat resistance. The case where the resin composition does not substantially include the other resins means that the content of the other resins in the total solid content of the resin composition is 0.1 mass % or less, preferably 0.05 mass % or less, and more preferably 0 mass %.

<Organic Solvent>

The coloring resin composition according to the embodiment of the present invention contains an organic solvent. Basically, the organic solvent is not particularly limited as long as it satisfies the solubility of the respective components and the application properties of the coloring resin composition. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph No. 0223 of WO2015/166779A, the contents of which are incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, 3-butoxy-N,N-dimethylpropanamide, γ-butyrolactone, and N-methyl-2-pyrrolidone. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015). Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms but having a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the organic solvent in the coloring resin composition is preferably 10 to 95 mass %, more preferably 20 to 90 mass %, and still more preferably 30 to 90 mass %.

<Pigment Derivative>

The coloring resin composition according to the embodiment of the present invention can contain a pigment derivative. Examples of the pigment derivative include a compound having a structure in which a part of a chromophore is substituted with an acid group, a basic group, or a phthalimidomethyl group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex-based skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. As the acid group included in the pigment derivative, a sulfo group or a carboxy group is preferable and a sulfo group is more preferable. As the basic group included in the pigment derivative, an amino group is preferable and a tertiary amino group is more preferable.

As the pigment derivative, a pigment derivative having excellent visible light transparency (hereinafter, also referred to as a transparent pigment derivative) can be used. The maximum value (εmax) of the molar absorption coefficient of the transparent pigment derivative in a wavelength region of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, JP2008-081565A, and JP2019-109512A.

The content of the pigment derivative is preferably 1 to 30 parts by mass and still more preferably 3 to 20 parts by mass with respect to 100 parts by mass of the pigment. The pigment derivative may be used singly or in combination of two or more kinds thereof

<Polymerizable Compound>

The coloring resin composition according to the embodiment of the present invention can contain a polymerizable compound. The polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, it is possible to suppress generation of development residues. Examples of the acid group include a carboxy group, a sulfo group, and a phosphoric acid group, and a carboxy group is preferable. Examples of a commercially available product of the polymerizable compound having an acid group include ARONIX M-305, M-510, M-520, and ARONIX TO-2349 (manufactured by TOAGOSEI CO., LTD.). An acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600, AI-600, and LINC-202UA (manufactured by KYOEISHA CHEMICAL Co., Ltd.) can also be used.

In a case of containing a polymerizable compound, the content of the polymerizable compound in the total solid content of the coloring resin composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof

<Photopolymerization Initiator>

The coloring resin composition according to the embodiment of the present invention can contain a photopolymerization initiator. The photopolymerization initiator is not particularly limited, and can be appropriately selected from known photopolymerization initiators. For example, a compound having photosensitivity to rays in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton, a compound having an oxadiazole skeleton, a compound having an imidazole skeleton, and the like), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a biimidazole compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from a biimidazole compound, an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of the biimidazole compound include 2,2-bis(2-chlorophenyl)-4,4′,5,5′-tetraphenylbiimidazole, 2,2′-bis(o-chlorophenyl)-4,4′,5,5-tetrakis(3,4,5-trimethoxyphenyl)-1,2′-biimidazole, 2,2′-bis(2,3-dichlorophenyl)-4,4′,5,5′-tetraphenylbiimidazole, and 2,2′-bis (o-chlorophenyl)-4,4,5,5′-tetraphenyl-1,2′-biimidazole. Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), and Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation;

photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

In addition, as the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound are shown below, but the present invention is not limited thereto.

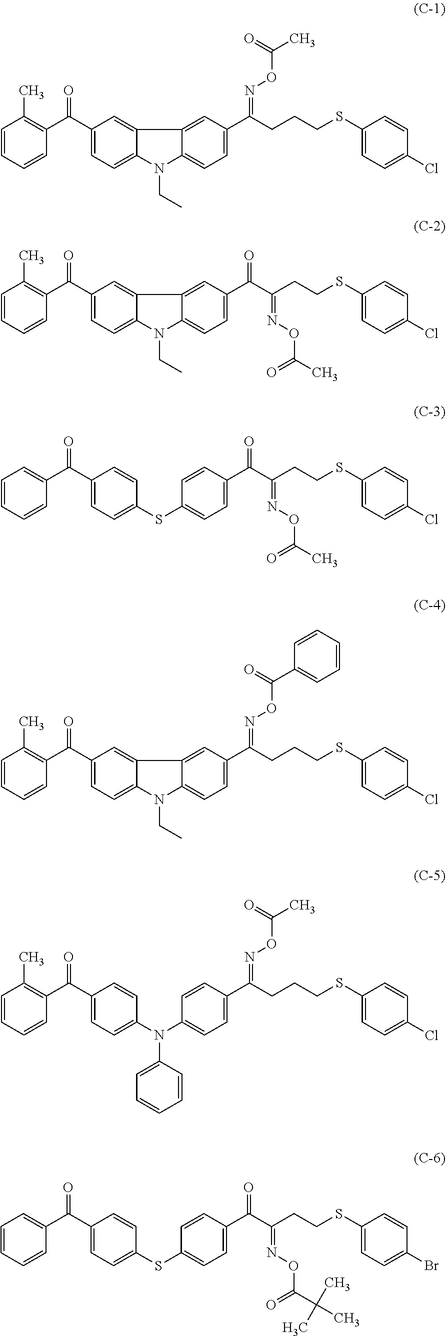 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

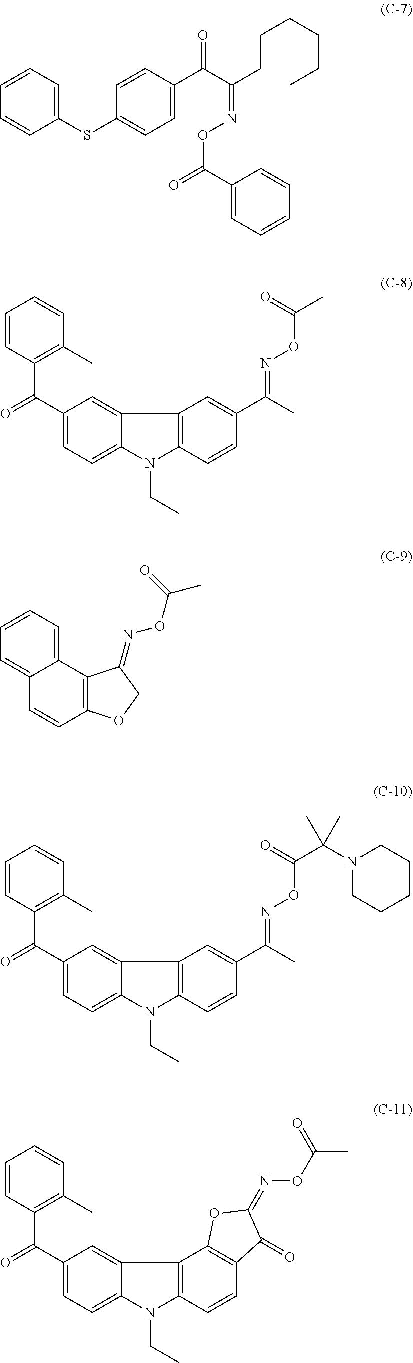 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

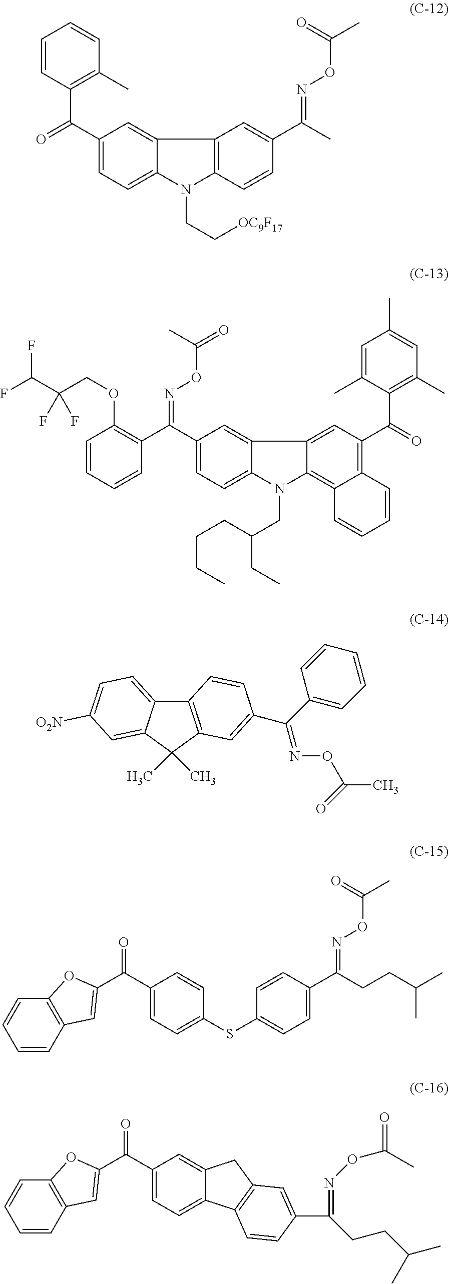

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring resin composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime compound described in JP6469669B.

In a case of containing a photopolymerization initiator, the content of the photopolymerization initiator in the total solid content of the coloring resin composition is preferably 0.1 to 30 mass %. The lower limit is preferably 0.5 mass % or more and more preferably 1 mass % or more. The upper limit is preferably 20 mass % or less and more preferably 15 mass % or less. The photopolymerization initiator may be used singly or in combination of two or more kinds thereof

<Silane Coupling Agent>

The coloring resin composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the coloring resin composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof

<Curing Accelerator>

For the purpose of promoting the reaction of the resin and the polymerizable compound and lowering the curing temperature, the coloring resin composition according to the embodiment of the present invention can further contain a curing accelerator. As the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used.

In a case where the coloring resin composition according to the embodiment of the present invention contains a curing accelerator, the content of the curing accelerator is preferably 0.3 to 8.9 mass % and more preferably 0.8 to 6.4 mass % with respect to the total solid content of the coloring resin composition.

<Polymerization Inhibitor>

The coloring resin composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. The content of the polymerization inhibitor in the total solid content of the coloring resin composition is preferably 0.0001 to 5 mass %.

<Surfactant>

The coloring resin composition according to the embodiment of the present invention can contain a surfactant. As the surfactant, various surfactants such as a fluorine-based surfactant, a nonionic surfactant, a cationic surfactant, an anionic surfactant, or a silicon-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the coloring resin composition, liquid characteristics (particularly, fluidity) are further improved, and liquid saving properties can be further improved. In addition, it is possible to form a film with a small thickness unevenness.

The fluorine content in the fluorine-based surfactant is suitably 3 to 40 mass %, and more preferably 5 to 30 mass % and particularly preferably 7% to 25 mass %. The fluorine-based surfactant in which the fluorine content is within the above-described range is effective in terms of the evenness of the thickness of the coating film or liquid saving properties and the solubility of the surfactant in the coloring resin composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

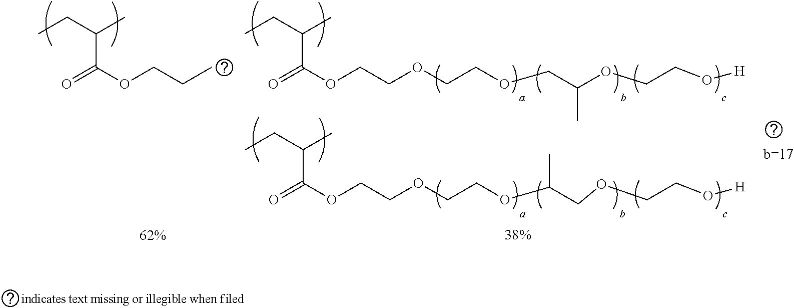

A weight-average molecular weight of the above-described compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

The content of the surfactant in the total solid content of the coloring resin composition is preferably 0.001 mass % to 5.0 mass % and more preferably 0.005 to 3.0 mass %. The surfactant may be used singly or in combination of two or more kinds thereof. In a case of using two or more kinds thereof, the total amount thereof is preferably within the above-described range.

<Ultraviolet Absorber>

The coloring resin composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. The content of the ultraviolet absorber in the total solid content of the coloring resin composition is preferably 0.01 to 10 mass % and more preferably 0.01 to 5 mass %. The ultraviolet absorber may be used singly or in combination of two or more kinds thereof. In a case where two or more kinds thereof are used, it is preferable that the total amount thereof is within the above-described range.

<Antioxidant>

The coloring resin composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. The content of the antioxidant in the total solid content of the coloring resin composition is preferably 0.01 to 20 mass % and more preferably 0.3 to 15 mass %. The antioxidant may be used singly or in combination of two or more kinds thereof. In a case where two or more kinds thereof are used, it is preferable that the total amount thereof is within the above-described range.

<Other Components>

Optionally, the coloring resin composition according to the embodiment of the present invention may further contain a sensitizer, a filler, a thermal curing accelerator, a plasticizer, and other auxiliary agents (for example, conductive particles, an anti-foaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring resin composition may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of a film to be obtained, the coloring resin composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The coloring resin composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

In the coloring resin composition according to the embodiment of the present invention, the content of liberated metal which is not bonded to or coordinated with a pigment or the like is preferably 100 ppm or less, more preferably 50 ppm or less, and still more preferably 10 ppm or less, it is particularly preferable to not contain the liberated metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the coloring resin composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the coloring resin composition include washing with ion exchange water, filtration, ultrafiltration, and purification with an ion exchange resin.

It is also preferable that the coloring resin composition according to the embodiment of the present invention does not substantially include terephthalic acid ester. Here, the “does not substantially include” means that the content of terephthalic acid ester is 1000 mass ppb or less in the total amount of the coloring resin composition, and it is more preferable to be 100 mass ppb or less and particularly preferable to be 0.

<Storage Container>

A storage container of the coloring resin composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or coloring resin compositions. Examples of such a container include the containers described in JP2015-123351A. In addition, for the purpose of preventing metal elution from the container interior wall, improving storage stability of the coloring resin composition, and suppressing the alteration of components, it is also preferable that the container interior wall is formed of glass, stainless steel, or the like.

<Method for Preparing Coloring Resin Composition>

The coloring resin composition according to the embodiment of the present invention can be prepared by mixing the above-described components with each other. During the preparation of the coloring resin composition, all the components may be dissolved and/or dispersed in an organic solvent at the same time to prepare the coloring resin composition. Optionally, two or more solutions or dispersion liquids in which the respective components are appropriately blended may be prepared, and the solutions or dispersion liquids may be mixed with each other during use (during application) to prepare the coloring resin composition.

In addition, in the preparation of the coloring resin composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring resin composition, it is preferable that the coloring resin composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

(Film)

The film according to the embodiment of the present invention is a film obtained from the above-described coloring resin composition according to the embodiment of the present invention. The film according to the embodiment of the present invention can be used for a color filter, a near-infrared transmitting filter, a near-infrared cut filter, a black matrix, a light-shielding film, and the like. For example, the film according to an embodiment of the present invention can be preferably used as a colored layer of a color filter.

The thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

In the film according to the embodiment of the present invention, a thickness of the film after performing a heating treatment of the film at 300° C. for 5 hours in a nitrogen atmosphere is preferably 70% or more of a thickness of the film before the heating treatment, more preferably 80% or more thereof, and still more preferably 90% or more.

In addition, a thickness of the film after performing a heating treatment of the film at 350° C. for 5 hours in a nitrogen atmosphere is preferably 70% or more of a thickness of the film before the heating treatment, more preferably 80% or more thereof, and still more preferably 90% or more.

In addition, a thickness of the film after performing a heating treatment of the film at 400° C. for 5 hours in a nitrogen atmosphere is preferably 70% or more of a thickness of the film before the heating treatment, more preferably 80% or more thereof, and still more preferably 90% or more.

In the film according to the embodiment of the present invention, it is preferable that a maximum value of a transmittance of the film at a wavelength of 400 to 1100 nm is 70% or more (preferably 75% or more, more preferably 80% or more, and still more preferably 85% or more), and a minimum value thereof is 30% or less (preferably 25% or less, more preferably 20% or less, and still more preferably 15% or less).

(Method for Manufacturing Film)

The film according to the embodiment of the present invention can be manufactured through a step of applying the coloring resin composition according to the embodiment of the present invention on a support. The method for manufacturing the film according to the embodiment of the present invention preferably further includes a step of forming a pattern (pixel). Examples of a method for forming the pattern (pixel) include a photolithography method and a dry etching method, and a photolithography method is preferable.

<Photolithography Method>

First, a case of forming the pattern by a photolithography method to manufacture a film will be described. Pattern formation by the photolithography method preferably includes a step of forming a coloring resin composition layer on a support using the coloring resin composition according to the embodiment of the present invention, a step of exposing the coloring resin composition layer in a patterned manner, and a step of removing a non-exposed portion of the coloring resin composition layer by development to form a pattern (pixel). A step (pre-baking step) of baking the coloring resin composition layer and a step (post-baking step) of baking the developed pattern (pixel) may be provided, optionally.

In the step of forming a coloring resin composition layer, the coloring resin composition layer is formed on a support using the coloring resin composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. The surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, wettability of the coloring resin composition is good. The surface contact angle of the base layer can be adjusted by, for example, adding a surfactant.

As a method of applying the coloring resin composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. A method for applying the ink jet is not particularly limited, and examples thereof include a method described in “Extension of Use of Ink Jet-Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, as the method of applying the coloring resin composition, methods described in WO2017/030174A and WO2017/018419A can also be used, the contents of which are incorporated herein by reference.

The coloring resin composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the coloring resin composition layer is exposed in a patterned manner (exposing step). For example, the coloring resin composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the film formed from the composition according to the embodiment of the present invention may be irradiated with light continuously to expose the film formed from the composition according to the embodiment of the present invention, or the film formed from the composition according to the embodiment of the present invention may be irradiated with light in a pulse to expose the film formed from the composition according to the embodiment of the present invention (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring resin composition layer is removed by development to form a pattern (pixel). The non-exposed portion of the coloring resin composition layer can be removed by development using a developer. Thus, the coloring resin composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an aqueous alkaline solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of transportation, storage, and the like, the developer may be first produced as a concentrated liquid and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring resin composition layer after development while rotating the support on which the coloring resin composition layer after development is formed. In addition, it is preferable that the rinsing is performed by moving a nozzle jetting the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

<Dry Etching Method>

Pattern formation by a dry etching method preferably includes a step of forming a coloring resin composition layer on a support using the coloring resin composition according to the embodiment of the present invention and curing the entire coloring resin composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

(Color Filter)

The color filter according to the embodiment of the present invention has the film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, the thickness of the film according to the embodiment of the present invention can be appropriately adjusted depending on the purposes. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

In the color filter according to the embodiment of the present invention, the width of the pixel is preferably 0.5 to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured using an ultrahigh resistance meter 5410 (manufactured by Advantest Corporation).

In addition, in the color filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition for forming a protective layer, which is dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition for forming a protective layer, as a method for applying the resin composition for forming a protective layer, a known method such as a spin coating method, a casting method, a screen printing method, and an ink jet method can be used. As the organic solvent included in the resin composition for forming a protective layer, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1 to 70 mass % and still more preferably 1 to 60 mass % with respect to the total mass of the protective layer. In addition, as the protective layer, the protective layers described in paragraph Nos. 0073 to 0092 of JP2017-151176A can also be used.

The color filter may have a base layer.

In addition, in the green pixel of the color filter, green color may be formed in a combination of C. I. Pigment Green 7, C. I. Pigment Green 36, C. I. Pigment Yellow 139, and C. I. Pigment Yellow 185, or in a combination of C. I. Pigment Green 58, C. I. Pigment Yellow 150, and C. I. Pigment Yellow 185.

The color filter may have a structure in which each colored pixel is embedded in a space partitioned in, for example, a lattice form by a partition wall. In addition, the coloring resin composition according to the embodiment of the present invention can also be suitably used for a pixel configuration described in WO2019/102887A.

(Solid-State Imaging Element)

A solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each coloring pixel is embedded in a space partitioned in, for example, a lattice shape by a partition wall. In this case, it is preferable that the partition wall has a lower refractive index than each colored pixel. Examples of an imaging device having such a structure include the devices described in JP2012-227478A, JP2014-179577A, WO2018/043654A, and US2018/0040656A. An imaging device including the solid-state imaging element according to the embodiment of the present invention can also be used as a vehicle camera or a surveillance camera, in addition to a digital camera or electronic apparatus (mobile phones or the like) having an imaging function. Further, the solid-state imaging element incorporating the color filter according to the embodiment of the present invention may incorporate another color filter, a near-infrared cut filter, an organic photoelectric conversion film, or the like in addition to the color filter according to the embodiment of the present invention.

(Image Display Device)

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in detail using examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below. Unless otherwise specified, “parts” and “%” are based on mass.

<Measurement of Weight-Average Molecular Weight (Mw) of Sample>

A weight-average molecular weight of a sample was measured by gel permeation chromatography (GPC) according to the following conditions.

Types of columns: columns formed by connection of TOSOH TSKgel Super HZM-H, TOSOH TSKgel Super HZ4000, and TOSOH TSKgel Super HZ2000

Developing solvent: tetrahydrofuran

Column temperature: 40° C.

Flow rate (amount of a sample to be injected): 1.0 μL (sample concentration: 0.1 mass %)

Device name: HLC-8220GPC manufactured by Tosoh Corporation

Detector: refractive index (RI) detector

Calibration curve base resin: polystyrene resin

<Measurement of Acid Value of Sample>

An acid value of a sample represents a mass of potassium hydroxide required to neutralize acidic components per 1 g of solid content in the sample. The acid value of the sample was measured as follows. That is, a measurement sample was dissolved in a mixed solvent of tetrahydrofuran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×Vs×0.5×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the sample (expressed in terms of solid contents)

<Production of Dispersion Liquids R1 to R8, B1 to B5, G1 to G4, Y1 and Y2, I1 to I6, and Bk1 to Bk7>

A mixed solution obtained by mixing raw materials listed in the table below was mixed and dispersed for 3 hours by a beads mill (using 0.3 mm diameter zirconia beads), and then subjected to a dispersion treatment under a pressure of 2000 MPa at a flow rate of 500 g/min using a high-pressure disperser equipped with a pressure-reducing system NANO-3000-10 (manufactured by Nippon BEE Chemical Co., Ltd.). The dispersion treatment was repeated 10 times to obtain each dispersion liquid.

TABLE 1

| | Coloring material | | | | | | | | | | | | | |
|---|---|---|---|---|---|---|---|---|---|---|---|---|---|---|
| | | | | | | | | | | | | IR | | |
| Dispersion | | | | | | | | | | | | coloring | IRGA- | |
| liquid | PR264 | PR254 | PR179 | PB15:4 | PB15:6 | PB16 | PG7 | PG36 | PY138 | PY215 | PV23 | agent | PHORE | PBk32 |
| Dispersion | 20.8 | — | — | — | — | — | — | — | — | — | — | — | — | — |
| liquid R1 | | | | | | | | | | | | | | |
| Dispersion | — | 24.2 | — | — | — | — | — | — | — | — | — | — | — | — |
| liquid R2 | | | | | | | | | | | | | | |
| Dispersion | 11.6 | 10.6 | — | — | — | — | — | — | — | — | — | — | — | — |
| liquid R3 | | | | | | | | | | | | | | |
| Dispersion | 22.9 | 2.1 | — | — | — | — | — | — | — | — | — | — | — | — |
| liquid R4 | | | | | | | | | | | | | | |
| Dispersion | — | 12.8 | — | — | — | — | — | — | 5.5 | — | — | — | — | — |
| liquid R5 | | | | | | | | | | | | | | |
| Dispersion | 13.1 | — | — | — | — | — | — | — | — | 3.6 | — | — | — | — |
| liquid R6 | | | | | | | | | | | | | | |
| Dispersion | — | — | 12.9 | — | — | — | — | — | — | — | — | — | — | — |
| liquid R7 | | | | | | | | | | | | | | |
| Dispersion | — | — | 10.1 | — | — | — | — | — | — | 4.2 | — | — | — | — |
| liquid R8 | | | | | | | | | | | | | | |
| Dispersion | — | — | — | 21.5 | — | — | — | — | — | — | — | — | — | — |
| liquid B1 | | | | | | | | | | | | | | |
| Dispersion | — | — | — | — | 22.6 | — | — | — | — | — | — | — | — | — |
| liquid B2 | | | | | | | | | | | | | | |
| Dispersion | — | — | — | — | — | 22.4 | — | — | — | — | — | — | — | — |
| liquid B3 | | | | | | | | | | | | | | |
| Dispersion | — | — | — | 17.2 | 5.4 | — | — | — | — | — | — | — | — | — |
| liquid B4 | | | | | | | | | | | | | | |
| Dispersion | — | — | — | 10.8 | — | 6.9 | — | — | — | — | — | — | — | — |
| liquid B5 | | | | | | | | | | | | | | |
| Dispersion | — | — | — | — | — | — | 12.3 | — | — | — | — | — | — | — |
| liquid G1 | | | | | | | | | | | | | | |
| Dispersion | — | — | — | — | — | — | — | 11.9 | — | — | — | — | — | — |
| liquid G2 | | | | | | | | | | | | | | |
| Dispersion | — | — | — | — | — | — | 10.1 | — | — | 2.0 | — | — | — | — |
| liquid G3 | | | | | | | | | | | | | | |
| Dispersion | — | — | — | — | — | — | — | 10.2 | 2.9 | — | — | — | — | — |
| liquid G4 | | | | | | | | | | | | | | |
| Dispersion | — | — | — | — | — | — | — | — | 12.9 | — | — | — | — | — |
| liquid Y1 | | | | | | | | | | | | | | |
| Dispersion | — | — | — | — | — | — | — | — | — | 13.1 | — | — | — | — |
| liquid Y2 | | | | | | | | | | | | | | |
| Dispersion | — | — | — | — | — | — | — | — | — | — | — | 22.5 | — | — |
| liquid I1 | | | | | | | | | | | | | | |
| Dispersion | — | — | — | — | — | — | — | — | — | — | — | 22.5 | — | — |
| liquid I2 | | | | | | | | | | | | | | |
| Dispersion | — | — | — | — | — | — | — | — | — | — | — | 22.5 | — | — |
| liquid I3 | | | | | | | | | | | | | | |
| Dispersion | — | — | — | — | — | — | — | — | — | — | — | 24.3 | — | — |
| liquid I4 | | | | | | | | | | | | | | |
| Dispersion | — | — | — | — | — | — | — | — | — | — | — | 24.3 | — | — |
| liquid I5 | | | | | | | | | | | | | | |
| Dispersion | — | — | — | — | — | — | — | — | — | — | — | 24.3 | — | — |
| liquid I6 | | | | | | | | | | | | | | |
| | Pigment derivative | | | Resin (dispersant) | | | | | | | | | | |
| Dispersion | Derivative | Derivative | Derivative | | | AA- | AA- | AA- | AA- | | Solvent | | | |
| liquid | 1 | 2 | 3 | AA-2 | AA-4 | 6 | 10 | 12 | 15 | CA-1 | S-1 | S-2 | S-3 | S-4 |
| Dispersion | 5.2 | — | — | 9.2 | — | — | — | — | — | — | 64.8 | — | — | — |
| liquid R1 | | | | | | | | | | | | | | |
| Dispersion | — | 5.6 | — | — | 9.8 | — | — | — | — | — | 60.4 | — | — | — |
| liquid R2 | | | | | | | | | | | | | | |
| Dispersion | — | 4.6 | — | — | — | 11.2 | — | — | — | — | — | 62.0 | — | — |
| liquid R3 | | | | | | | | | | | | | | |
| Dispersion | 5.0 | — | — | — | — | — | — | — | 12.3 | — | — | — | 57.7 | — |
| liquid R4 | | | | | | | | | | | | | | |
| Dispersion | 2.6 | — | — | 4.5 | — | — | — | — | — | — | 74.6 | — | — | — |
| liquid R5 | | | | | | | | | | | | | | |
| Dispersion | 2.4 | — | — | — | 4.3 | — | — | — | — | — | 76.6 | — | — | — |
| liquid R6 | | | | | | | | | | | | | | |
| Dispersion | 2.7 | — | — | — | — | 4.2 | — | — | — | — | 80.2 | — | — | — |
| liquid R7 | | | | | | | | | | | | | | |
| Dispersion | 2.6 | — | — | — | — | — | — | 4.0 | — | — | 79.1 | — | — | — |
| liquid R8 | | | | | | | | | | | | | | |
| Dispersion | — | 5.0 | — | 9.8 | — | — | — | — | — | — | — | — | 63.7 | |
| liquid B1 | | | | | | | | | | | | | | |
| Dispersion | — | 4.2 | — | — | 10.3 | — | — | — | — | — | — | — | — | 62.9 |
| liquid B2 | | | | | | | | | | | | | | |
| Dispersion | — | 5.6 | — | — | — | — | 10.5 | — | — | — | — | 61.5 | — | — |
| liquid B3 | | | | | | | | | | | | | | |
| Dispersion | — | 4.8 | — | 5.4 | — | — | 4.2 | — | — | — | — | 63.0 | — | — |
| liquid B4 | | | | | | | | | | | | | | |
| Dispersion | 5.6 | — | — | — | — | — | — | — | — | 8.4 | 68.3 | — | — | — |
| liquid B5 | | | | | | | | | | | | | | |
| Dispersion | — | 2.5 | — | 4.1 | — | — | — | — | — | — | 81.1 | — | — | — |
| liquid G1 | | | | | | | | | | | | | | |
| Dispersion | — | 2.3 | — | — | 3.9 | — | — | — | — | — | 81.9 | — | — | — |
| liquid G2 | | | | | | | | | | | | | | |
| Dispersion | — | 2.6 | — | — | — | 3.3 | — | — | — | — | 82.0 | — | — | — |
| liquid G3 | | | | | | | | | | | | | | |
| Dispersion | — | 2.3 | — | — | — | — | — | 3.7 | — | — | 80.9 | — | — | — |
| liquid G4 | | | | | | | | | | | | | | |
| Dispersion | — | 2.3 | — | 3.5 | — | — | — | — | — | — | 81.3 | — | — | — |
| liquid Y1 | | | | | | | | | | | | | | |
| Dispersion | — | 2.3 | — | 3.7 | — | — | — | — | — | — | 80.9 | — | — | — |
| liquid Y2 | | | | | | | | | | | | | | |
| Dispersion | — | — | 6.4 | 4.5 | — | — | — | — | — | — | — | — | — | 66.6 |
| liquid I1 | | | | | | | | | | | | | | |
| Dispersion | — | — | 6.4 | — | 4.5 | — | — | — | — | — | — | — | 66.6 | — |
| liquid I2 | | | | | | | | | | | | | | |
| Dispersion | — | — | 6.4 | — | — | 4.5 | — | — | — | — | — | 66.6 | — | — |
| liquid I3 | | | | | | | | | | | | | | |
| Dispersion | — | — | 7.2 | — | — | — | 4.5 | — | — | — | 64.0 | — | — | — |
| liquid I4 | | | | | | | | | | | | | | |
| Dispersion | — | — | 7.2 | — | — | — | 2.3 | — | 2.2 | — | 64.0 | — | — | — |
| liquid I5 | | | | | | | | | | | | | | |
| Dispersion | — | — | 7.2 | — | — | — | — | — | — | 4.5 | 64.0 | — | — | — |
| liquid I6 | | | | | | | | | | | | | | |

TABLE 2

| | Coloring material | | | | | | | | | | | | | |
|---|---|---|---|---|---|---|---|---|---|---|---|---|---|---|
| | | | | | | | | | | | | IR | | |
| Dispersion | | | | | | | | | | | | coloring | IRGA- | |
| liquid | PR264 | PR254 | PR179 | PB15:4 | PB15:6 | PB16 | PG7 | PG36 | PY138 | PY215 | PV23 | agent | PHORE | PBk32 |
| Dispersion | — | 7.7 | — | 5.0 | — | — | — | — | — | — | — | — | — | — |
| liquid | | | | | | | | | | | | | | |
| Bk1 | | | | | | | | | | | | | | |
| Dispersion | — | — | 4.9 | — | — | 1.9 | 5.2 | — | — | — | — | — | — | — |
| liquid | | | | | | | | | | | | | | |
| Bk2 | | | | | | | | | | | | | | |
| Dispersion | 6.8 | — | — | — | — | 4.4 | — | — | — | 1.0 | — | — | — | — |
| liquid | | | | | | | | | | | | | | |
| Bk3 | | | | | | | | | | | | | | |
| Dispersion | — | 5.6 | — | — | 3.2 | — | — | — | 2.2 | — | — | 3.6 | — | — |
| liquid | | | | | | | | | | | | | | |
| Bk4 | | | | | | | | | | | | | | |
| Dispersion | — | — | — | — | — | 6.3 | — | — | — | — | — | — | 6.3 | — |
| liquid | | | | | | | | | | | | | | |
| Bk5 | | | | | | | | | | | | | | |
| Dispersion | — | — | — | — | 3.1 | — | — | — | 3.1 | — | — | — | 3.1 | 3.1 |
| liquid | | | | | | | | | | | | | | |
| Bk6 | | | | | | | | | | | | | | |
| Dispersion | — | — | — | — | 4.2 | — | — | — | 4.2 | — | 4.2 | — | — | — |
| liquid | | | | | | | | | | | | | | |
| Bk7 | | | | | | | | | | | | | | |
| Dispersion | 6.8 | — | — | — | — | 4.4 | — | — | — | 1.0 | — | — | — | — |
| liquid | | | | | | | | | | | | | | |
| Bk8 | | | | | | | | | | | | | | |
| Dispersion | 6.8 | — | — | — | — | 4.4 | — | — | — | 1.0 | — | — | — | — |
| liquid | | | | | | | | | | | | | | |
| Bk9 | | | | | | | | | | | | | | |
| Dispersion | 6.8 | — | — | — | — | 4.4 | — | — | — | 1.0 | — | — | — | — |
| liquid | | | | | | | | | | | | | | |
| Bk10 | | | | | | | | | | | | | | |
| Dispersion | 6.8 | — | — | — | — | 4.4 | — | — | — | 1.0 | — | — | — | — |
| liquid | | | | | | | | | | | | | | |
| Bk11 | | | | | | | | | | | | | | |
| Dispersion | 6.8 | — | — | — | — | 4.4 | — | — | — | 1.0 | — | — | — | — |
| liquid | | | | | | | | | | | | | | |
| Bk12 | | | | | | | | | | | | | | |
| Dispersion | 6.8 | — | — | — | — | 4.4 | — | — | — | 1.0 | — | — | — | — |
| liquid | | | | | | | | | | | | | | |
| Bk13 | | | | | | | | | | | | | | |
| | Pigment derivative | | | Resin (dispersant) | | | | | | | Solvent | | | |
| Dispersion | Derivative | Derivative | Derivative | AA- | AA- | AA- | AA- | AA- | AA- | CA- | | | | |
| liquid | 1 | 2 | 3 | 2 | 4 | 6 | 10 | 12 | 15 | 1 | S-1 | S-2 | S-3 | S-4 |
| Dispersion | | | | | | | | | | | | | | |
| liquid | 2.3 | — | — | 4.5 | — | — | — | — | — | — | 80.5 | — | — | — |
| Bk1 | | | | | | | | | | | | | | |
| Dispersion | | | | | | | | | | | | | | |
| liquid | — | 2.4 | — | — | 4.3 | — | — | — | — | — | 81.3 | — | — | — |
| Bk2 | | | | | | | | | | | | | | |
| Dispersion | | | | | | | | | | | | | | |
| liquid | 2.3 | — | — | — | — | 4.0 | — | — | — | — | 81.5 | — | — | — |
| Bk3 | | | | | | | | | | | | | | |
| Dispersion | | | | | | | | | | | | | | |
| liquid | 2.3 | — | — | — | — | — | — | 4.1 | — | — | 79.0 | — | — | — |
| Bk4 | | | | | | | | | | | | | | |
| Dispersion | | | | | | | | | | | | | | |
| liquid | — | 2.1 | — | — | — | — | 3.8 | — | — | — | 81.6 | — | — | — |
| Bk5 | | | | | | | | | | | | | | |
| Dispersion | | | | | | | | | | | | | | |
| liquid | — | 2.1 | — | — | — | — | 3.8 | — | — | — | 81.6 | — | — | — |
| Bk6 | | | | | | | | | | | | | | |
| Dispersion | | | | | | | | | | | | | | |
| liquid | 1.0 | 1.0 | 1.0 | — | — | — | 3.8 | — | — | — | 81.6 | — | — | — |
| Bk7 | | | | | | | | | | | | | | |
| Dispersion | | | | | | | | | | | | | | |
| liquid | 2.3 | — | — | 4.0 | — | — | — | — | — | — | 61.5 | 20.0 | — | — |
| Bk8 | | | | | | | | | | | | | | |
| Dispersion | | | | | | | | | | | | | | |
| liquid | 2.3 | — | — | — | 4.0 | — | — | — | — | — | 61.5 | — | 20.0 | — |
| Bk9 | | | | | | | | | | | | | | |
| Dispersion | | | | | | | | | | | | | | |
| liquid | 2.3 | — | — | — | — | — | 4.0 | — | — | — | 61.5 | — | — | 20.0 |
| Bk10 | | | | | | | | | | | | | | |
| Dispersion | | | | | | | | | | | | | | |
| liquid | 2.3 | — | — | — | — | — | — | 4.0 | — | — | 81.5 | — | — | — |
| Bk11 | | | | | | | | | | | | | | |
| Dispersion | | | | | | | | | | | | | | |
| liquid | 2.3 | — | — | — | — | — | — | — | 4.0 | — | 81.5 | — | — | — |
| Bk12 | | | | | | | | | | | | | | |
| Dispersion | | | | | | | | | | | | | | |
| liquid | 2.3 | — | — | — | — | — | — | — | — | 4.0 | 81.5 | — | — | — |
| Bk13 | | | | | | | | | | | | | | |

The unit of numerical values shown in the above table is part by mass. Among the raw materials shown in the above table, details of the raw materials shown by abbreviations are as follows.

[Coloring Material]

PR264: C. I. Pigment Red 264 (red pigment, diketopyrrolopyrrole pigment)

PR254: C. I. Pigment Red 254 (red pigment, diketopyrrolopyrrole pigment)

PR179: C. I. Pigment Red 179

PB15:4: C. I. Pigment Blue 15:4 (blue pigment, phthalocyanine pigment)

PB15:6: C. I. Pigment Blue 15:6 (blue pigment, phthalocyanine pigment)

PB16: C. I. Pigment Blue 16 (blue pigment, phthalocyanine pigment)

PG7: C. I. Pigment Green 7

PG36: C. I. Pigment Green 36

PY138: C. I. Pigment Yellow 138

PY215: C. I. Pigment Yellow 215

PV23: C. I. Pigment Violet 23

IR coloring agent: compound having the following structure (near-infrared absorbing pigment, in the following structural formula, Me represents a methyl group and Ph represents a phenyl group)

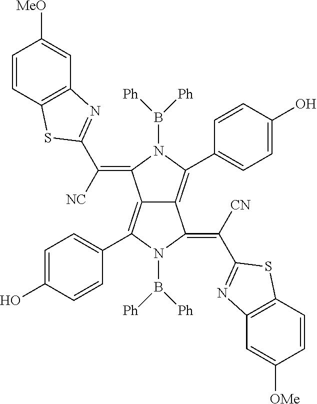 [SMILES: COc1ccc2sc(/C(C#N)=c3/c4c(-c5ccc(O)cc5)n(B(c5ccccc5)c5ccccc5)/c(=C(/C#N)c5nc6cc(OC)ccc6s5)c4c(-c4ccc(O)cc4)n3B(c3ccccc3)c3ccccc3)nc2c1]

IRGAPHORE: Irgaphor Black S 0100 CF (manufactured by BASF, compound having the following structure, lactam pigment)

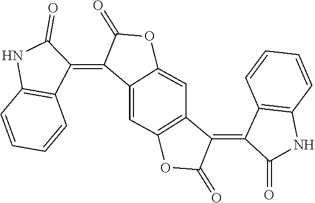 [SMILES: O=C1Nc2ccccc2/C1=C1/C(=O)Oc2cc3c(cc21)OC(=O)/C3=C1\C(=O)Nc2ccccc21]

PBk32: C. I. Pigment Black 32 (compound having the following structure, perylene pigment)

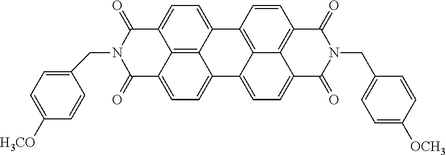 [SMILES: COc1ccc(CN2C(=O)c3ccc4c5ccc6c7c(ccc(c8ccc(c3c48)C2=O)c75)C(=O)N(Cc2ccc(OC)cc2)C6=O)cc1]

(Pigment Derivative)

Derivative 1: compound having the following structure

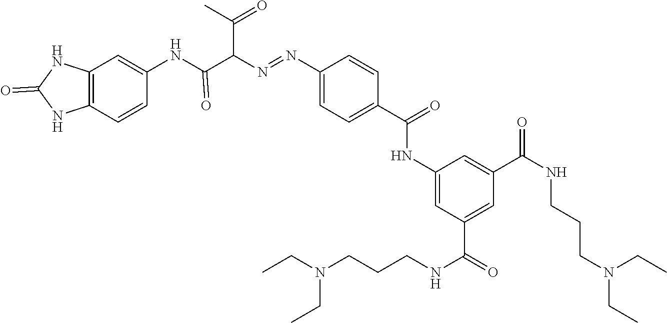 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Derivative 2: compound having the following structure

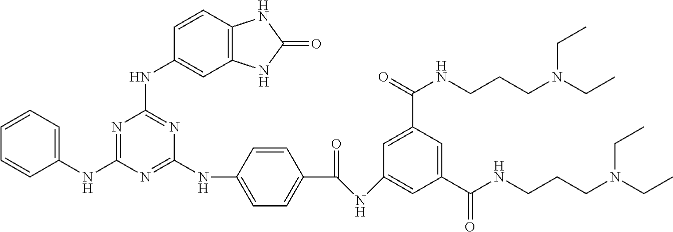 [SMILES: CCN(CC)CCCNC(=O)c1cc(NC(=O)c2ccc(Nc3nc(Nc4ccccc4)nc(Nc4ccc5[nH]c(=O)[nH]c5c4)n3)cc2)cc(C(=O)NCCCN(CC)CC)c1]

Derivative 3: compound having the following structure

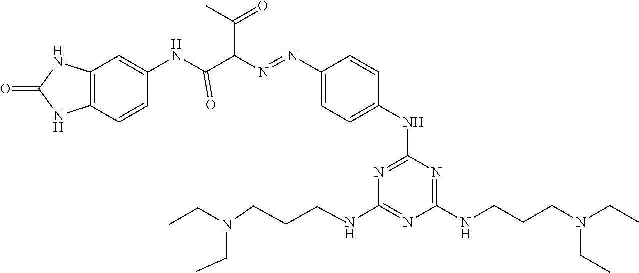 [SMILES: CCN(CC)CCCCNc1nc(NCCCN(CC)CC)nc(Nc2ccc(/N=N/C(C(C)=O)C(=O)Nc3ccc4[nH]c(=O)[nH]c4c3)cc2)n1]

[Resin]

AA-2: resin having the following structure (numerical value added to a main chain represents a molar ratio and numerical value added to a side chain (repeating unit of Polym) represents the number of repeating units; weight-average molecular weight is 26000 and acid value is 55 mgKOH/g)

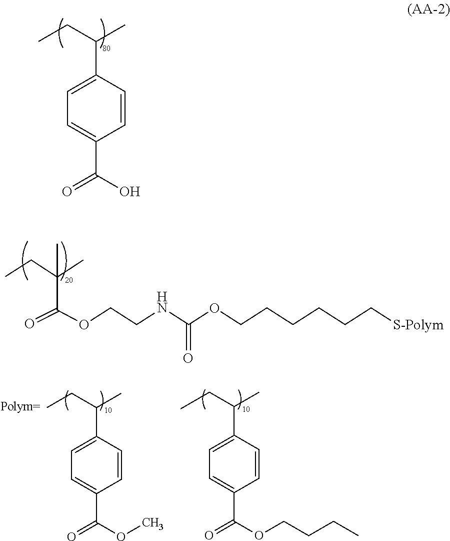

AA-4: resin having the following structure (numerical value added to a main chain represents a molar ratio and numerical value added to a side chain (repeating unit of Polym) represents the number of repeating units; weight-average molecular weight is 21000 and acid value is 38 mgKOH/g)

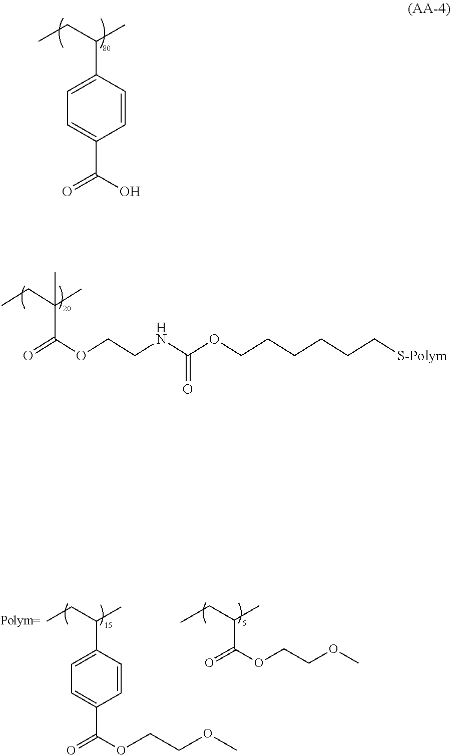

AA-6: resin having the following structure (numerical value added to a main chain represents a molar ratio and numerical value added to a side chain (repeating unit of Polym) represents the number of repeating units; weight-average molecular weight is 18500 and acid value is 42 mgKOH/g)

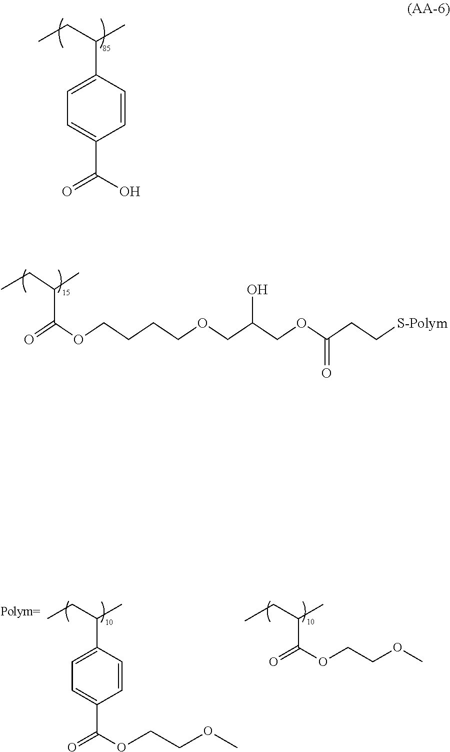

AA-10: resin having the following structure (numerical value added to a main chain represents a molar ratio and numerical value added to a side chain (repeating unit of Polym) represents the number of repeating units; weight-average molecular weight is 32000 and acid value is 70 mgKOH/g)

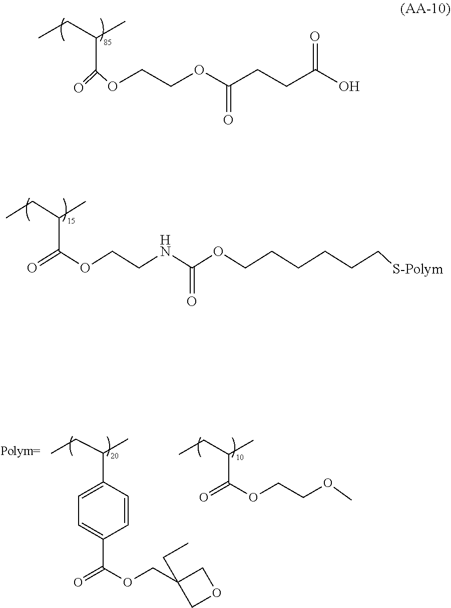

AA-12: resin having the following structure (numerical value added to a main chain represents a molar ratio and numerical value added to a side chain (repeating unit of Polym) represents the number of repeating units; weight-average molecular weight is 29500 and acid value is 63 mgKOH/g)

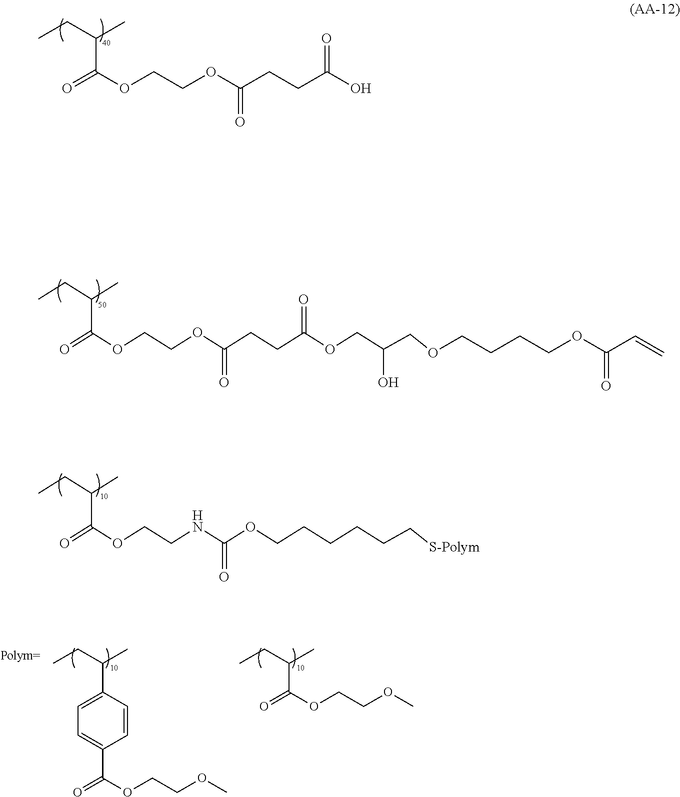

AA-15: resin having the following structure (numerical value added to a repeating unit (Polym) represents the number of repeating units; weight-average molecular weight is 12500 and acid value is 55 mgKOH/g)

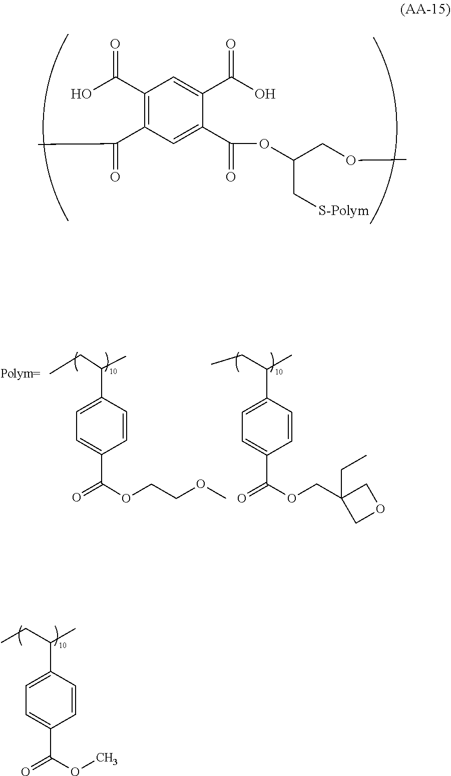

CA-1: resin having the following structure ((meth)acrylic resin, numerical value added to a main chain represents a molar ratio and numerical value added to a side chain represents the number of repeating units; weight-average molecular weight is 20000 and acid value is 77 mgKOH/g)

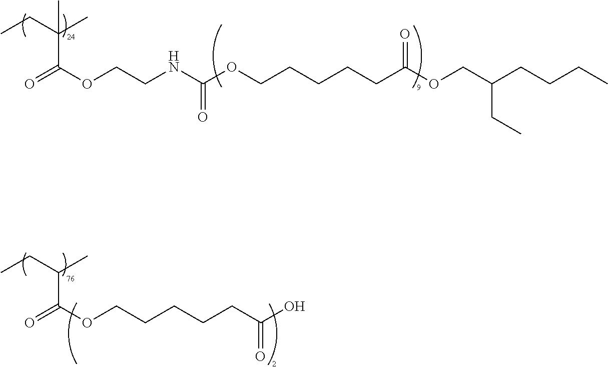

[Solvent (Organic Solvent)]

S-1: propylene glycol monomethyl ether acetate

S-2: propylene glycol monomethyl ether

S-3: cyclohexanone

S-4: cyclopentanone

<Production of Resin Composition>

In each of Examples and Comparative Examples, raw materials shown in the tables below were mixed to prepare coloring resin compositions of Examples and Comparative Examples. The unit of the numerical value in the column of the amount added described in the tables below is parts by mass.

TABLE 3

| | | | | | Polymerizable | | Photopolymerization | | | |
|---|---|---|---|---|---|---|---|---|---|---|
| | Pigment dispersion liquid | | Resin | | compound | | initiator | | Solvent | |
| | Type | Part by mass | Type | Part by mass | Type | Part by mass | Type | Part by mass | Type | Part by mass |
| Example 1 | Dispersion liquid | 54.6 | A-1 | 12.0 | D-1 | 5.0 | E-1 | 5.0 | S-1 | 23.4 |
| | R1 | | | | | | | | | |
| Example 2 | Dispersion liquid | 56.4 | A-2 | 4.0 | D-1 | 4.0 | E-1 | 3.0 | S-1 | 32.6 |
| | R1 | | | | | | | | | |
| Example 3 | Dispersion liquid | 54.6 | A-3 | 2.0 | D-1 | 3.0 | E-2 | 1.0 | S-3 | 39.4 |
| | R1 | | | | | | | | | |
| Example 4 | Dispersion liquid | 53.4 | A-4 | 8.0 | D-1 | 3.0 | E-1 | 3.0 | S-3 | 32.6 |
| | R2 | | | | | | | | | |
| Example 5 | Dispersion liquid | 58.6 | A-5 | 8.0 | D-2 | 3.0 | E-2 | 3.0 | S-3 | 27.4 |
| | R2 | | | | | | | | | |
| Example 6 | Dispersion liquid | 55.0 | A-6 | 8.0 | D-1 | 3.0 | E-3 | 3.0 | S-3 | 31.0 |
| | R2 | | | | | | | | | |
| Example 7 | Dispersion liquid | 55.9 | A-7 | 10.0 | D-1 | 5.0 | E-1 | 3.0 | S-3 | 26.1 |
| | R3 | | | | | | | | | |
| Example 8 | Dispersion liquid | 57.2 | A-8 | 10.0 | D-2 | 5.0 | E-2 | 3.0 | S-3 | 24.8 |
| | R3 | | | | | | | | | |
| Example 9 | Dispersion liquid | 63.7 | A-9 | 10.0 | D-3 | 4.0 | E-3 | 3.0 | S-1 | 19.3 |
| | R3 | | | | | | | | | |
| Example 10 | Dispersion liquid | 56.9 | A-10 | 12.0 | D-1 | 4.0 | E-3 | 3.0 | S-3 | 24.1 |
| | R4 | | | | | | | | | |
| Example 11 | Dispersion liquid | 55.0 | A-4 | 5.0 | D-1 | 4.0 | E-2 | 3.0 | S-1 | 33.0 |
| | R5 | | | | | | | | | |
| Example 12 | Dispersion liquid | 55.0 | A-5 | 5.0 | D-2 | 3.0 | E-2 | 3.0 | S-1 | 34.0 |
| | R6 | | | | | | | | | |
| Example 13 | Dispersion liquid | 55.0 | A-6 | 5.0 | D-1 | 3.0 | E-3 | 3.0 | S-1 | 34.0 |
| | R7 | | | | | | | | | |
| Example 14 | Dispersion liquid | 55.0 | A-11 | 5.0 | D-2 | 2.0 | E-3 | 3.0 | S-1 | 35.0 |
| | R8 | | | | | | | | | |
| Example 15 | Dispersion liquid | 52.5 | A-11 | 8.0 | D-1 | 5.0 | E-1 | 2.0 | S-3 | 32.5 |
| | B1 | | | | | | | | | |
| Example 16 | Dispersion liquid | 52.0 | A-12 | 8.0 | D-2 | 5.0 | E-1 | 3.0 | S-3 | 32.0 |
| | B1 | | | | | | | | | |
| Example 17 | Dispersion liquid | 57.9 | A-13 | 8.0 | D-3 | 5.0 | E-1 | 3.0 | S-3 | 26.2 |
| | B1 | | | | | | | | | |
| Example 18 | Dispersion liquid | 52.3 | A-14 | 8.0 | D-1 | 5.0 | E-2 | 3.0 | S-3 | 31.7 |
| | B2 | | | | | | | | | |
| Example 19 | Dispersion liquid | 56.7 | A-15 | 8.0 | D-2 | 2.0 | E-2 | 2.0 | S-3 | 31.3 |
| | B2 | | | | | | | | | |
| Example 20 | Dispersion liquid | 55.1 | A-16 | 8.0 | D-3 | 5.0 | E-2 | 3.0 | S-1 | 28.9 |
| | B2 | | | | | | | | | |
| Example 21 | Dispersion liquid | 58.0 | A-17 | 10.0 | D-1 | 5.0 | E-3 | 3.0 | S-1 | 24.0 |
| | B3 | | | | | | | | | |
| Example 22 | Dispersion liquid | 53.8 | A-18 | 10.0 | D-1 | 2.0 | E-3 | 3.0 | S-1 | 31.2 |
| | B3 | | | | | | | | | |
| Example 23 | Dispersion liquid | 54.1 | A-19 | 10.0 | D-2 | 5.0 | E-3 | 3.0 | S-1 | 27.9 |
| | B3 | | | | | | | | | |
| Example 24 | Dispersion liquid | 59.2 | A-20 | 10.0 | D-1 | 5.0 | E-1 | 3.0 | S-3 | 22.9 |
| | B4 | | | | | | | | | |
| Example 25 | Dispersion liquid | 56.4 | A-21 | 8.0 | D-1 | 5.0 | E-2 | 2.0 | S-3 | 28.6 |
| | B4 | | | | | | | | | |
| Example 26 | Dispersion liquid | 56.8 | A-22 | 8.0 | D-2 | 2.0 | E-3 | 3.0 | S-3 | 30.2 |
| | B4 | | | | | | | | | |
| Example 27 | Dispersion liquid | 63.7 | A-23 | 9.0 | D-1 | 5.0 | E-1 | 3.0 | S-3 | 19.3 |
| | B5 | | | | | | | | | |
| Example 28 | Dispersion liquid | 70.2 | A-24 | 10.0 | D-1 | 5.0 | E-2 | 3.0 | S-3 | 11.8 |
| | B5 | | | | | | | | | |
| Example 29 | Dispersion liquid | 55.0 | A-4 | 5.0 | D-1 | 5.0 | E-3 | 2.0 | S-1 | 33.0 |
| | G1 | | | | | | | | | |
| Example 30 | Dispersion liquid | 55.0 | A-5 | 5.0 | D-1 | 5.0 | E-3 | 3.0 | S-1 | 32.0 |
| | G2 | | | | | | | | | |
| Example 31 | Dispersion liquid | 55.0 | A-6 | 5.0 | D-2 | 5.0 | E-3 | 3.0 | S-1 | 32.0 |
| | G3 | | | | | | | | | |
| Example 32 | Dispersion liquid | 55.0 | A-11 | 5.0 | D-2 | 5.0 | E-3 | 3.0 | S-1 | 32.0 |
| | G4 | | | | | | | | | |
| Example 33 | Dispersion liquid | 55.0 | A-11 | 5.0 | D-3 | 2.0 | E-3 | 2.0 | S-1 | 36.0 |
| | Y1 | | | | | | | | | |
| Example 34 | Dispersion liquid | 55.0 | A-11 | 5.0 | D-3 | 5.0 | E-3 | 3.0 | S-1 | 32.0 |
| | Y2 | | | | | | | | | |
| Example 35 | Dispersion liquid | 53.8 | A-1 | 8.0 | D-1 | 2.0 | E-3 | 1.0 | S-1 | 35.2 |
| | I1 | | | | | | | | | |
| Example 36 | Dispersion liquid | 56.6 | A-2 | 8.0 | D-1 | 5.0 | E-1 | 3.0 | S-1 | 27.5 |
| | I1 | | | | | | | | | |
| Example 37 | Dispersion liquid | 59.8 | A-3 | 8.0 | D-1 | 5.0 | E-2 | 3.0 | S-1 | 24.2 |
| | I1 | | | | | | | | | |
| Example 38 | Dispersion liquid | 60.3 | A-4 | 8.0 | D-1 | 2.0 | E-3 | 1.0 | S-3 | 28.7 |
| | I2 | | | | | | | | | |
| Example 39 | Dispersion liquid | 57.1 | A-5 | 8.0 | D-2 | 5.0 | E-1 | 2.0 | S-3 | 27.9 |
| | I2 | | | | | | | | | |
| Example 40 | Dispersion liquid | 56.3 | A-6 | 12.0 | D-1 | 10.0 | E-2 | 5.0 | S-3 | 16.7 |
| | I3 | | | | | | | | | |

TABLE 4

| | Pigment | | | | Polymerizable | | Photopolymerization | | | |
|---|---|---|---|---|---|---|---|---|---|---|
| | dispersion liquid | | Resin | | compound | | initiator | | Solvent | |
| | | Part by | | Part by | | Part by | | Part by | | Part by |
| | Type | mass | Type | mass | Type | mass | Type | mass | Type | mass |
| Example 41 | Dispersion | 55.9 | A-7 | 8.0 | D-2 | 5.0 | E-3 | 5.0 | S-3 | 26.1 |
| | liquid I3 | | | | | | | | | |
| Example 42 | Dispersion | 54.1 | A-8 | 8.0 | D-1 | 2.0 | E-1 | 3.0 | S-3 | 32.9 |
| | liquid I4 | | | | | | | | | |
| Example 43 | Dispersion | 55.9 | A-9 | 8.0 | D-1 | 2.0 | E-2 | 3.0 | S-3 | 31.1 |
| | liquid I5 | | | | | | | | | |
| Example 44 | Dispersion | 60.6 | A-10 | 8.0 | D-1 | 5.0 | E-3 | 3.0 | S-3 | 23.4 |
| | liquid I5 | | | | | | | | | |
| Example 45 | Dispersion | 55.8 | A-11 | 8.0 | D-1 | 5.0 | E-3 | 3.0 | S-3 | 28.2 |
| | liquid I5 | | | | | | | | | |
| Example 46 | Dispersion | 55.0 | A-12 | 8.0 | D-1 | 5.0 | E-3 | 3.0 | S-3 | 29.0 |
| | liquid I6 | | | | | | | | | |
| Example 47 | Dispersion | 55.0 | A-4 | 5.0 | D-1 | 2.0 | E-2 | 3.0 | S-1 | 35.0 |
| | liquid Bk1 | | | | | | | | | |
| Example 48 | Dispersion | 55.0 | A-5 | 5.0 | D-1 | 2.0 | E-2 | 3.0 | S-1 | 35.0 |
| | liquid Bk2 | | | | | | | | | |
| Example 49 | Dispersion | 55.0 | A-6 | 5.0 | D-1 | 2.0 | E-3 | 3.0 | S-1 | 35.0 |
| | liquid Bk3 | | | | | | | | | |
| Example 50 | Dispersion | 55.0 | A-11 | 5.0 | D-1 | 2.0 | E-3 | 3.0 | S-1 | 35.0 |
| | liquid Bk4 | | | | | | | | | |
| Example 51 | Dispersion | 27.6 | A-4 | 10.0 | D-1 | 11.5 | E-2 | 5.0 | S-1 | 31.5 |
| | liquid R1 | 27.6 | | | | | | | | |
| | Dispersion | | | | | | | | | |
| | liquid B2 | | | | | | | | | |
| Example 52 | Dispersion | 18.3 | A-6 | 5.0 | D-1 | 5.0 | E-2 | 3.0 | S-1 | 45.0 |
| | liquid R5 | 18.3 | | | | | | | | |
| | Dispersion | 18.3 | | | | | | | | |
| | liquid G1 | | | | | | | | | |
| | Dispersion | | | | | | | | | |
| | liquid Y1 | | | | | | | | | |
| Example 53 | Dispersion | 18.3 | A-4 | 5.0 | D-2 | 5.0 | E-2 | 3.0 | S-1 | 45.0 |
| | liquid R6 | 18.3 | | | | | | | | |
| | Dispersion | 18.3 | | | | | | | | |
| | liquid G2 | | | | | | | | | |
| | Dispersion | | | | | | | | | |
| | liquid B1 | | | | | | | | | |
| Example 54 | Dispersion | 18.3 | A-6 | 5.0 | D-3 | 5.0 | E-3 | 3.0 | S-1 | 45.0 |
| | liquid R6 | 18.3 | | | | | | | | |
| | Dispersion | 18.3 | | | | | | | | |
| | liquid B2 | | | | | | | | | |
| | Dispersion | | | | | | | | | |
| | liquid Y2 | | | | | | | | | |
| Example 55 | Dispersion | 55.0 | A-6 | 5.0 | D-1 | 2.0 | E-2 | 3.0 | S-1 | 35.0 |
| | liquid Bk5 | | | | | | | | | |
| Example 56 | Dispersion | 55.0 | A-6 | 5.0 | D-1 | 2.0 | E-2 | 3.0 | S-1 | 35.0 |
| | liquid Bk6 | | | | | | | | | |
| Example 57 | Dispersion | 55.0 | A-6 | 5.0 | D-1 | 2.0 | E-2 | 3.0 | s-1 | 35.0 |
| | liquid Bk7 | | | | | | | | | |
| Example 58 | Dispersion | 55.0 | A-27 | 5.0 | D-1 | 2.0 | E-2 | 3.0 | s-1 | 35.0 |
| | liquid Bk7 | | | | | | | | | |
| Example 59 | Dispersion | 55.0 | A-28 | 5.0 | D-1 | 2.0 | E-2 | 3.0 | S-1 | 35.0 |
| | liquid Bk7 | | | | | | | | | |
| Example 60 | Dispersion | 55.0 | A-29 | 5.0 | D-1 | 2.0 | E-2 | 3.0 | S-1 | 35.0 |
| | liquid Bk7 | | | | | | | | | |
| Example 61 | Dispersion | 55.0 | A-30 | 5.0 | D-1 | 2.0 | E-2 | 3.0 | S-1 | 35.0 |
| | liquid Bk7 | | | | | | | | | |
| Example 62 | Dispersion | 55.0 | CA-3 | 5.0 | D-1 | 2.0 | E-3 | 3.0 | S-1 | 35.0 |
| | liquid Bk3 | | | | | | | | | |
| Example 63 | Dispersion | 55.0 | A-1 | 5.0 | D-1 | 2.0 | E-3 | 3.0 | S-1 | 35.0 |
| | liquid Bk8 | | | | | | | | | |
| Example 64 | Dispersion | 55.0 | A-5 | 5.0 | D-1 | 2.0 | E-3 | 3.0 | S-1 | 35.0 |
| | liquid Bk9 | | | | | | | | | |
| Example 65 | Dispersion | 55.0 | A-6 | 5.0 | D-1 | 2.0 | E-3 | 3.0 | S-1 | 35.0 |
| | liquid Bk10 | | | | | | | | | |
| Example 66 | Dispersion | 55.0 | A-6 | 5.0 | D-1 | 2.0 | E-3 | 3.0 | S-1 | 35.0 |
| | liquid Bk11 | | | | | | | | | |
| Example 67 | Dispersion | 55.0 | A-6 | 5.0 | D-1 | 2.0 | E-3 | 3.0 | S-1 | 35.0 |
| | liquid Bk12 | | | | | | | | | |
| Example 68 | Dispersion | 55.0 | A-6 | 5.0 | D-1 | 2.0 | E-3 | 3.0 | S-1 | 35.0 |
| | liquid Bk13 | | | | | | | | | |
| Comparative | Dispersion | 40.2 | CA-3 | 8.0 | D-1 | 11.5 | E-3 | 5.0 | S-1 | 35.3 |
| Example 1 | liquid I6 | | | | | | | | | |
| Comparative | Dispersion | 43.6 | CA-4 | 8.0 | D-1 | 11.5 | E-3 | 5.0 | S-3 | 31.9 |
| Example 2 | liquid I6 | | | | | | | | | |

Among the raw materials listed in the above tables, details of the raw materials shown by abbreviations are as follows.

[Dispersion Liquid]

Dispersion liquids R1 to R8, B1 to B5, G1 to G4, Y1 and Y2, I1 to 16, and Bk1 to Bk13: dispersion liquids described above

[Resin]

A-1: resin having the following structure; numerical added to a repeating unit represents a molar ratio; weight-average molecular weight is 12300.

A-2: resin having the following structure; numerical added to a repeating unit represents a molar ratio; weight-average molecular weight is 18500.

A-3: resin having the following structure; numerical added to a repeating unit represents a molar ratio; weight-average molecular weight is 23000.

A-4: resin having the following structure; numerical added to a repeating unit represents a molar ratio; weight-average molecular weight is 8900.

A-5: resin having the following structure; numerical added to a repeating unit represents a molar ratio; weight-average molecular weight is 27000.

A-6: resin having the following structure; numerical added to a repeating unit represents a molar ratio; weight-average molecular weight is 56000.

A-7: resin having the following structure; numerical added to a repeating unit represents a molar ratio; weight-average molecular weight is 31400.

A-8: resin having the following structure; numerical added to a repeating unit represents a molar ratio; weight-average molecular weight is 42000.

A-9: resin having the following structure; numerical added to a repeating unit represents a molar ratio; weight-average molecular weight is 18900.

A-10: resin having the following structure; numerical added to a repeating unit represents a molar ratio; weight-average molecular weight is 16700.

A-11: resin having the following structure; numerical added to a repeating unit represents a molar ratio; weight-average molecular weight is 31000.

A-12: resin having the following structure; numerical added to a repeating unit represents a molar ratio; weight-average molecular weight is 14000.

A-13: resin having the following structure; numerical added to a repeating unit represents a molar ratio; weight-average molecular weight is 12600.

A-14: resin having the following structure; numerical added to a repeating unit represents a molar ratio; weight-average molecular weight is 17400.

A-15: resin having the following structure; numerical added to a repeating unit represents a molar ratio; weight-average molecular weight is 34000.

A-16: resin having the following structure; numerical added to a repeating unit represents a molar ratio; weight-average molecular weight is 23100.

A-17: resin having the following structure; numerical added to a repeating unit represents a molar ratio; weight-average molecular weight is 19000.

A-18: resin having the following structure; numerical added to a repeating unit represents a molar ratio; weight-average molecular weight is 22300.

A-19: resin having the following structure; numerical added to a repeating unit represents a molar ratio; weight-average molecular weight is 28700.

A-20: resin having the following structure; numerical added to a repeating unit represents a molar ratio; weight-average molecular weight is 15000.

A-21: resin having the following structure; numerical added to a repeating unit represents a molar ratio; weight-average molecular weight is 9700.

A-22: resin having the following structure; numerical added to a repeating unit represents a molar ratio; weight-average molecular weight is 50000.

A-23: resin having the following structure; numerical added to a repeating unit represents a molar ratio; weight-average molecular weight is 12100.

A-24: resin having the following structure; numerical added to a repeating unit represents a molar ratio; weight-average molecular weight is 13000.

A-27: resin having the following structure; numerical added to a repeating unit represents a molar ratio; weight-average molecular weight is 25000.

A-28: resin having the following structure; numerical added to a repeating unit represents a molar ratio; weight-average molecular weight is 28100.

A-29: resin having the following structure; numerical added to a repeating unit represents a molar ratio; weight-average molecular weight is 34200.

A-30: resin having the following structure; numerical added to a repeating unit represents a molar ratio; weight-average molecular weight is 14500.

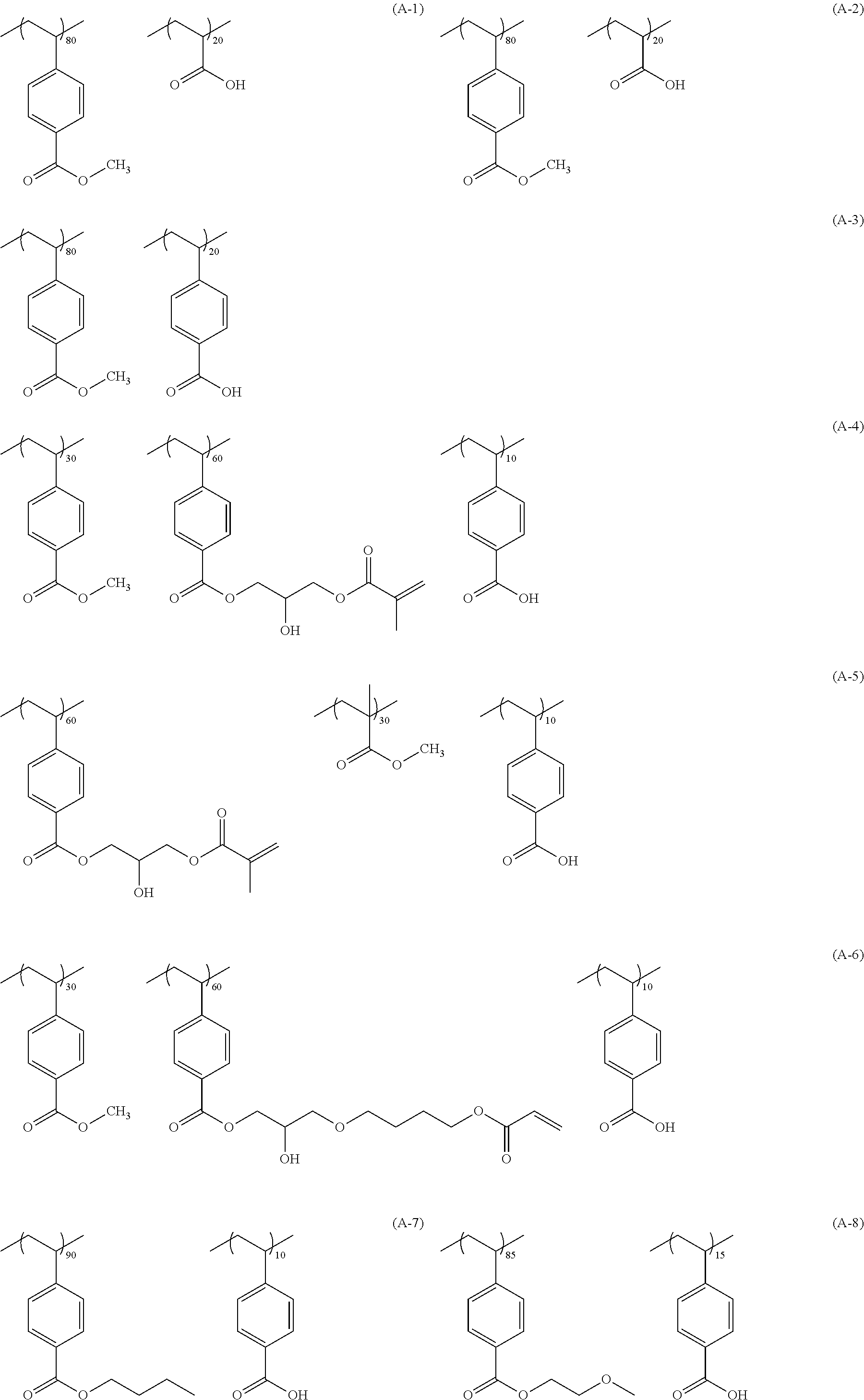

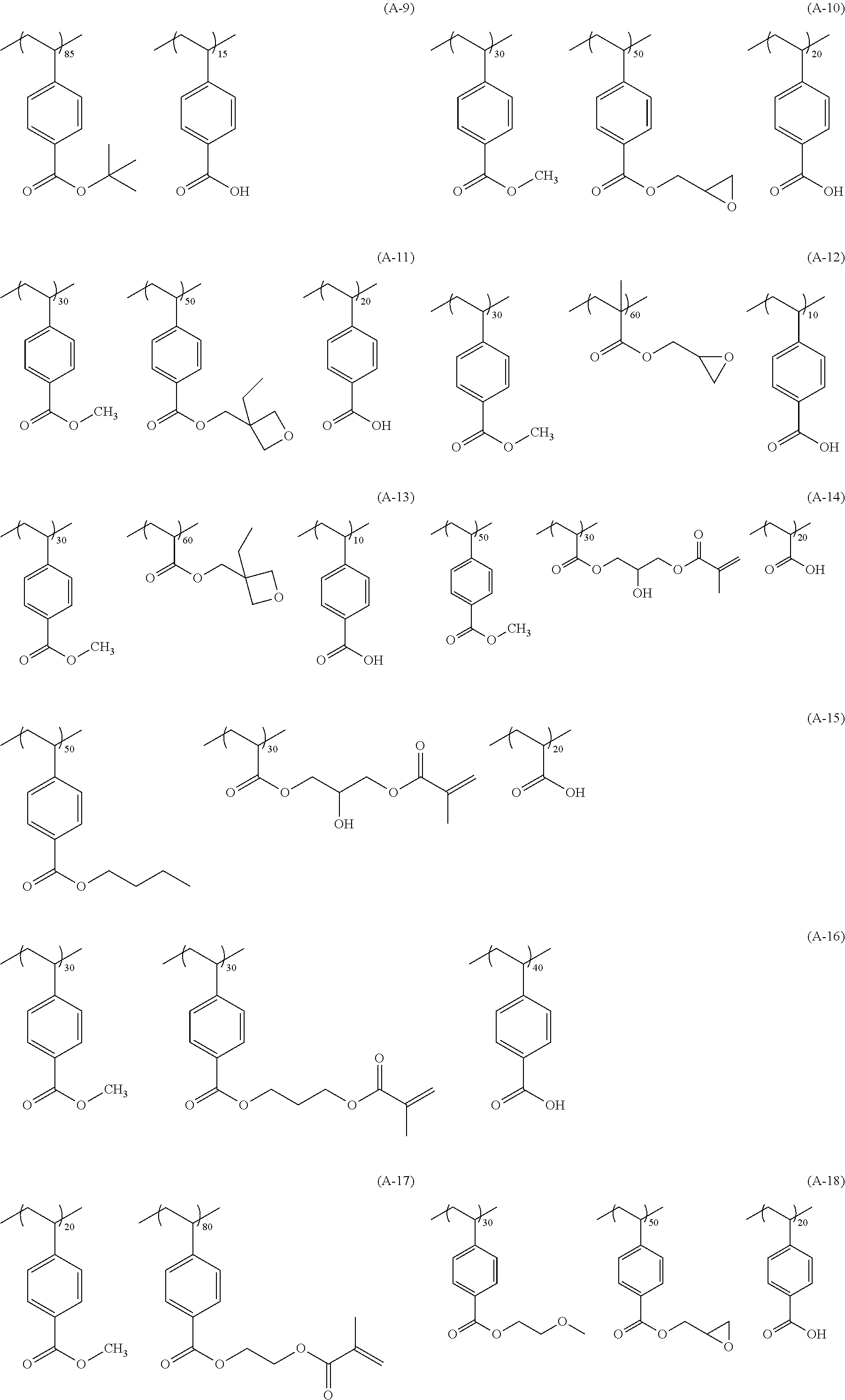

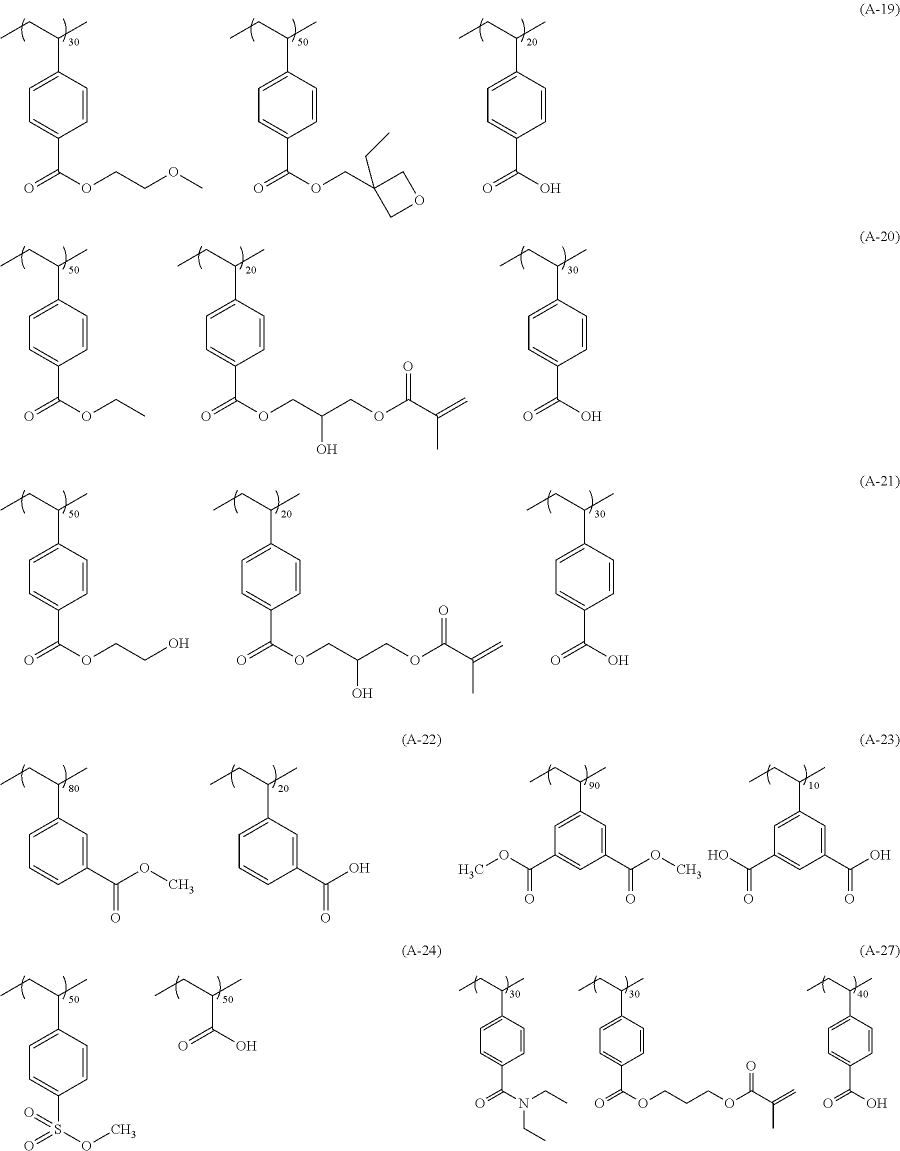

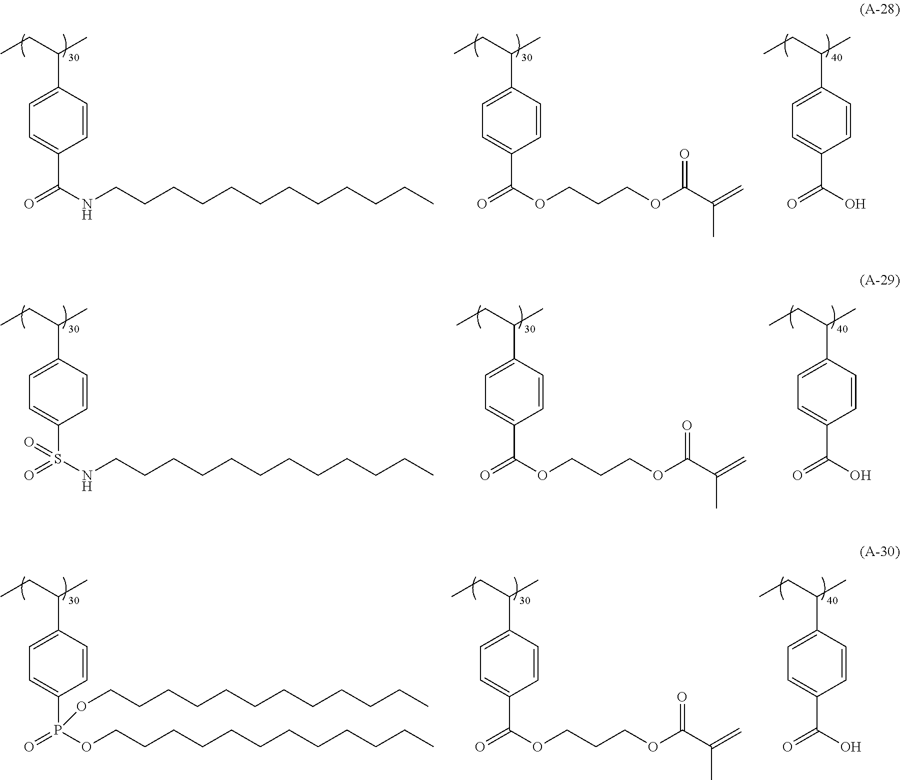

CA-3: resin having the following structure; numerical added to a repeating unit represents a molar ratio; weight-average molecular weight is 18700

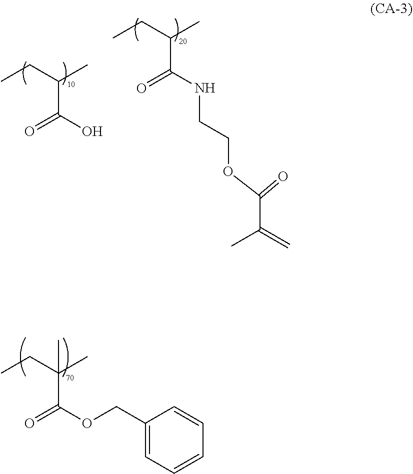

CA-4: resin represented by the following formula; numerical added to a repeating unit represents a molar ratio; weight-average molecular weight is 15900

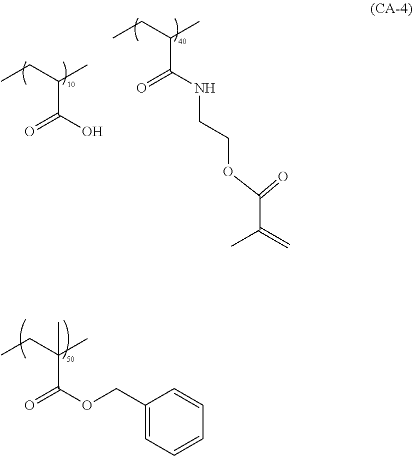

[Polymerizable Compound]

D-1: KAYARAD DPHA (manufactured by Nippon Kayaku Co., Ltd.)

D-2: NK ESTER A-DPH-12E (manufactured by Shin-Nakamura Chemical Co., Ltd.)

D-3: ARONIX M-510 (manufactured by TOAGOSEI CO., LTD.)

[Photopolymerization Initiator]

E-1: IRGACURE 379 (aminoacetophenone-based photo-radical initiator (manufactured by BASF))

E-2: Irgacure OXE01 (oxime ester-based photo-radical initiator (manufactured by BASF))

E-3: Irgacure OXE03 (oxime ester-based photo-radical initiator (manufactured by BASF))

[Solvent (Organic Solvent)]

S-1: propylene glycol monomethyl ether acetate

S-3: cyclohexanone

<Evaluation>

[Evaluation of Exposure Sensitivity]

In each of Examples and Comparative Examples, on a silicon wafer, each coloring resin composition was applied to a glass substrate by spin coating, and dried (pre-baked) at 100° C. for 120 seconds using a hot plate. Thereafter, the composition was heated (post-baked) at 200° C. for 30 minutes using an oven to form a resin composition layer having a thickness of 0.60 μm. Next, using an i-ray stepper exposure device FPA-3000 i5+(manufactured by Canon Inc.), the resin composition layer was irradiated with light having a wavelength of 365 nm through a mask pattern in which square non-masked pixels with a side of 1.0 μm were arranged in an area of 4 mm×3 mm to perform exposure thereon with a specific exposure amount. Next, the silicon wafer on which the resin composition layer after the exposure was formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pattern (pixel). While changing the above-described specific exposure amount, the obtained pattern was observed, the minimum exposure amount for resolving the square pattern with a side length of 1.0 μm was determined, and evaluation was performed according to the following evaluation standard. It can be said that, as the value of the minimum exposure amount is smaller, the composition has more excellent exposure sensitivity.

—Evaluation Standard—

A: minimum exposure amount was less than 100 mJ/cm².

B: minimum exposure amount was 100 or more and less than 200 mJ/cm².

C: minimum exposure amount was 200 or more and less than 500 mJ/cm².

D: minimum exposure amount was 500 or more and less than 1000 mJ/cm².

E: minimum exposure amount was 1000 mJ/cm² or more.

[Evaluation of Storage Stability]

In each of Examples and Comparative Examples, the viscosity (mPa·s) of each coloring resin composition was measured by “RE-85L” manufactured by TOKI SANGYO CO., LTD. After the above-described measurement, the coloring resin composition was allowed to stand at 45° C. under the conditions of light shielding for 3 days, and the viscosity (mPa·s) was measured again. Storage stability was evaluated according to the following evaluation standard from a viscosity difference (ΔVis) before and after leaving to stand. It can be said that, as the numerical value of the viscosity difference (ΔVis) is smaller, the storage stability of the composition is better. In each of the above-described viscosity measurements, the temperature and humidity were controlled to 22±5° C. and 60±20% in a laboratory, and the temperature of the coloring resin composition was adjusted to 25° C.

—Evaluation Standard—

A: ΔVis was 0.5 mPa·s or less.

B: ΔVis was more than 0.5 mPa·s and 1.0 mPa·s or less.

C: ΔVis was more than 1.0 mPa·s and 2.0 mPa·s or less.

D: ΔVis was more than 2.0 mPa·s and 2.5 mPa·s or less.

E: ΔVis was more than 2.5 mPa·s.

[Evaluation of Spectral Change]

In each of Examples and Comparative Examples, on a glass substrate, each coloring resin composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. Using Cary 5000 UV-Vis-NIR spectrophotometer (manufactured by Agilent Technologies, Inc.), a transmittance Tr1 of the obtained film at a wavelength of 450 nm was measured. Next, the obtained film was heat-treated at 300° C. for 5 hours in a nitrogen atmosphere. A transmittance Tr2 of the film after the heating treatment at a wavelength of 450 nm was measured. An absolute value ΔT of the difference between Tr1 and Tr2 was calculated, and the spectral change was evaluated according to the following evaluation standard. It can be said that, as ΔT is smaller, the spectral change is less likely to occur, which is preferable. Both Tr1 and Tr2 were measured in a state in which the temperature and humidity were controlled to 22±5° C. and 60±20% in a laboratory, and the temperature of the substrate was adjusted to 25° C.

—Evaluation Standard—

A: ΔT was 0.1% or less.

B: ΔT was more than 0.1% and 0.5% or less.

C: ΔT was more than 0.5% and 1% or less.

D: ΔT was more than 1% and 5% or less.

E: ΔT was more than 5%.

[Evaluation of Film Contraction Ratio]

In each of Examples and Comparative Examples, on a glass substrate, each coloring resin composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. The film thickness was measured by scraping a part of the film to expose a surface of the glass substrate, and measuring a level difference (film thickness of the coating film) between the surface of the glass substrate and the coating film using a stylus profilometer (DektakXT, manufactured by BRUKER). Next, the obtained film was heat-treated at 300° C. for 5 hours in a nitrogen atmosphere. The film thickness of the film after the heating treatment was measured in the same manner as described above, a film contraction ratio was calculated from the following expression, and the film contraction ratio was evaluated according to the following evaluation standard. Both T0 and T1 below were measured in a state in which the temperature and humidity were controlled to 22±5° C. and 60±20% in a laboratory, and the temperature of the substrate was adjusted to 25° C. It can be said that, as the film contraction ratio is smaller, the film contraction is more suppressed, which is a preferred result.

Film contraction ratio (%)=(1−(T1/T0))×100

T0: thickness of film immediately after production (=0.60 μm)

T1: thickness of film after the heating treatment at 300° C. for 5 hours in a nitrogen atmosphere

—Evaluation Standard—

A: film contraction ratio was 1% or less.

B: film contraction ratio was more than 1% and 5% or less.

C: film contraction ratio was more than 5% and 10% or less.

D: film contraction ratio was more than 10% and 30% or less.

E: film contraction ratio was more than 30%.

[Evaluation of Cracks]

In each of Examples and Comparative Examples, on a glass substrate, each coloring resin composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm.

Next, SiO₂ was laminated at 200 nm on the surface of the obtained film by a sputtering method to form an inorganic film. The obtained film in which the inorganic film was formed on the surface was heat-treated at 300° C. for 5 hours in a nitrogen atmosphere. The surface of the inorganic film after the heating treatment was observed with an optical microscope, the number of cracks per 1 cm² was counted, and the presence or absence of cracks was evaluated according to the following evaluation standard.

—Evaluation Standard—

A: number of cracks per 1 cm² was 0.

B: number of cracks per 1 cm² was 1 to 10.

C: number of cracks per 1 cm² was 11 to 50.

D: number of cracks per 1 cm² was 51 to 100.

E: number of cracks per 1 cm² was 101 or more.

TABLE 5

| | Evaluation result | | | | |
|---|---|---|---|---|---|
| | | | | Film | |
| | Exposure | Storage | Spectral | contraction | |
| | sensitivity | stability | change | ratio | Cracks |
| Example 1 | C | A | B | B | A |
| Example 2 | C | B | B | A | A |
| Example 3 | B | A | B | B | A |
| Example 4 | C | A | B | B | A |
| Example 5 | B | B | B | A | A |
| Example 6 | A | A | B | A | A |
| Example 7 | C | A | B | B | A |
| Example 8 | B | B | A | A | A |
| Example 9 | A | A | A | A | A |
| Example 10 | A | B | A | A | B |
| Example 11 | A | A | A | B | A |
| Example 12 | A | A | A | B | A |
| Example 13 | A | A | A | A | A |
| Example 14 | A | A | A | A | A |
| Example 15 | C | B | A | B | A |
| Example 16 | C | A | A | B | B |
| Example 17 | C | A | B | A | A |
| Example 18 | A | A | B | A | A |
| Example 19 | A | A | A | A | A |
| Example 20 | A | B | A | B | A |
| Example 21 | A | A | B | A | A |
| Example 22 | A | A | A | A | A |
| Example 23 | A | A | A | A | A |
| Example 24 | C | B | A | A | A |
| Example 25 | A | A | B | B | A |
| Example 26 | A | A | B | A | A |
| Example 27 | C | B | B | C | B |
| Example 28 | B | A | A | C | B |
| Example 29 | A | A | A | A | A |
| Example 30 | A | A | A | A | A |
| Example 31 | A | A | A | A | A |
| Example 32 | A | A | A | A | A |
| Example 33 | A | A | A | A | A |
| Example 34 | A | A | A | B | B |
| Example 35 | A | A | B | A | A |
| Example 36 | C | B | A | A | A |
| Example 37 | A | A | A | B | A |
| Example 38 | A | A | B | A | A |
| Example 39 | C | B | A | A | A |
| Example 40 | A | A | A | A | A |

TABLE 6

| | Evaluation result | | | | |
|---|---|---|---|---|---|
| | | | | Film | |
| | Exposure | Storage | Spectral | contraction | |
| | sensitivity | stability | change | ratio | Cracks |
| Example 41 | A | A | B | B | A |
| Example 42 | C | A | A | C | B |
| Example 43 | B | A | A | C | B |
| Example 44 | A | A | B | B | A |
| Example 45 | A | A | B | B | B |
| Example 46 | A | B | A | C | B |
| Example 47 | B | A | A | A | B |
| Example 48 | B | A | A | A | B |
| Example 49 | A | A | A | B | B |
| Example 50 | A | A | A | A | A |
| Example 51 | B | A | B | A | B |
| Example 52 | A | A | A | B | A |
| Example 53 | A | A | A | A | A |
| Example 54 | A | A | A | A | A |
| Example 55 | B | B | C | A | A |
| Example 56 | B | B | C | A | A |
| Example 57 | B | A | A | A | A |
| Example 58 | A | B | B | B | A |
| Example 59 | B | B | B | B | A |
| Example 60 | B | B | C | B | A |
| Example 61 | A | C | C | B | A |
| Example 62 | B | A | A | C | C |
| Example 63 | B | A | A | B | A |
| Example 64 | A | A | A | B | A |
| Example 65 | A | A | A | A | A |
| Example 66 | A | A | A | A | A |
| Example 67 | A | A | A | B | A |
| Example 68 | B | A | A | B | C |
| Comparative | B | B | D | E | D |
| Example 1 | | | | | |
| Comparative | C | B | D | E | E |
| Example 2 | | | | | |

In a case of using the coloring resin composition of Examples, the occurrence of cracks was suppressed as compared with a case of using the coloring resin composition of Comparative Example 1 or 2. Therefore, as compared with the coloring resin composition of Comparative Example 1 or 2, it can be said that it was possible to expand a process window of process after manufacturing the film.

### Example 100: Pattern Formation by Photolithography Method

The coloring resin composition of Example 1 was applied to a silicon wafer by spin coating, and dried (pre-baked) at 100° C. for 120 seconds using a hot plate. Thereafter, the coloring resin composition was heated (post-baked) at 200° C. for 30 minutes using an oven to form a resin composition layer having a thickness of 0.60 μm.

Next, using an i-ray stepper exposure device FPA-3000 i5+(manufactured by Canon Inc.), the resin composition layer was irradiated with light having a wavelength of 365 nm through a mask pattern in which square non-masked pixels with a side of 1.1 μm were arranged in an area of 4 mm×3 mm to perform exposure thereon with an exposure amount of 500 mJ/cm².

Next, the silicon wafer on which the resin composition layer after the exposure was formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pattern (pixel).

The produced silicon wafer with a pattern was divided into two, and one of these was heat-treated at 300° C. for 5 hours in a nitrogen atmosphere (hereinafter, one is referred to as a substrate before heating treatment at 300° C. and the other is referred to as a substrate after heating treatment at 300° C.). In a case where cross sections of resist patterns formed on the substrate before heating treatment at 300° C. and the substrate after heating treatment at 300° C. were evaluated by a scanning electron microscope (SEM), the height of the resist pattern formed on the substrate after heating treatment at 300° C. was 75% of the height of the resist pattern formed on the substrate before heating treatment at 300° C.

What is claimed is:

1. A coloring resin composition comprising:
a resin;
a coloring material; and
an organic solvent,
wherein the resin includes a resin A including a repeating unit (A) represented by Formula (a), 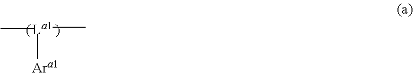
in Formula (a), L^{a1} represents a trivalent group,
Ar^{a1} represents an aromatic hydrocarbon group having a substituent,
the substituent is a group having a structure in which a bonding portion with the aromatic hydrocarbon group is an ester bond or an amide bond,
in the ester bond, an atom on a side different from an oxygen atom in the ester bond is on a side of the bonding portion with the aromatic hydrocarbon group, and
in the amide bond, an atom on a side different from a nitrogen atom in the amide bond is on a side of the bonding portion with the aromatic hydrocarbon group.

2. The coloring resin composition according to claim 1,
wherein L^{a1} is an aliphatic hydrocarbon group.

3. The coloring resin composition according to claim 1,
wherein the repeating unit (A) is a repeating unit represented by Formula (1), 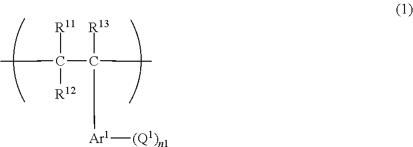
in Formula (1), R¹¹ to R¹³ each independently represent a hydrogen atom, an alkyl group, or an aryl group, Ar¹ represents an aromatic hydrocarbon group, and Q¹ represents a group represented by any one of Formula (Q-1) to Formula (Q-5), 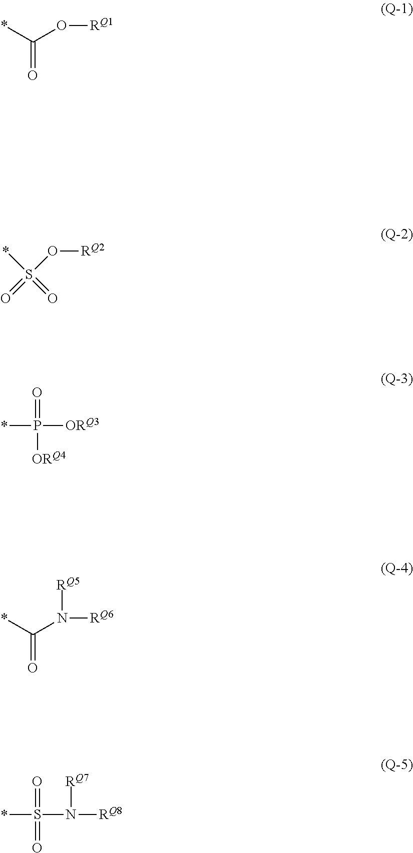
in the formulae, R^{Q1}, R^{Q2}, R^{Q3}, R^{Q6}, and R^{Q8} each independently represent a substituent,
R^{Q4}, R^{Q5}, and R^{Q7} each independently represent a hydrogen atom or a substituent,
* represents a bonding site, and
n1 represents an integer of 1 to a maximum number of substitutions of Ar¹.

4. The coloring resin composition according to claim 1,
wherein the repeating unit (A) is a repeating unit represented by Formula (2), 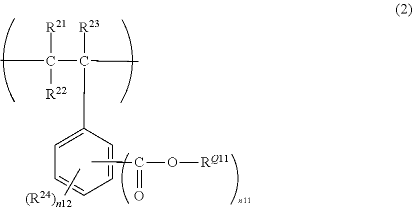
in Formula (2), R²¹ to R²³ each independently represent a hydrogen atom, an alkyl group, or an aryl group, R²⁴ represents a substituent, R^{Q11} represents a substituent, n11 represents an integer of 1 to 5, n12 represents an integer of 0 to 4, and n11+n12 is 1 to 5.

5. The coloring resin composition according to claim 1,
wherein the resin A has a carboxy group.

6. The coloring resin composition according to claim 1,
wherein an acid value of the resin A is 20 to 200 mgKOH/g.

7. The coloring resin composition according to claim 1,
wherein a weight-average molecular weight of the resin A is 10000 to 100000.

8. The coloring resin composition according to claim 1,
wherein the resin A has a crosslinkable group.

9. The coloring resin composition according to claim 1,
wherein the resin A is a graft polymer or a star polymer.

10. The coloring resin composition according to claim 1,
wherein the resin A is a graft polymer which has a graft chain including the repeating unit (A).

11. The coloring resin composition according to claim 1,
wherein the coloring material includes at least one selected from the group consisting of a chromatic coloring material and a near-infrared absorbing coloring material.

12. The coloring resin composition according to claim 1,
wherein the coloring material includes a chromatic coloring material and a near-infrared absorbing coloring material.

13. The coloring resin composition according to claim 1,
wherein the coloring material includes a black coloring material.

14. The coloring resin composition according to claim 1,
wherein the coloring material includes at least one chromatic coloring material selected from the group consisting of a red coloring material, a yellow coloring material, a blue coloring material, and a violet coloring material.

15. The coloring resin composition according to claim 1, further comprising:
a photopolymerization initiator.

16. The coloring resin composition according to claim 15,
wherein the photopolymerization initiator is an oxime compound.

17. A film formed of the coloring resin composition according to claim 1.

18. A color filter comprising:
the film according to claim 17.

19. A solid-state imaging element comprising:
the film according to claim 17.

20. An image display device comprising:
the film according to claim 17.
